(19) United States
(12) Patent Application Publication
(10) Pub. No.: US 2025/0301908 A1
(43) Pub. Date: Sep. 25, 2025

(54) BORON-NITROGEN-CONTAINING ORGANIC COMPOUNDS AND USES THEREOF IN ORGANIC ELECTRONIC DEVICES

(71) Applicant: Zhejiang Brilliant Optoelectronic Technology Co.,Ltd., Taizhou (CN)

(72) Inventors: Junyou PAN, Taizhou (CN); Hao ZHANG, Taizhou (CN)

(73) Assignee: Zhejiang Brilliant Optoelectronic Technology Co.,Ltd., Taizhou (CN)

(21) Appl. No.: 19/232,000

(22) Filed: Jun. 9, 2025

Related U.S. Application Data
(63) Continuation of application No. PCT/CN2023/137506, filed on Dec. 8, 2023.

(30) Foreign Application Priority Data
Dec. 8, 2022 (CN) 202211572027.9

(51) Int. Cl. H10K 85/60; C07F 5/02; C09K 11/02; C09K 11/06; H10K 50/12

(52) U.S. Cl. CPC H10K 85/658; C07F 5/027; C09K 11/025; C09K 11/06; H10K 85/6572; H10K 85/6574; C07B 2200/05; C09K 2211/1007; C09K 2211/1011; C09K 2211/1018; H10K 50/12

(57) ABSTRACT

Disclosed are boron-nitrogen-containing organic compounds including a structure represented by a combination of formula (I-1) and formula (I-2). Also disclosed are formulations containing an organic solvent, and at least one boron-nitrogen-containing organic compound. Further disclosed are organic electronic devices containing the boron-nitrogen-containing organic compounds. The boron-nitrogen-containing organic compound is applied to the organic device, the device utilizing the boron-nitrogen-containing organic compound exhibit high luminescence efficiency, narrow emission spectrum FWHM, long operational lifetime, etc.

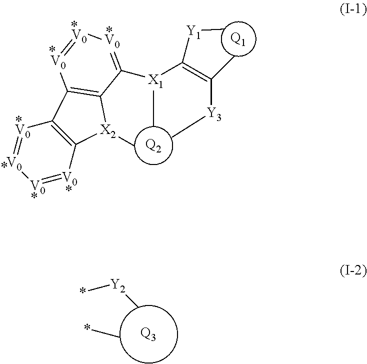

### CROSS-REFERENCE TO RELATED APPLICATIONS

The present application is a continuation of International Application No. PCT/CN2023/137506, filed on Dec. 8, 2023, which claims priority to Chinese Patent Application No. 202211572027.9, filed on Dec. 8, 2022. All of the aforementioned applications are incorporated herein by reference in their entireties.

### TECHNICAL FIELD

The present disclosure relates to the field of organic electronic material and device technology, and in particularly to a boron-nitrogen-containing organic compound, a formulation, and the applications thereof in organic electronic devices, particularly in organic electroluminescent diodes.

### BACKGROUND

Optoelectronic devices, especially organic light-emitting diodes (OLEDs), show great potential for application in the display field due to the synthetic chemical diversity, the low manufacturing cost in large-scale production, the excellent optical and electrical properties, etc.

In OLED displays, various colors are expressed by mixing the three primary colors (i.e., red, green, and blue) of light, but if the color purity of each of the three primary colors is low, it is not possible to display a large number of colors, resulting in a significant reduction in the picture quality of the display. Therefore, in commercially available displays, the color purity can be improved by removing unwanted colors from the emission spectrum using an optical filter. If the intrinsic spectrum of the molecule is wide, the proportion of spectrum that need to be removed will increase. Therefore, in the case of high luminescence efficiency, the luminescence efficiency of the device will be significantly reduced. For instance, the full width at half maximum (FWHM) of blue emission spectrum in commercial smartphones typically ranges from 20 nm to 25 nm, but the FWHM of the fluorescent materials generally ranges from 40 nm to 60 nm, that of phosphorescent materials ranges from 60 nm to 90 nm, and that of TADF materials ranges from 70 nm to 100 nm. Therefore, when using fluorescent materials, their FW

HM is relatively narrow, so only removing a portion of unnecessary colors is sufficient. However, when using phosphorescent or TADF materials, more than half of the colors need to be removed, resulting in a significant decrease in the actual luminescence efficiency.

Blue-emitting BN compounds with narrow emission spectrum (DOI: 10.1002/adma.201505491) have received widespread attention since their initial report were first reported by Hatakeyama et al. in 2016. The boron-nitrogen compound exhibit a multi-resonance effects, i.e., the molecular structure is maintained in a special planar rigid conjugated structure, and the different electronegativities brought by the unique empty orbits on the boron atoms that can be involved in electron cloud conjugation as well as the lone-pair electrons on the nitrogen atoms that can be involved in electron cloud conjugation are mutually enhanced through conjugation effect, which results in the formation of the intramolecular short-range charge-transfer state to achieve high luminescence efficiency with the thermally activated delayed fluorescence (TADF) property. In addition, the planar structure of the boron-nitrogen compound compared to other light-emitting materials (e.g. conventional fluorescent materials) is special in that the energy levels of the molecular vibration modes are highly merged, which results in a significantly narrower FWHM of the emission spectrum compared with other light-emitting materials (e.g., conventional fluorescent materials), and thus facilitates the realization of high color purity. Due to the high device efficiency, high color purity, and potential high device stability of the boron-nitrogen compounds, these materials are highly valued in both academia and industry, and are one of the hottest topics in the field of OLED luminescent materials.

However, in the case of the boron-nitrogen compound, the FWHM of the emission spectrum and the luminescence efficiency often depend on the ability to effectively suppress the vibrational and rotational degrees of freedom of the internal molecular groups. For example, in the case of the currently developed boron-nitrogen compounds (their structure are shown in the following formula a to formula e), due to the large torsion angle between the phenyl group connected to the nitrogen atom and the boron-nitrogen rigid conjugated plane, this phenyl group does not directly participate in the super-resonance effect of the boron-nitrogen rigid conjugated plane and cannot directly participate in the luminescence process of the boron-nitrogen ring compounds. Moreover, such phenyl groups tend to exhibit large vibrational and rotational degrees of freedom, which has an adverse effect on narrowing the FWHM of the boron-nitrogen compounds. There is still room for further improvement in achieving high luminescence efficiency, narrow FWHM, and long device operational lifetime for boron-nitrogen compounds.

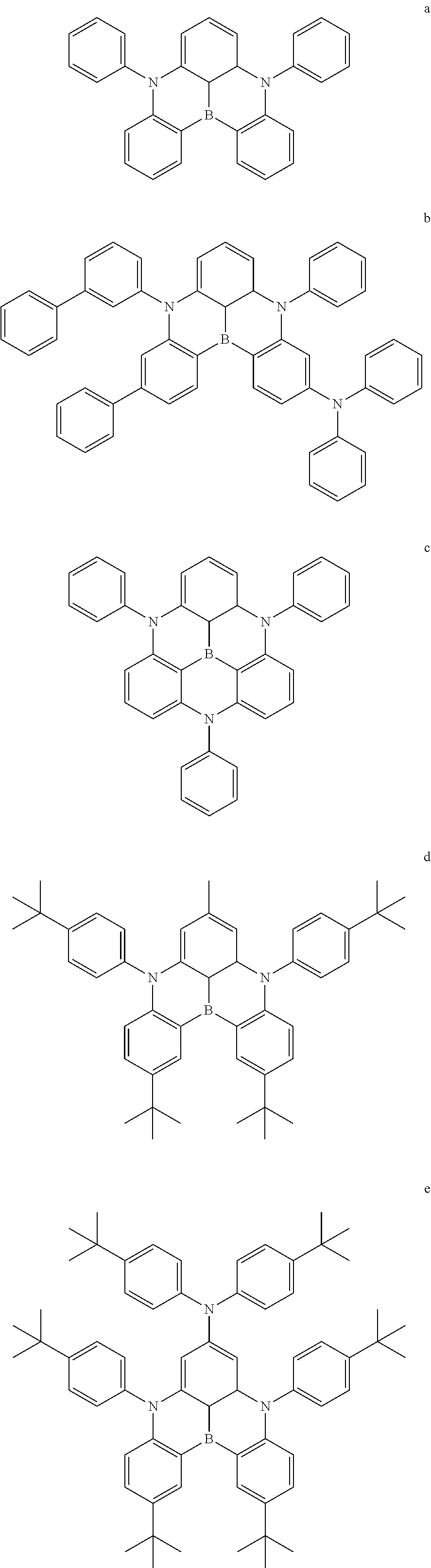

### SUMMARY

In one aspect, the present disclosure provides a boron-nitrogen-containing organic compound, a structure of the boron-nitrogen-containing organic compound is represented by a combination of formula (I-1) and formula (I-2):

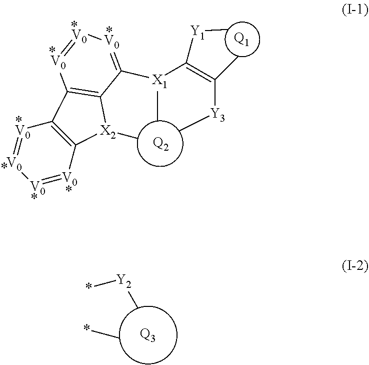

Where each * independently represents a linkage site where formula (I-1) is fused with formula (I-2); Q₁ ring, Q₂ ring, and Q₃ ring are each independently selected from a substituted/unsubstituted aryl group, a substituted/unsubstituted heteroaryl group, or a substituted/unsubstituted fused-ring structure; each of X₁ and X₂ is independently selected from B, N, P, P═O, or Al; each of Y₁ and Y₂ is independently selected from C═O, N—R₁, O, S, Se, P, P═O, or P═S; each Y₃ is independently selected from C═O, N—R₁, O, Se, P, P═O, or P═S; V₀ at each occurrence is independently C—R₂ or N—R₃;
each of R₁ to R₃ at each occurrence is independently selected from —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 60 ring atoms, an aryloxy or heteroaryloxy group containing 5 to 60 ring atoms, or any combination thereof.

In another aspect, the present disclosure also provides a polymer comprising at least one first repeating unit, the at least one first repeating unit comprises at least one structure corresponding to a boron-nitrogen-containing organic compound as described herein.

In yet another aspect, the present disclosure further provides a formulation comprising an organic solvent, and at least one boron-nitrogen-containing organic compound as described herein or at least one polymer as described herein.

In yet another aspect, the present disclosure further provides a mixture comprising a boron-nitrogen-containing organic compound or a polymer as described herein, and at least one organic functional material, the at least one organic functional material is selected from at least one of the following: a hole-injection material, a hole-transport material, an electron-transport material, an electron-injection material, an electron-blocking material, a hole-blocking material, a light-emitting material, a host material.

In yet another aspect, the present disclosure further provides an organic electronic device comprising at least one boron-nitrogen-containing organic compound or polymer or mixture as described herein.

Beneficial effect: the present disclosure applies the boron-nitrogen-containing organic compound to organic light-emitting devices, which can achieve high luminescence efficiency, high color purity, high device stability, long device operational lifetime, etc. The boron-nitrogen-containing organic compound as described herein improves the optical properties of a boron-nitrogen skeleton mainly by using large conjugated groups as modifying groups. The conjugated length of the boron-nitrogen molecules can be extended by introducing a large conjugated group (i.e., Q₃ ring is fused to the core structure of BN via a five ring), thereby improving the molecular stability. In addition, the electron cloud density around the adjacent B atoms can be adjusted by introducing different conjugated groups, which facilitates the adjustment of the molecular emission spectrum; at the same time, the large conjugated group improves the planar stacking effect of the molecule to a certain extent, which can reduce the exciton annihilation phenomenon in the device, thereby regulating the emission color of the organic compound, improving the efficiency of the light-emitting device, and prolong the the lifetime. The present inventors were surprised to find that in some cases, blue emission can be maintained even if the conjugated structure becomes larger, thereby enabling the organic light-emitting device to have high luminescent efficiency, high color purity, long device operational lifetime, etc.

### DETAILED DESCRIPTION OF THE EMBODIMENTS

The present disclosure provides a boron-nitrogen-containing organic compound, a formulation, an organic electronic device, and the applications thereof, aiming to solve the problems of low efficiency and short lifetime in the existing OLEDs.

The present disclosure provides a boron-nitrogen-containing organic compound that can be used as an organic light-emitting material in organic light-emitting devices, but is not limited thereto. The boron-nitrogen-containing organic compound has been optimized and selected to possess at least the following characteristics: high luminescence efficiency, narrow FWHM, and long lifetime.

In order to make the objects, the technical solutions and the effects of the present disclosure more clear and definite, the present disclosure is further described in detail below with reference to specific embodiments. It should be understood that the embodiments described herein are only intended to explain the present disclosure and are not intended to limit the present disclosure. Unless otherwise specified, the data ranges involved in the present disclosure shall include the endpoint values.

As used herein, the terms “host material”, “matrix material” have the same meaning, and they are interchangeable with each other.

As used herein, the terms “dopant material”, “light-emitting material”, and “emitter material” have the same meaning, and they are interchangeable with each other.

As used herein, the terms “color converter”, “color conversion layer”, and “CCL” have the same meaning, and they are interchangeable with each other.

As used herein, the terms “formulation”, “printing ink”, and “ink” have the same meaning, and they are interchangeable with each other.

As used herein, the term “substituted” means that a hydrogen atom of the compound is substituted.

As used herein, the same substituentin multiple occurrences, may be independently selected from different groups.

As used herein, the term “substituted/unsubstituted” means that the defined group may or may not be substituted. When the defined group is substituted with a substituent, it should be understood that it is optionally substituted with a substituent acceptable in the art, and the substituent may be further substituted with a substituent acceptable in the art.

As used herein, “the number of ring atoms” means that the number of atoms constituting the ring itself of a structural compound (e.g., a monocyclic compound, a fused ring compound, a cross-linked compound, a carbocyclic compound, and a heterocyclic compound) by covalent bonding. When the ring is substituted with a substituent, the atoms contained in the substituent are not included in the ring atoms. The above rule applies for all cases without further specific description. For example, the number of ring atoms of a benzene ring is 6, the number of ring atoms of a naphthalene ring is 10, and the number of ring atoms of a thienyl group is 5.

As used herein, the term “aromatic group” refers to a hydrocarbon group containing an aromatic ring. The term “heteroaromatic group” refers to an aromatic hydrocarbon group containing at least one heteroatom. The heteroatoms are preferably selected from Si, N, P, O, S and/or Ge, particularly preferably selected from Si, N, P, O and/or S. The term “fused-ring aromatic group” refers to an aromatic group containing two or more rings, in which two carbon atoms are shared by the adjacent two rings, i.e., fused rings. The term “fused heterocyclic aromatic group” refers a fused aromatic hydrocarbon group containing at least one heteroatom. For the purposes of the present disclosure, the aromatic groups or heteroaromatic groups comprise not only aromatic ring systems, but also non-aromatic ring systems. Therefore, systems such as pyridine, thiophene, pyrrole, pyrazole, triazole, imidazole, oxazole, oxadiazole, thiazole, tetrazole, pyrazine, pyridazine, pyrimidine, triazine, carbene, and the like is also considered be aromatic groups or heterocyclic aromatic groups for the purposes of this disclosure. For the purposes of the present disclosure, the fused-ring aromatic or fused heterocyclic aromatic ring systems contain not only aromatic or heteroaromatic systems, but also have a plurality of aromatic or heterocyclic aromatic groups linked by short non-aromatic units (<10% of non-H atoms, preferably ≤5% of non-H atoms, such as C, N or O atoms). Therefore, a system such as 9,9′-spirobifluorene, 9,9-diarylfluorene, triarylamine, diaryl ether, and the like is also considered to be aromatic ring systems for the purposes of this disclosure.

In embodiments of the present disclosure, the energy level structure of the organic materials, singlet energy level (S₁), oscillator strength f1, triplet energy level (T₁), highest occupied molecular orbital (HOMO), and lowest unoccupied molecular orbital (LUMO) play key roles. The determination of these energy levels is introduced as follows.

HOMO and LUMO energy levels can be measured by optoelectronic effect, for example, by XPS (X-ray photoelectron spectroscopy), UPS (UV photoelectron spectroscopy), or by cyclic voltammetry (hereinafter referred to as CV). Recently, quantum chemical methods, such as density functional theory (hereinafter referred to as DFT), are becoming effective methods for calculating the molecular orbital energy levels.

The singlet energy level S₁ of the organic materials can be determined by the emission spectrum. The triplet energy level T₁ of the organic materials can be measured by low-temperature time-resolved spectroscopy. S₁ and T₁ can also be calculated by quantum simulation (for example, by time-dependent DFT), for instance with the commercial software Gaussian 09W (Gaussian Inc.), the specific simulation method can be found in WO2011141110 or as described in the following embodiments. ΔE_{ST} is defined as (S₁-T₁).

It should be noted that the absolute values of HOMO, LUMO, S₁, f1, and T₁ may depend on the measurement method or calculation method used. Even for the same method, different ways of evaluation, for example, using either the onset or peak value of a CV curve as reference, may result in different HOMO/LUMO values. Therefore, reasonable and meaningful comparison should be carried out by employing the same measurement and evaluation methods. In the embodiments of the present disclosure, the values of HOMO, LUMO, S₁, f1, and T₁ are based on the time-dependent DFT simulation, which however should not exclude the applications of other measurement or calculation methods.

In the disclosure, (HOMO−1) is defined as the energy level of the second highest occupied molecular orbital, (HOMO−2) is defined as the energy level of the third highest occupied molecular orbital, and so on. (LUMO+1) is defined as the energy level of the second lowest unoccupied molecular orbital, (LUMO+2) is defined as the energy level of the third lowest occupied molecular orbital, and so on.

In one aspect, the present disclosure provides a boron-nitrogen-containing organic compound, the structure of the boron-nitrogen-containing organic compound is represented by a combination of formula (I-1) and formula (I-2):

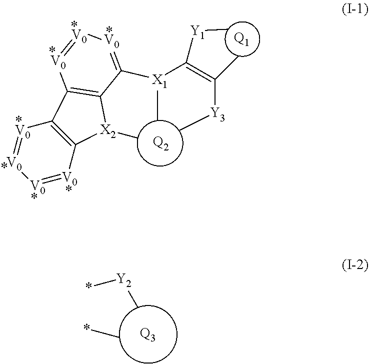

Where each * independently represents a linkage site where formula (I-1) is fused with formula (I-2); Q₁ ring, Q₂ ring, and Q₃ ring are each independently selected from a substituted/unsubstituted aryl group, a substituted/unsubstituted heteroaryl group, or a substituted/unsubstituted fused-ring structure; each of X₁ and X₂ is independently selected from B, N, P, P═O, or Al; each of Y₁ and Y₂ is independently selected from C═O, N—R₁, O, S, Se, P, P═O, or P═S; each Y₃ is independently selected from C═O, N—R₁, O, Se, P, P═O, or P═S; V₀ at each occurrence is independently C—R₂ or N—R₃; each of R₁ to R₃ at each occurrence is independently selected from —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 60 ring atoms, an aryloxy or heteroaryloxy group containing 5 to 60 ring atoms, or any combination thereof.

In some embodiments, Q₁ ring, Q₂ ring, and Q₃ ring of the boron-nitrogen-containing organic compound are each independently selected from an aryl or heteroaryl ring, and at least one hydrogen in these rings may be substituted.

In some embodiments, each of Q₁ ring, Q₂ ring, and Q₃ ring at each occurrence is independently selected from a substituted/unsubstituted aryl or heteroaryl group containing 6 to 50 ring atoms, an aryloxy or heteroaryloxy group containing 6 to 50 ring atoms, or any combination thereof. In some embodiments, each of Q₁ ring, Q₂ ring, and Q₃ ring at each occurrence is independently selected from a substituted/unsubstituted aryl or heteroaryl group containing 6 to 30 ring atoms, an aryloxy or heteroaryloxy group containing 6 to 30 ring atoms, or any combination thereof. In some embodiments, each of Q₁ ring, Q₂ ring, and Q₃ ring at each occurrence is independently selected from a substituted/unsubstituted aryl or heteroaryl group containing 6 to 20 ring atoms, an aryloxy or heteroaryloxy group containing 6 to 20 ring atoms, or any combination thereof. In some embodiments, each of Q₁ ring, Q₂ ring, and Q₃ ring at each occurrence is independently selected from a substituted/unsubstituted aryl or heteroaryl group containing 6 to 15 ring atoms, an aryloxy or heteroaryloxy group containing 6 to 15 ring atoms, or any combination thereof.

In some embodiments, each of X₁ and X₂ is independently B or N.

In some embodiments, the structure of the boron-nitrogen-containing organic compound is represented by a combination of formula (I-1a) and formula (I-2a):

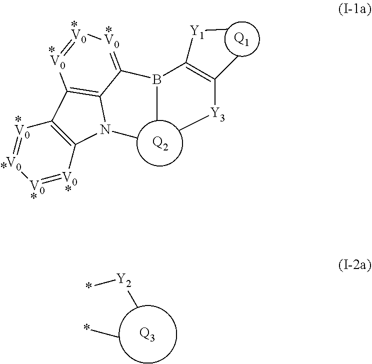

Where V₀, Y₁, Y₂, Y₃, Q₁ ring, Q₂ ring, Q₃ ring, and * are identically defined as described herein.

In some embodiments, the boron-nitrogen-containing organic compound comprises a structure of one of formulas (II-1)-(II-10):

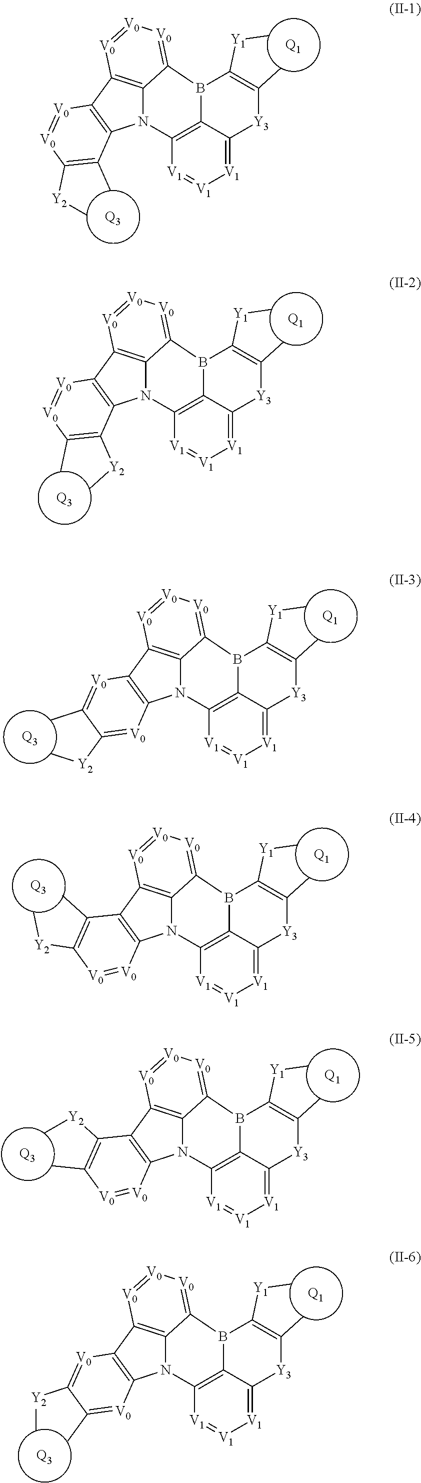

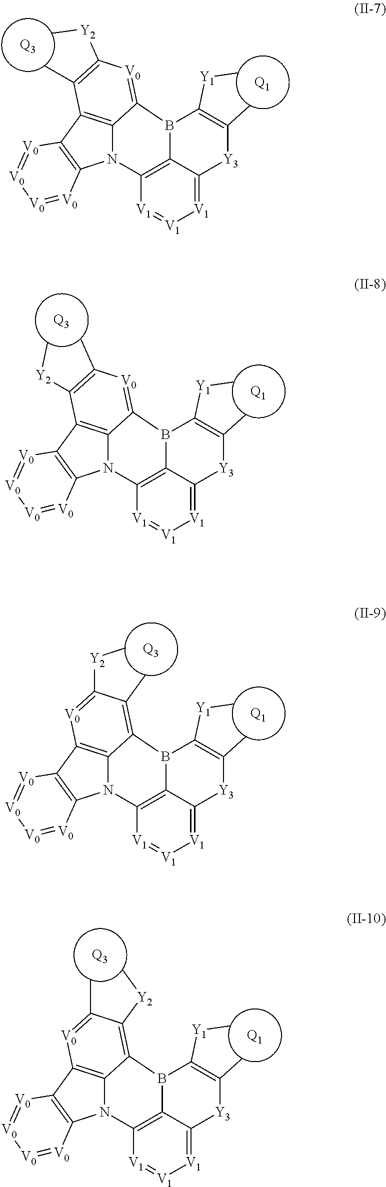

Where V₀, Y₁, Y₂, Y₃, Q₁ ring, and Q₃ ring are identically defined as described herein, V₁ is defined as the above-mentioned V₀.

In some embodiments, the boron-nitrogen-containing organic compound is selected from the structures of formulas (II-1)-(II-6):

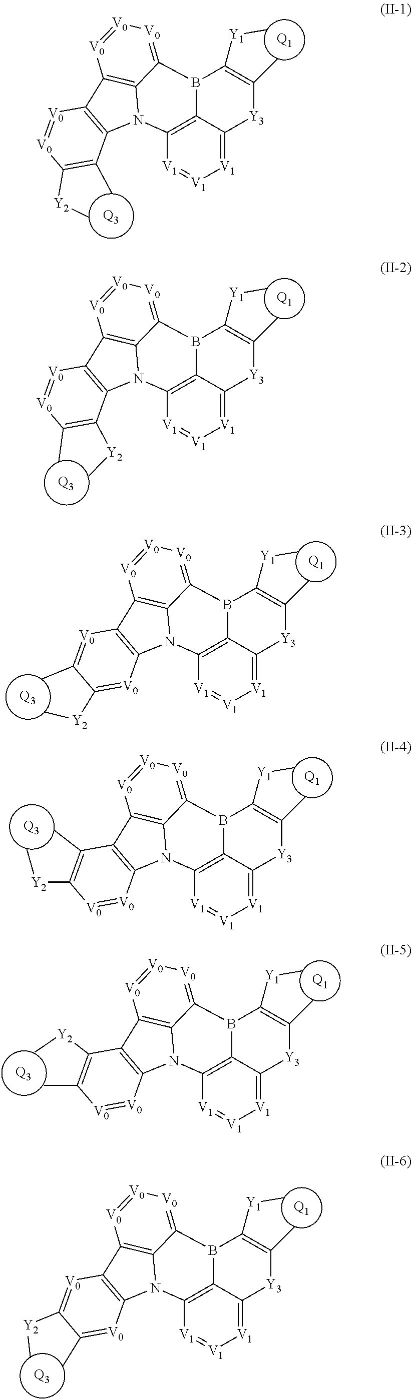

Where V₀, Y₁, Y₂, Y₃, Q₁ ring, and Q₃ ring are identically defined as described herein, V₁ is defined as the above-mentioned V₀.

In some embodiments, the boron-nitrogen-containing organic compound is selected from the structures of formulas (II-7), (11-8) and (1-10):

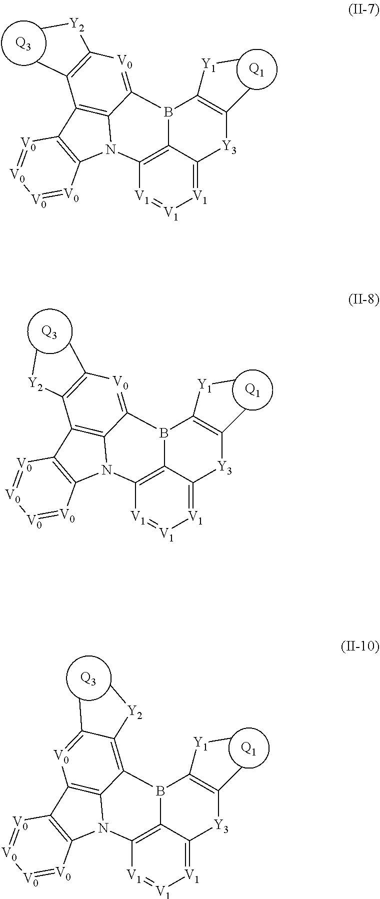

For the purposes of the present disclosure, the present disclosure preferably relates to a blue-emitting compound. Therefore, the compounds with small effective conjugated lengths are preferred, such as compounds with structures of formulas (II-1)-(II-6), (11-7), (11-8), and (11-10).

The compounds with formula (II-9) tend to emit green or blue-green light, and therefore are not preferred structures in some embodiments.

In some embodiments, in the boron-nitrogen-containing organic compound as described herein, each of Q₁ ring, Q₂ ring, and Q₃ ring at each occurrence is independently selected from one or combinations of more than one of the following structures:

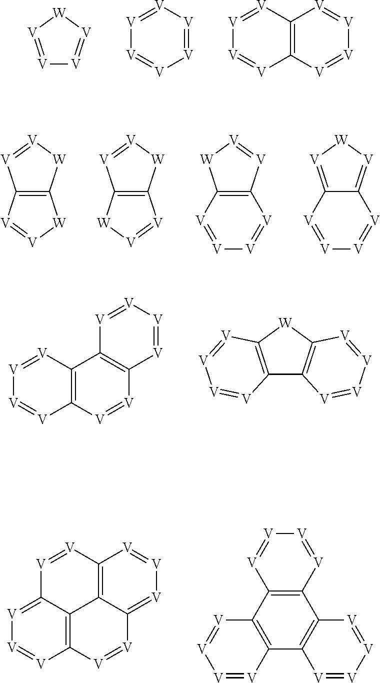

Where V at each occurrence is independently C—R₄ or N—R₅; W at each occurrence is independently selected from B—R₆, C(═O), N—R₇, O, S, P, P═O, or P═S; each of R₄ to R₇ at each occurrence is independently selected from —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 40 ring atoms, an aryloxy or heteroaryloxy group containing 5 to 40 ring atoms, or any combination thereof, where one or more R₄-R₇ may form a ring system with each other and/or with the groups bonded thereto.

In some embodiments, each of Q₁ ring, Q₂ ring, and Q₃ ring is independently selected from an aromatic group, a heteroaromatic group, or a fused-ring aromatic group.

In some embodiments, the aromatic or heteroaromatic group is selected from the following groups:

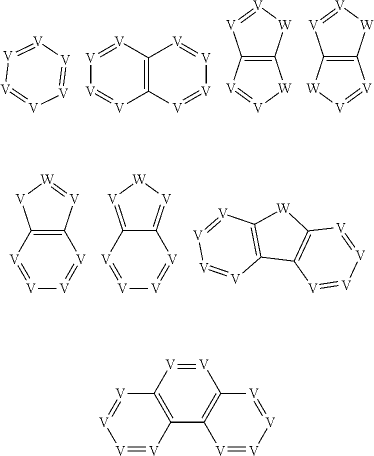

Where V and W are identically defined as described herein.

More preferably, the aromatic or heteroaromatic group is selected from the group consisting of:

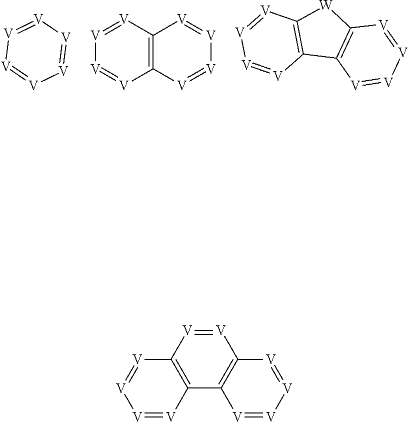

Where V and are identically defined as described herein.

In some embodiments, the fused-ring aromatic group is selected from the group consisting of benzene, naphthalene, anthracene, fluoranthene, phenanthrene, benzophenanthrene, perylene, tetracene, pyrene, benzopyrene, acenaphthylene, fluorene, and derivatives thereof; the fused-ring heteroaromatic group is selected from the group consisting of benzofuran, 1-benzothiophene, indole, carbazole, pyrroloimidazole, pyrrolopyrrole, thienopyrrole, thienothiophene, furopyrrole, furofuran, thienofuran, benzisoxazole, benzoisothiazole, benzimidazole, quinoline, isoquinoline, o-diazanaphthalene, quinoxaline, phenanthridine, perimidine, quinazoline, quinazolinone, and derivatives thereof.

In some embodiments, each of R₁ to R₃ at each occurrence may be independently selected from the following groups:

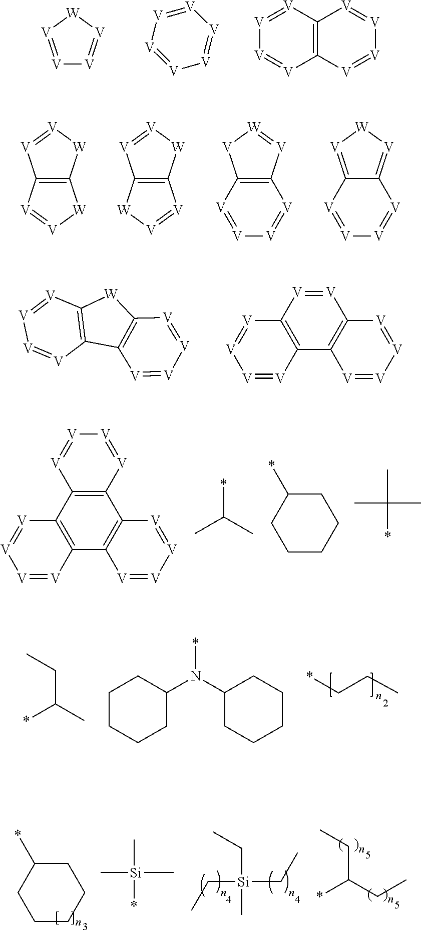

Where V and W are identically defined as described herein; n₂, n₃, n₄, and n₅ are integers greater than or equal to 1.

Further, each of R₁ to R₃ at each occurrence is independently selected from the following groups:

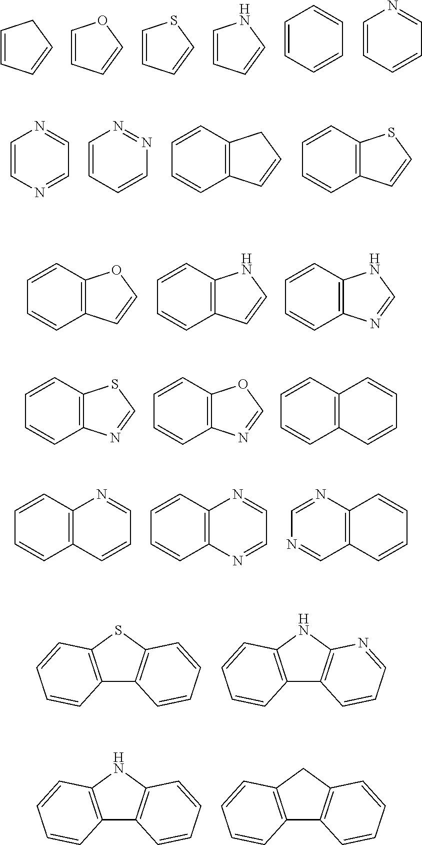

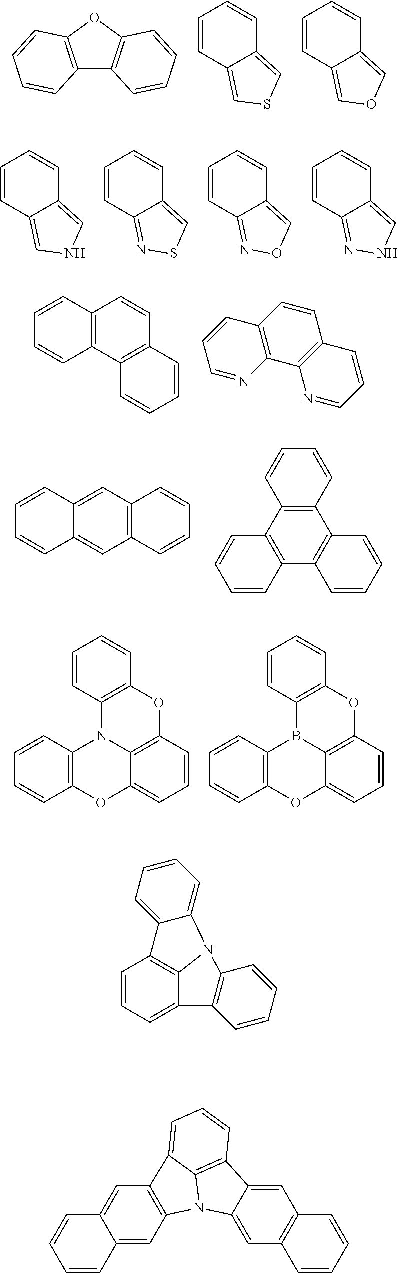

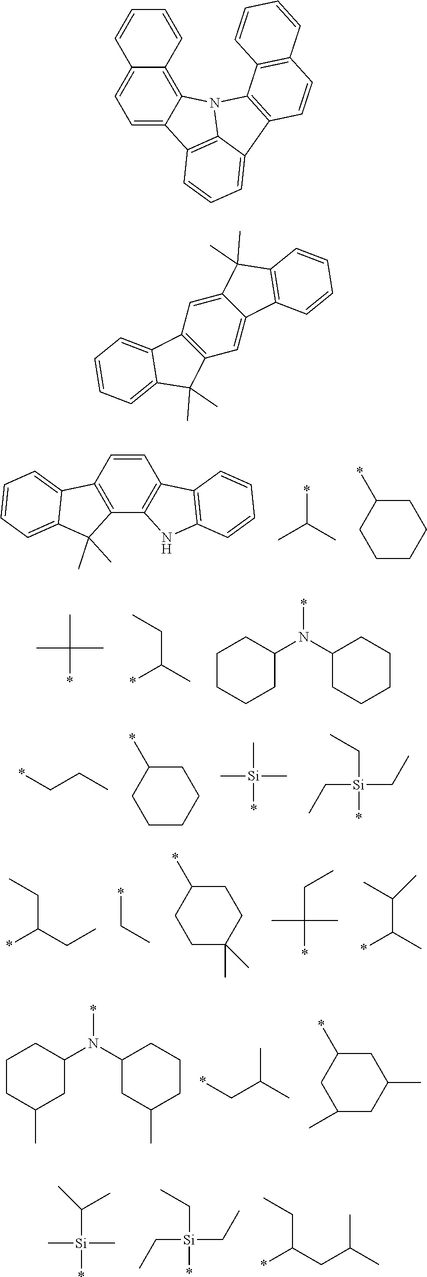

Where H atoms on the ring may be further substituted.

In some embodiments, in the boron-nitrogen-containing organic compound as described herein, each of R₁ to R₃ may be further selected from the following structural units or any combination thereof:

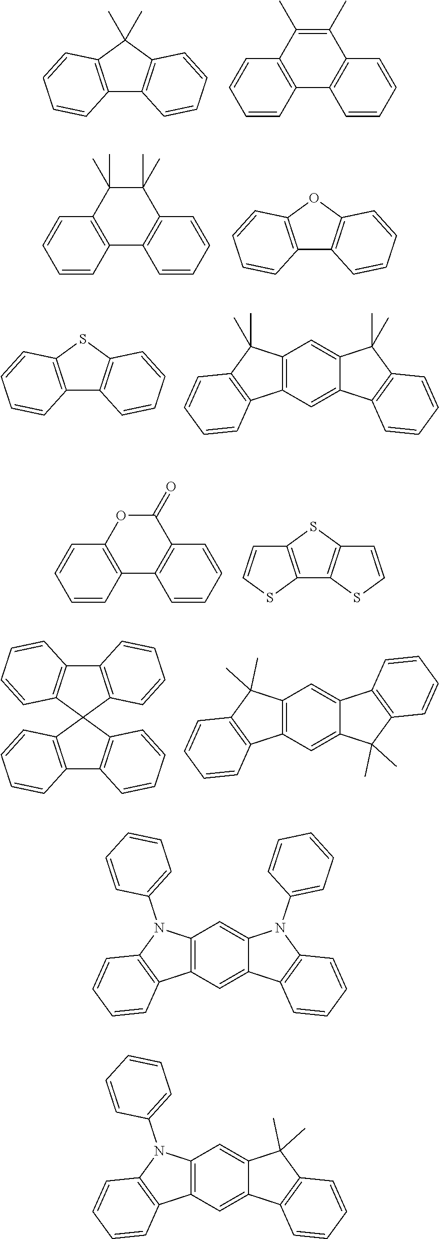

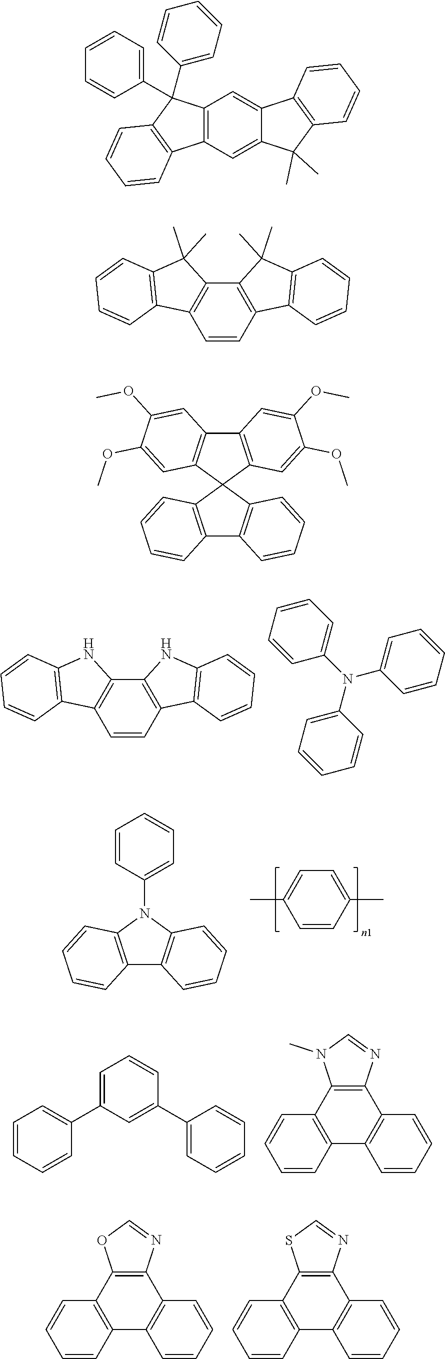

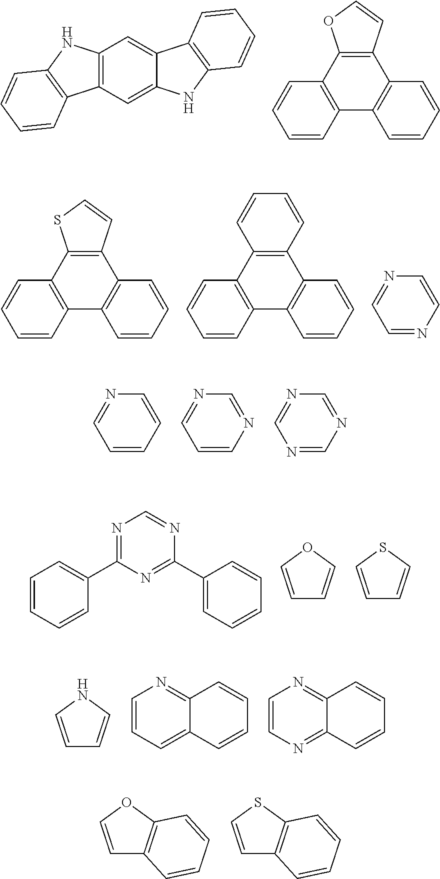

where n1 is an integer from 1 to 4.

In some embodiments, the boron-nitrogen-containing organic compound is partially deuterated; preferably 100 or more of total H, more preferably 2000 or more of total H, further preferably 300% or more of total H, and most preferably 400% or more of total H, are deuterated.

Specific examples of the boron-nitrogen-containing organic compounds as described herein are listed below, but not limited thereto:

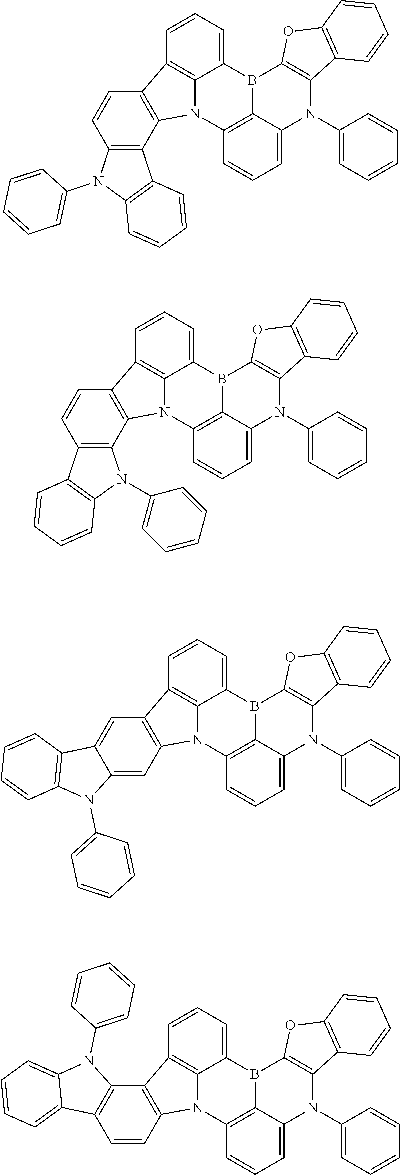 [SMILES: c1ccc(N2c3cccc4c3B(c3oc5ccccc5c32)c2cccc3c5ccc6c(c7ccccc7n6-c6ccccc6)c5n-4c23)cc1 ; c1ccc(N2c3cccc4c3B(c3oc5ccccc5c32)c2cccc3c5ccc6c7ccccc7n(-c7ccccc7)c6c5n-4c23)cc1 ; c1ccc(N2c3cccc4c3B(c3oc5ccccc5c32)c2cccc3c5cc6c7ccccc7n(-c7ccccc7)c6cc5n-4c23)cc1 ; c1ccc(N2c3cccc4c3B(c3oc5ccccc5c32)c2cccc3c5c(ccc6c7ccccc7n(-c7ccccc7)c65)n-4c23)cc1]

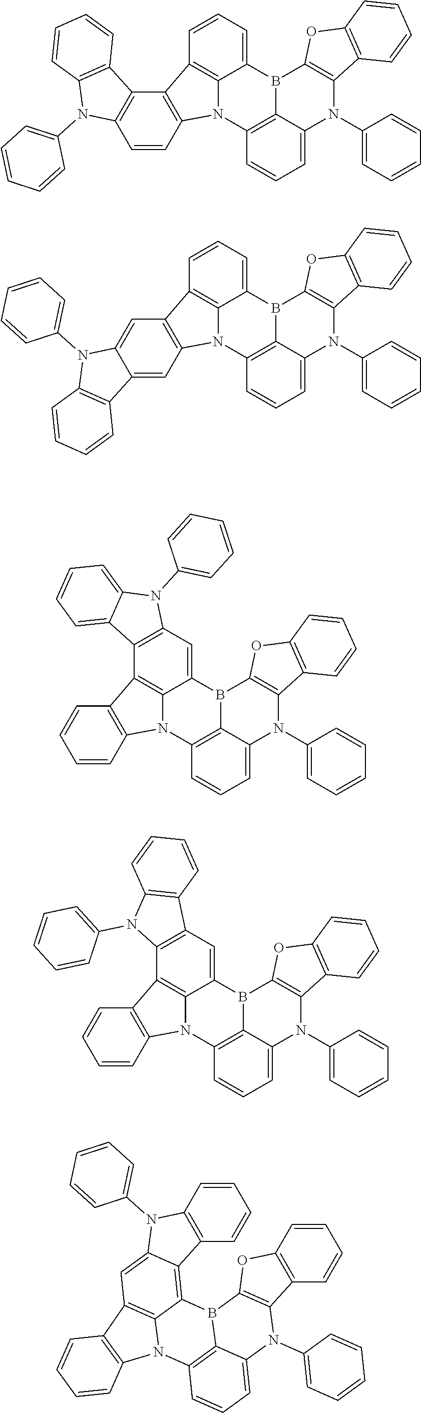 [SMILES: c1ccc(N2c3cccc4c3B(c3oc5ccccc5c32)c2cccc3c5c6c7ccccc7n(-c7ccccc7)c6ccc5n-4c23)cc1 ; c1ccc(N2c3cccc4c3B(c3oc5ccccc5c32)c2cccc3c5cc6c(cc5n-4c23)c2ccccc2n6-c2ccccc2)cc1 ; c1ccc(N2c3cccc4c3B(c3oc5ccccc5c32)c2cc3c(c5ccccc5n3-c3ccccc3)c3c5ccccc5n-4c23)cc1 ; c1ccc(N2c3cccc4c3B(c3oc5ccccc5c32)c2cc3c5ccccc5n(-c5ccccc5)c3c3c5ccccc5n-4c23)cc1 ; c1ccc(N2c3cccc4c3B(c3oc5ccccc5c32)c2c3c5ccccc5n(-c5ccccc5)c3cc3c5ccccc5n-4c23)cc1]

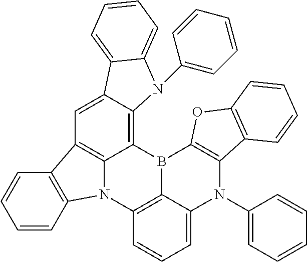 [SMILES: c1ccc(N2c3cccc4c3B(c3oc5ccccc5c32)c2c3c(cc5c6ccccc6n-4c25)c2ccccc2n3-c2ccccc2)cc1]

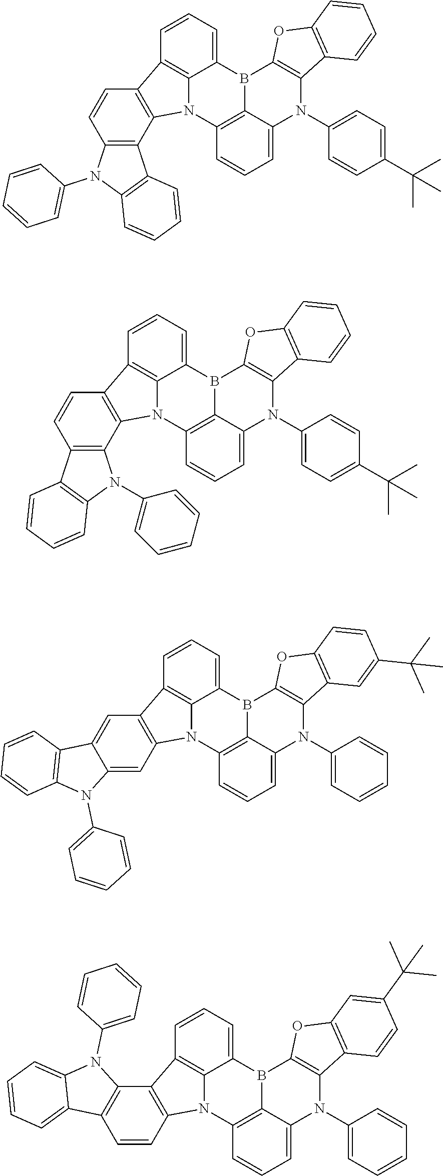 [SMILES: CC(C)(C)c1ccc(N2c3cccc4c3B(c3oc5ccccc5c32)c2cccc3c5ccc6c(c7ccccc7n6-c6ccccc6)c5n-4c23)cc1 ; CC(C)(C)c1ccc(N2c3cccc4c3B(c3oc5ccccc5c32)c2cccc3c5ccc6c7ccccc7n(-c7ccccc7)c6c5n-4c23)cc1 ; CC(C)(C)c1ccc2oc3c(c2c1)N(c1ccccc1)c1cccc2c1B3c1cccc3c4cc5c6ccccc6n(-c6ccccc6)c5cc4n-2c13 ; CC(C)(C)c1ccc2c3c(oc2c1)B1c2c(cccc2-n2c4ccc5c6ccccc6n(-c6ccccc6)c5c4c4cccc1c42)N3c1ccccc1]

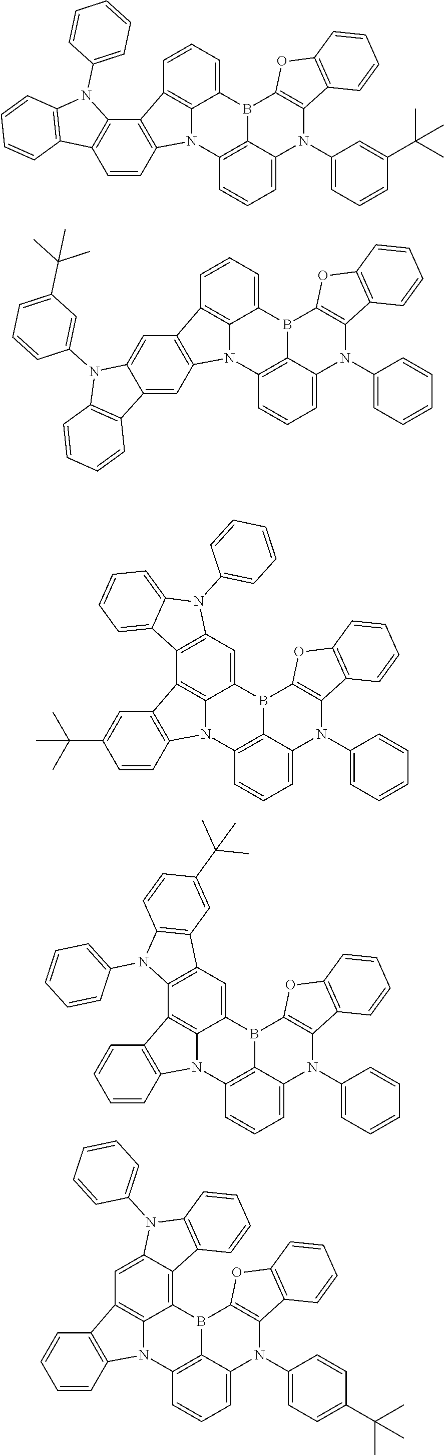

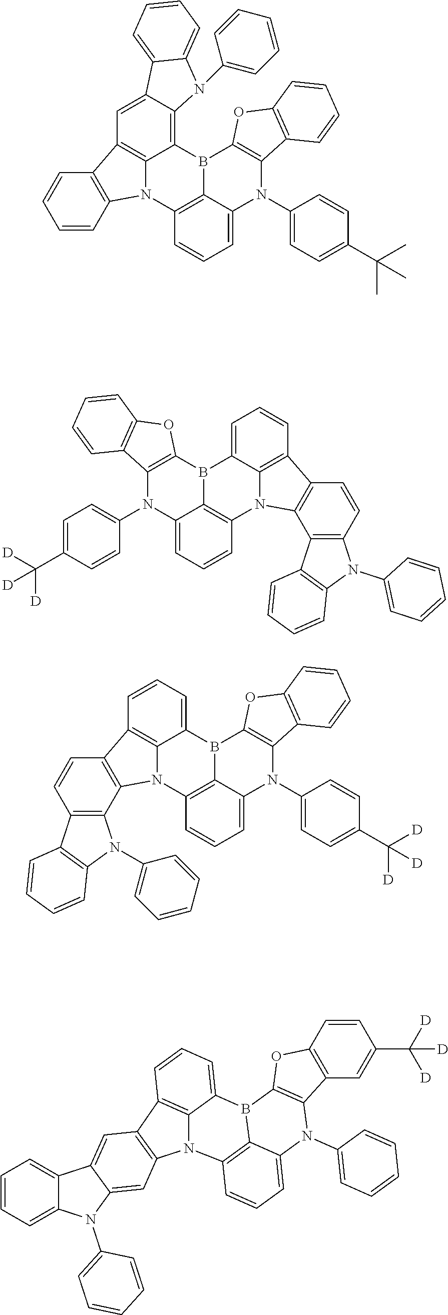

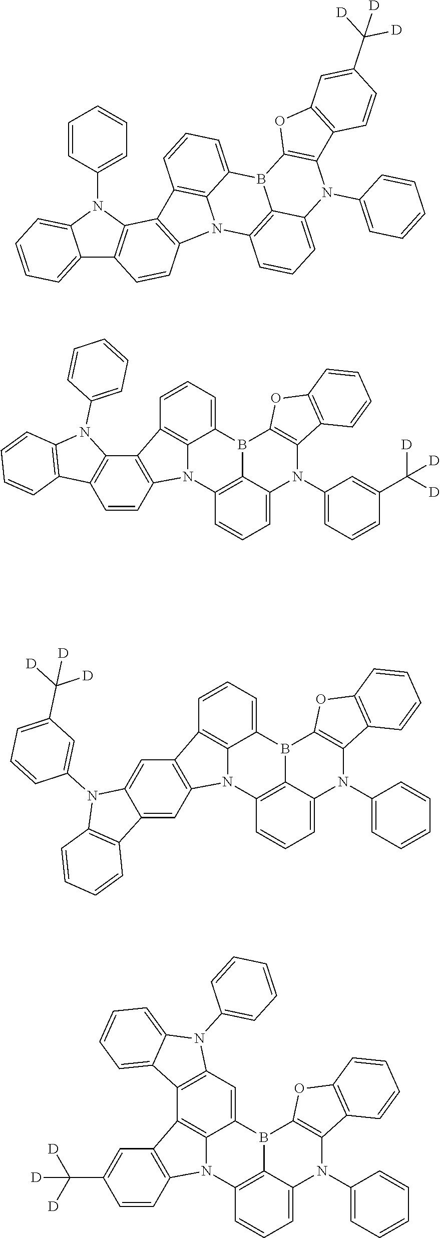 [SMILES: [2H]C([2H])([2H])c1ccc2c3c(oc2c1)B1c2c(cccc2-n2c4ccc5c6ccccc6n(-c6ccccc6)c5c4c4cccc1c42)N3c1ccccc1 ; [2H]C([2H])([2H])c1cccc(N2c3cccc4c3B(c3oc5ccccc5c32)c2cccc3c5c(ccc6c7ccccc7n(-c7ccccc7)c65)n-4c23)c1 ; [2H]C([2H])([2H])c1cccc(-n2c3ccccc3c3cc4c(cc32)c2cccc3c2n4-c2cccc4c2B3c2oc3ccccc3c2N4c2ccccc2)c1 ; [2H]C([2H])([2H])c1ccc2c(c1)c1c3c4ccccc4n(-c4ccccc4)c3cc3c1n2-c1cccc2c1B3c1oc3ccccc3c1N2c1ccccc1]

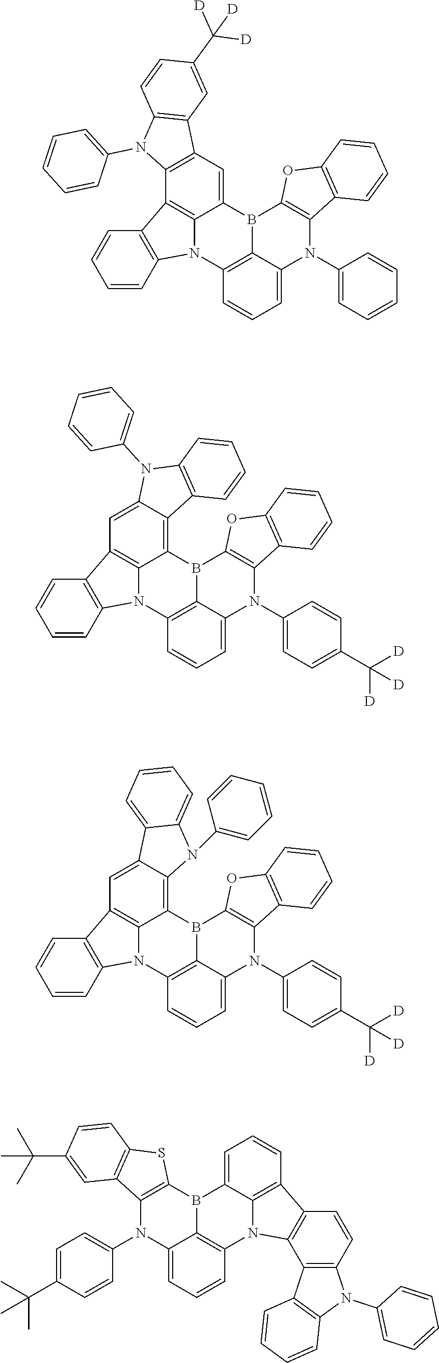 [SMILES: [2H]C([2H])([2H])c1ccc2c(c1)c1cc3c4c(c5ccccc5n4-c4cccc5c4B3c3oc4ccccc4c3N5c3ccccc3)c1n2-c1ccccc1 ; [2H]C([2H])([2H])c1ccc(N2c3cccc4c3B(c3oc5ccccc5c32)c2c3c5ccccc5n(-c5ccccc5)c3cc3c5ccccc5n-4c23)cc1 ; [2H]C([2H])([2H])c1ccc(N2c3cccc4c3B(c3oc5ccccc5c32)c2c3c(cc5c6ccccc6n-4c25)c2ccccc2n3-c2ccccc2)cc1 ; CC(C)(C)c1ccc(N2c3cccc4c3B(c3sc5ccc(C(C)(C)C)cc5c32)c2cccc3c5ccc6c(c7ccccc7n6-c6ccccc6)c5n-4c23)cc1]

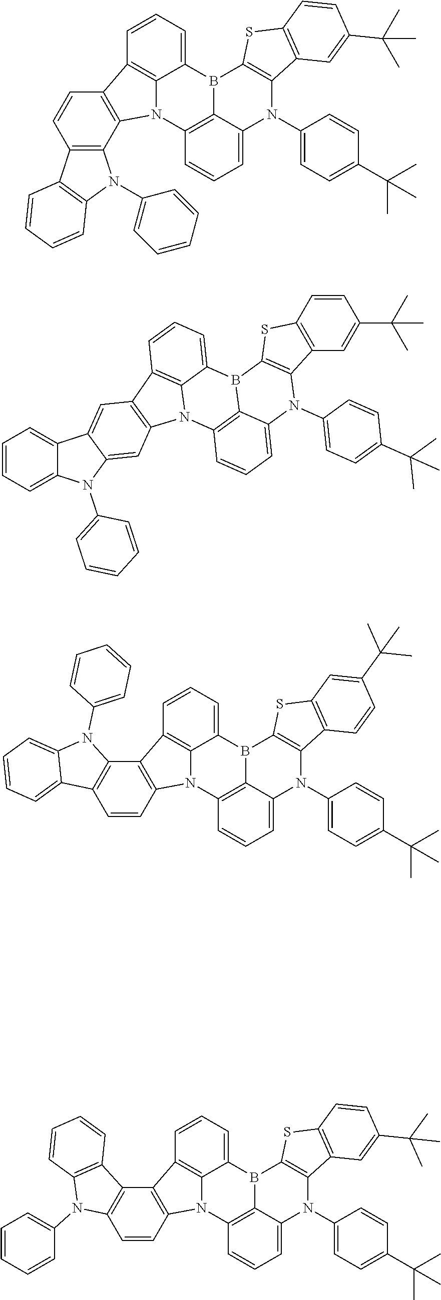 [SMILES: CC(C)(C)c1ccc(N2c3cccc4c3B(c3sc5ccc(C(C)(C)C)cc5c32)c2cccc3c5ccc6c7ccccc7n(-c7ccccc7)c6c5n-4c23)cc1 ; CC(C)(C)c1ccc(N2c3cccc4c3B(c3sc5ccc(C(C)(C)C)cc5c32)c2cccc3c5cc6c7ccccc7n(-c7ccccc7)c6cc5n-4c23)cc1 ; CC(C)(C)c1ccc(N2c3cccc4c3B(c3sc5cc(C(C)(C)C)ccc5c32)c2cccc3c5c(ccc6c7ccccc7n(-c7ccccc7)c65)n-4c23)cc1 ; CC(C)(C)c1ccc(N2c3cccc4c3B(c3sc5ccc(C(C)(C)C)cc5c32)c2cccc3c5c6c7ccccc7n(-c7ccccc7)c6ccc5n-4c23)cc1]

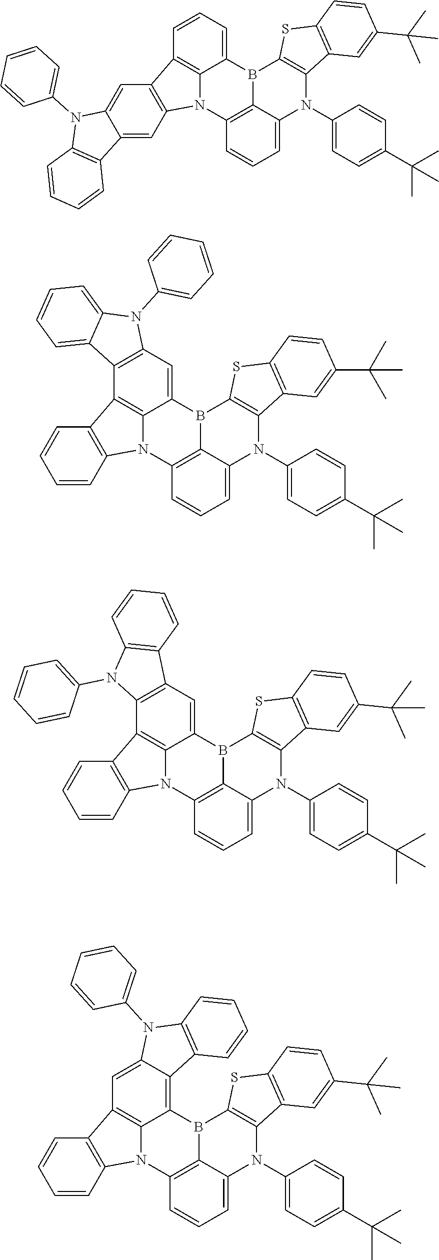 [SMILES: CC(C)(C)c1ccc(N2c3cccc4c3B(c3sc5ccc(C(C)(C)C)cc5c32)c2cccc3c5cc6c(cc5n-4c23)c2ccccc2n6-c2ccccc2)cc1 ; CC(C)(C)c1ccc(N2c3cccc4c3B(c3sc5ccc(C(C)(C)C)cc5c32)c2cc3c(c5ccccc5n3-c3ccccc3)c3c5ccccc5n-4c23)cc1 ; CC(C)(C)c1ccc(N2c3cccc4c3B(c3sc5ccc(C(C)(C)C)cc5c32)c2cc3c5ccccc5n(-c5ccccc5)c3c3c5ccccc5n-4c23)cc1 ; CC(C)(C)c1ccc(N2c3cccc4c3B(c3sc5ccc(C(C)(C)C)cc5c32)c2c3c5ccccc5n(-c5ccccc5)c3cc3c5ccccc5n-4c23)cc1]

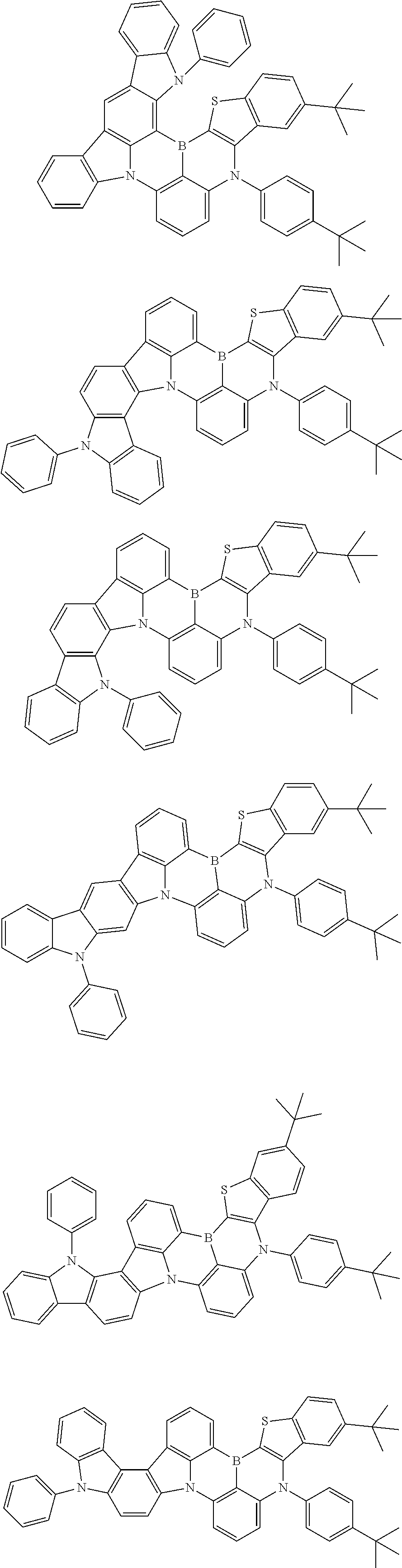

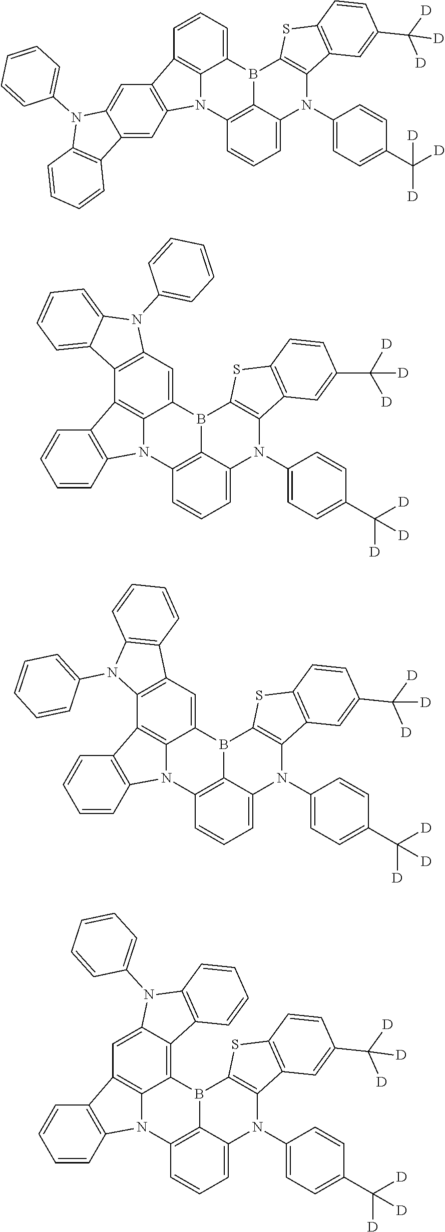 [SMILES: [2H]C([2H])([2H])c1ccc(N2c3cccc4c3B(c3sc5ccc(C([2H])([2H])[2H])cc5c32)c2cccc3c5cc6c(cc5n-4c23)c2ccccc2n6-c2ccccc2)cc1 ; [2H]C([2H])([2H])c1ccc(N2c3cccc4c3B(c3sc5ccc(C([2H])([2H])[2H])cc5c32)c2cc3c(c5ccccc5n3-c3ccccc3)c3c5ccccc5n-4c23)cc1 ; [2H]C([2H])([2H])c1ccc(N2c3cccc4c3B(c3sc5ccc(C([2H])([2H])[2H])cc5c32)c2cc3c5ccccc5n(-c5ccccc5)c3c3c5ccccc5n-4c23)cc1 ; [2H]C([2H])([2H])c1ccc(N2c3cccc4c3B(c3sc5ccc(C([2H])([2H])[2H])cc5c32)c2c3c5ccccc5n(-c5ccccc5)c3cc3c5ccccc5n-4c23)cc1]

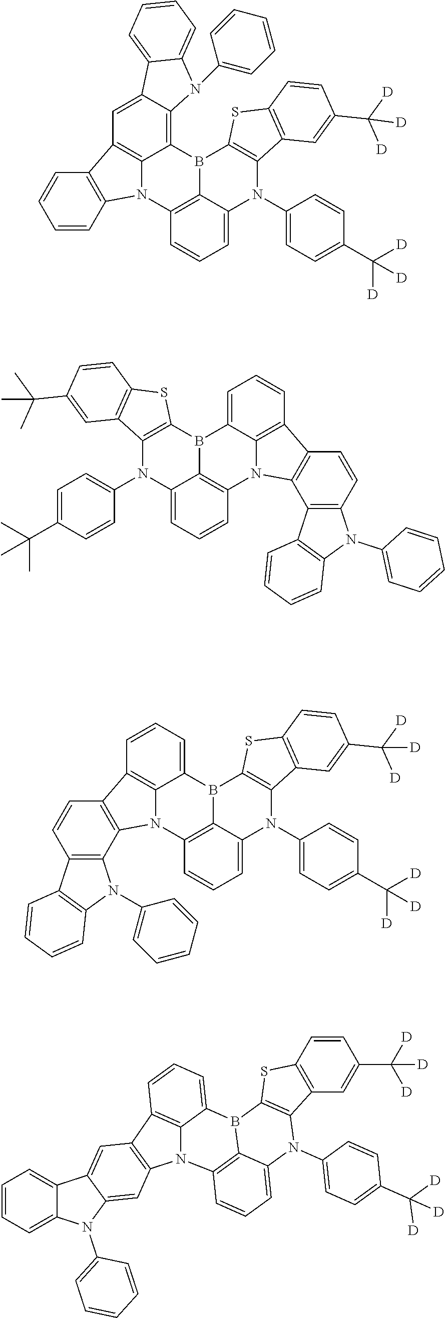 [SMILES: [2H]C([2H])([2H])c1ccc(N2c3cccc4c3B(c3sc5ccc(C([2H])([2H])[2H])cc5c32)c2c3c(cc5c6ccccc6n-4c25)c2ccccc2n3-c2ccccc2)cc1 ; CC(C)(C)c1ccc(N2c3cccc4c3B(c3sc5ccc(C(C)(C)C)cc5c32)c2cccc3c5ccc6c(c7ccccc7n6-c6ccccc6)c5n-4c23)cc1 ; [2H]C([2H])([2H])c1ccc(N2c3cccc4c3B(c3sc5ccc(C([2H])([2H])[2H])cc5c32)c2cccc3c5ccc6c7ccccc7n(-c7ccccc7)c6c5n-4c23)cc1 ; [2H]C([2H])([2H])c1ccc(N2c3cccc4c3B(c3sc5ccc(C([2H])([2H])[2H])cc5c32)c2cccc3c5cc6c7ccccc7n(-c7ccccc7)c6cc5n-4c23)cc1]

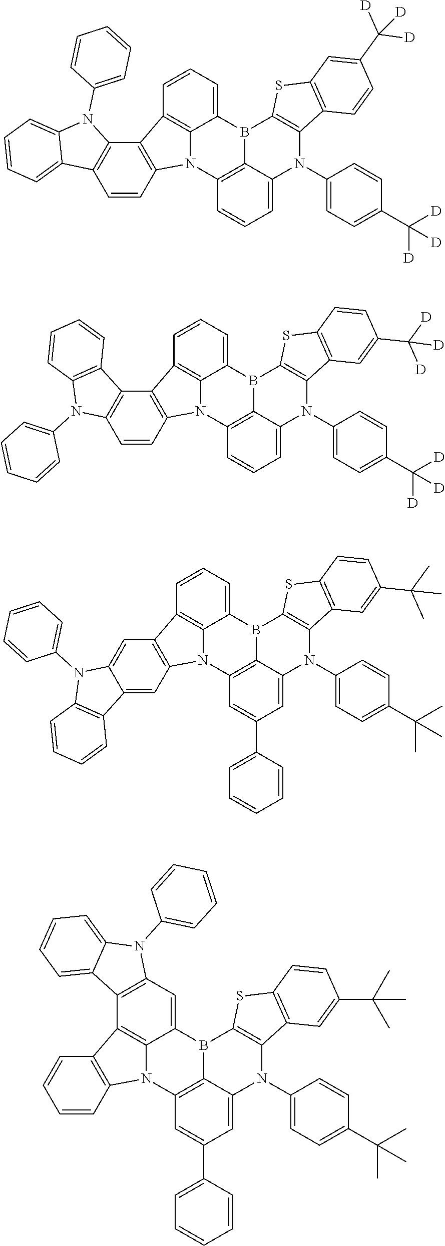 [SMILES: [2H]C([2H])([2H])c1ccc(N2c3cccc4c3B(c3sc5cc(C([2H])([2H])[2H])ccc5c32)c2cccc3c5c(ccc6c7ccccc7n(-c7ccccc7)c65)n-4c23)cc1 ; [2H]C([2H])([2H])c1ccc(N2c3cccc4c3B(c3sc5ccc(C([2H])([2H])[2H])cc5c32)c2cccc3c5c6c7ccccc7n(-c7ccccc7)c6ccc5n-4c23)cc1 ; CC(C)(C)c1ccc(N2c3cc(-c4ccccc4)cc4c3B(c3sc5ccc(C(C)(C)C)cc5c32)c2cccc3c5cc6c(cc5n-4c23)c2ccccc2n6-c2ccccc2)cc1 ; CC(C)(C)c1ccc(N2c3cc(-c4ccccc4)cc4c3B(c3sc5ccc(C(C)(C)C)cc5c32)c2cc3c(c5ccccc5n3-c3ccccc3)c3c5ccccc5n-4c23)cc1]

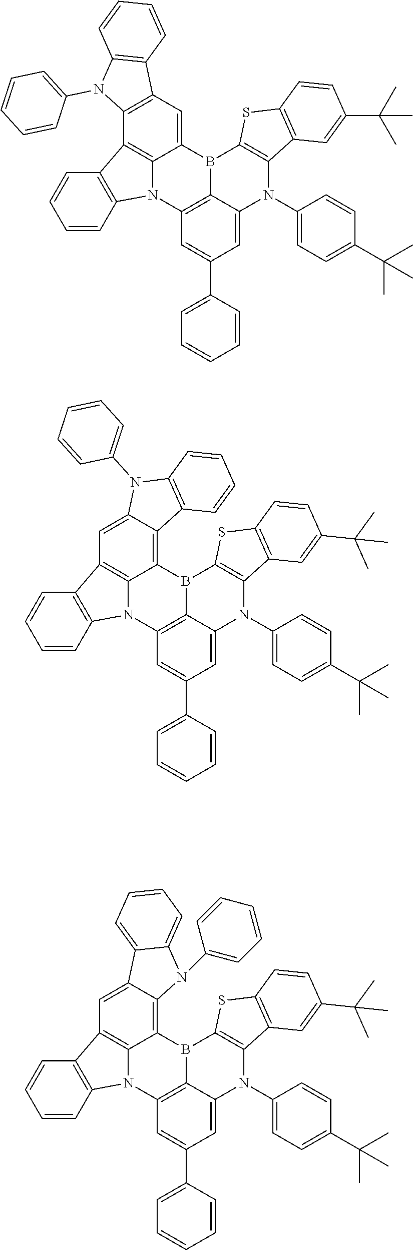 [SMILES: CC(C)(C)c1ccc(N2c3cc(-c4ccccc4)cc4c3B(c3sc5ccc(C(C)(C)C)cc5c32)c2cc3c5ccccc5n(-c5ccccc5)c3c3c5ccccc5n-4c23)cc1 ; CC(C)(C)c1ccc(N2c3cc(-c4ccccc4)cc4c3B(c3sc5ccc(C(C)(C)C)cc5c32)c2c3c5ccccc5n(-c5ccccc5)c3cc3c5ccccc5n-4c23)cc1 ; CC(C)(C)c1ccc(N2c3cc(-c4ccccc4)cc4c3B(c3sc5ccc(C(C)(C)C)cc5c32)c2c3c(cc5c6ccccc6n-4c25)c2ccccc2n3-c2ccccc2)cc1]

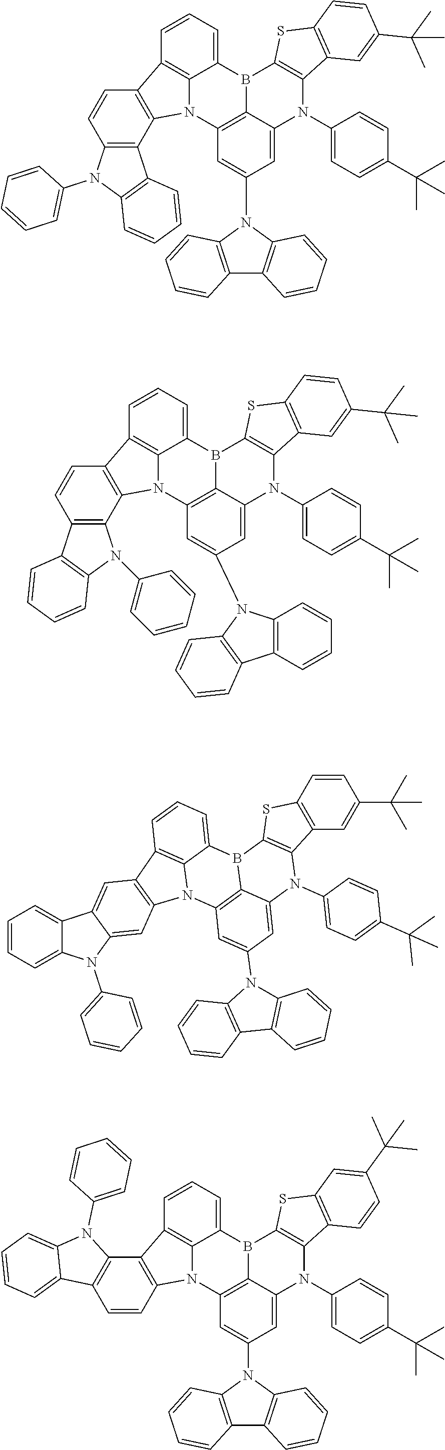 [SMILES: CC(C)(C)c1ccc(N2c3cc(-n4c5ccccc5c5ccccc54)cc4c3B(c3sc5ccc(C(C)(C)C)cc5c32)c2cccc3c5ccc6c(c7ccccc7n6-c6ccccc6)c5n-4c23)cc1 ; CC(C)(C)c1ccc(N2c3cc(-n4c5ccccc5c5ccccc54)cc4c3B(c3sc5ccc(C(C)(C)C)cc5c32)c2cccc3c5ccc6c7ccccc7n(-c7ccccc7)c6c5n-4c23)cc1 ; CC(C)(C)c1ccc(N2c3cc(-n4c5ccccc5c5ccccc54)cc4c3B(c3sc5ccc(C(C)(C)C)cc5c32)c2cccc3c5cc6c7ccccc7n(-c7ccccc7)c6cc5n-4c23)cc1 ; CC(C)(C)c1ccc(N2c3cc(-n4c5ccccc5c5ccccc54)cc4c3B(c3sc5cc(C(C)(C)C)ccc5c32)c2cccc3c5c(ccc6c7ccccc7n(-c7ccccc7)c65)n-4c23)cc1]

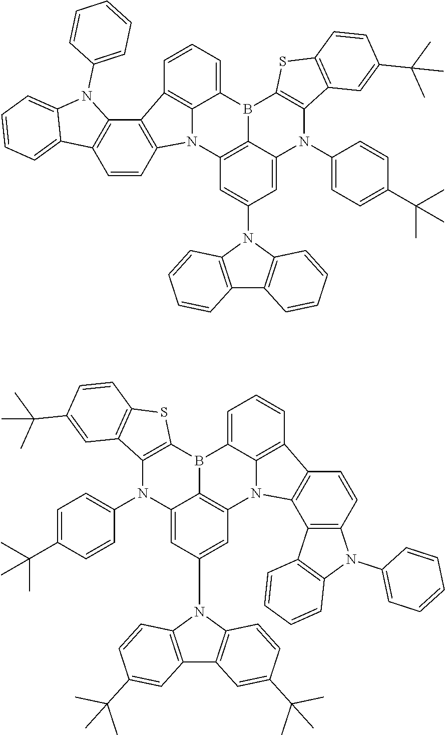

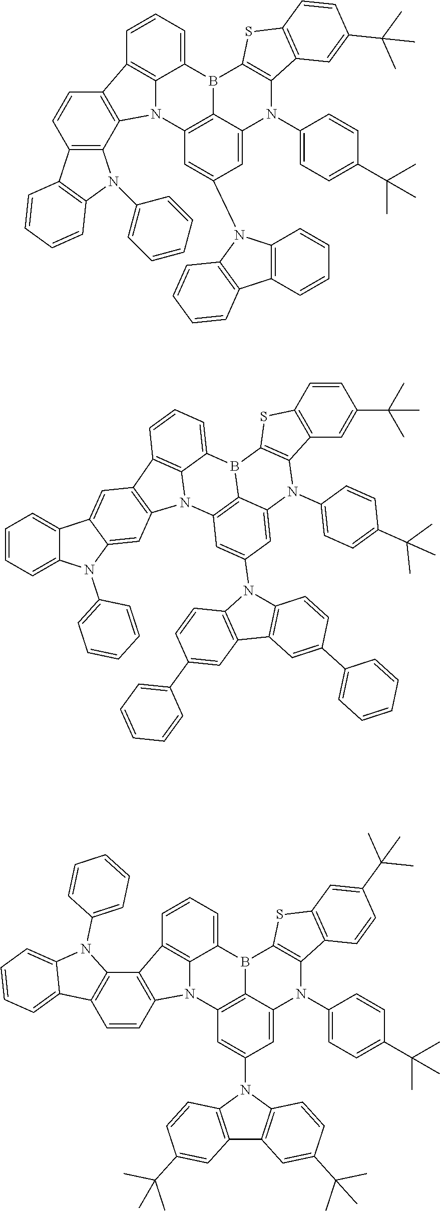 [SMILES: CC(C)(C)c1ccc(N2c3cc(-n4c5ccccc5c5ccccc54)cc4c3B(c3sc5ccc(C(C)(C)C)cc5c32)c2cccc3c5ccc6c7ccccc7n(-c7ccccc7)c6c5n-4c23)cc1 ; CC(C)(C)c1ccc(N2c3cc(-n4c5ccc(-c6ccccc6)cc5c5cc(-c6ccccc6)ccc54)cc4c3B(c3sc5ccc(C(C)(C)C)cc5c32)c2cccc3c5cc6c7ccccc7n(-c7ccccc7)c6cc5n-4c23)cc1 ; CC(C)(C)c1ccc(N2c3cc(-n4c5ccc(C(C)(C)C)cc5c5cc(C(C)(C)C)ccc54)cc4c3B(c3sc5cc(C(C)(C)C)ccc5c32)c2cccc3c5c(ccc6c7ccccc7n(-c7ccccc7)c65)n-4c23)cc1]

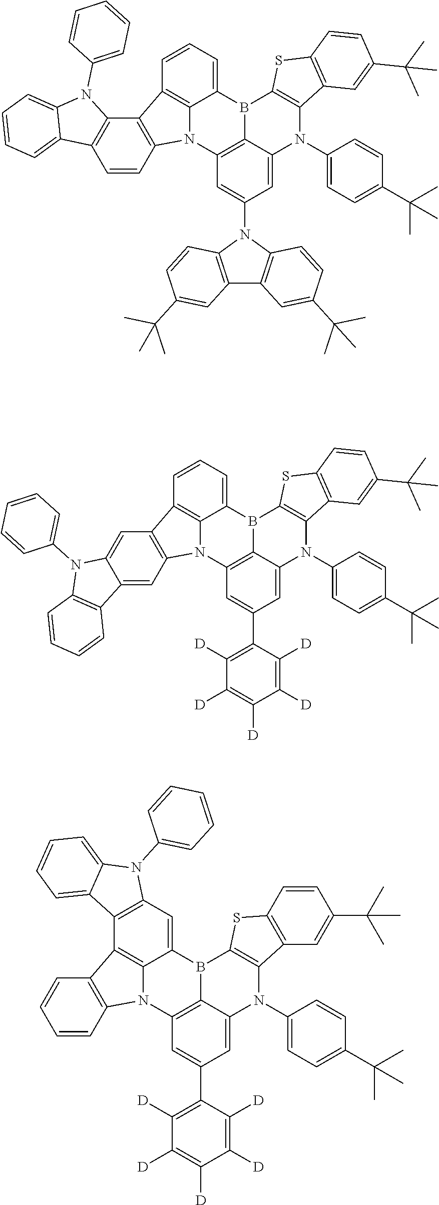 [SMILES: CC(C)(C)c1ccc(N2c3cc(-n4c5ccc(C(C)(C)C)cc5c5cc(C(C)(C)C)ccc54)cc4c3B(c3sc5ccc(C(C)(C)C)cc5c32)c2cccc3c5c(ccc6c7ccccc7n(-c7ccccc7)c65)n-4c23)cc1 ; [2H]c1c([2H])c([2H])c(-c2cc3c4c(c2)-n2c5cc6c7ccccc7n(-c7ccccc7)c6cc5c5cccc(c52)B4c2sc4ccc(C(C)(C)C)cc4c2N3c2ccc(C(C)(C)C)cc2)c([2H])c1[2H] ; [2H]c1c([2H])c([2H])c(-c2cc3c4c(c2)-n2c5ccccc5c5c6c7ccccc7n(-c7ccccc7)c6cc(c52)B4c2sc4ccc(C(C)(C)C)cc4c2N3c2ccc(C(C)(C)C)cc2)c([2H])c1[2H]]

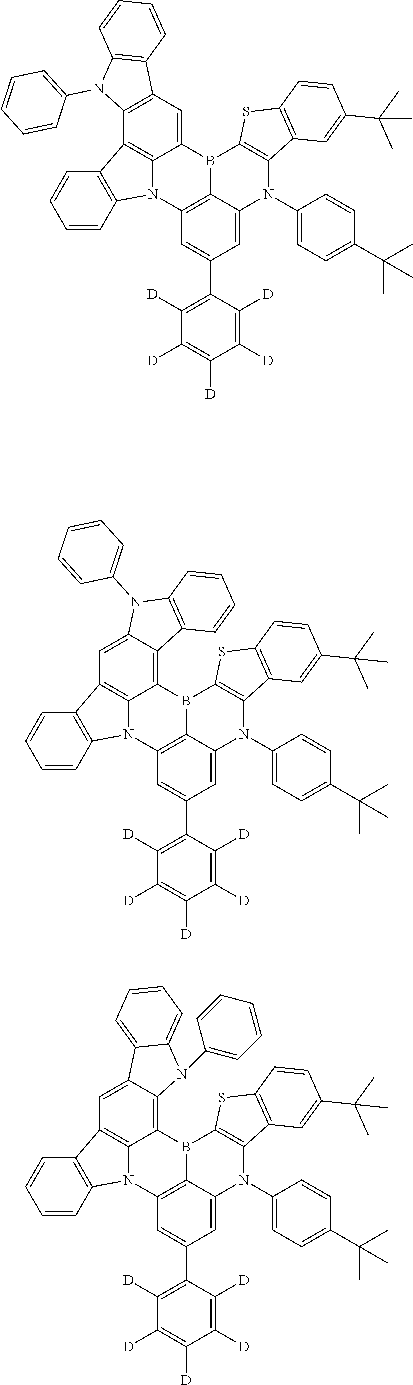 [SMILES: [2H]c1c([2H])c([2H])c(-c2cc3c4c(c2)-n2c5ccccc5c5c2c(cc2c6ccccc6n(-c6ccccc6)c25)B4c2sc4ccc(C(C)(C)C)cc4c2N3c2ccc(C(C)(C)C)cc2)c([2H])c1[2H] ; [2H]c1c([2H])c([2H])c(-c2cc3c4c(c2)-n2c5ccccc5c5cc6c(c(c52)B4c2sc4ccc(C(C)(C)C)cc4c2N3c2ccc(C(C)(C)C)cc2)c2ccccc2n6-c2ccccc2)c([2H])c1[2H] ; [2H]c1c([2H])c([2H])c(-c2cc3c4c(c2)-n2c5ccccc5c5cc6c7ccccc7n(-c7ccccc7)c6c(c52)B4c2sc4ccc(C(C)(C)C)cc4c2N3c2ccc(C(C)(C)C)cc2)c([2H])c1[2H]]

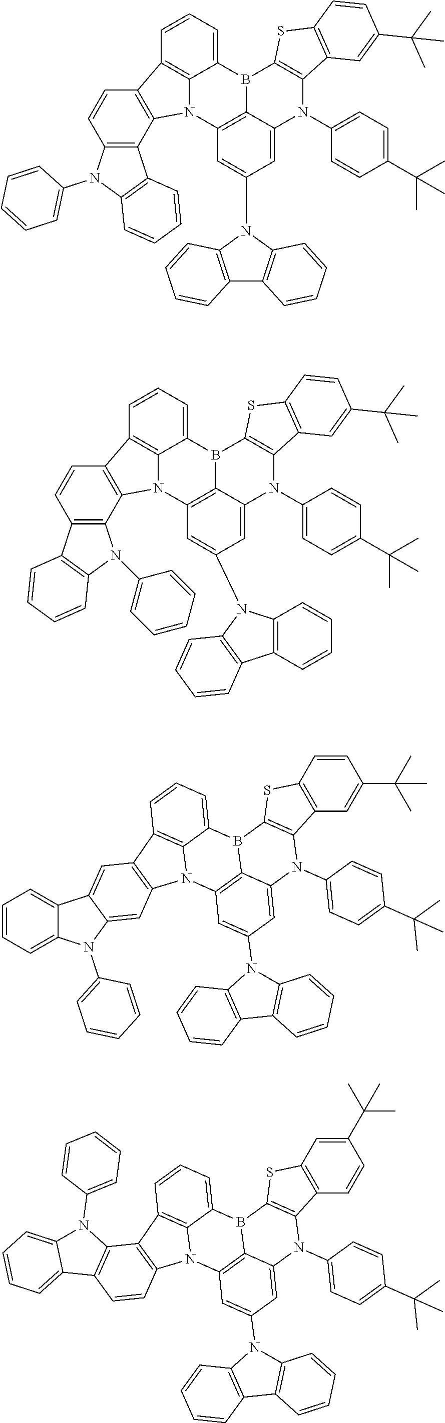 [SMILES: CC(C)(C)c1ccc(N2c3cc(-n4c5ccccc5c5ccccc54)cc4c3B(c3sc5ccc(C(C)(C)C)cc5c32)c2cccc3c5ccc6c(c7ccccc7n6-c6ccccc6)c5n-4c23)cc1 ; CC(C)(C)c1ccc(N2c3cc(-n4c5ccccc5c5ccccc54)cc4c3B(c3sc5ccc(C(C)(C)C)cc5c32)c2cccc3c5ccc6c7ccccc7n(-c7ccccc7)c6c5n-4c23)cc1 ; CC(C)(C)c1ccc(N2c3cc(-n4c5ccccc5c5ccccc54)cc4c3B(c3sc5ccc(C(C)(C)C)cc5c32)c2cccc3c5cc6c7ccccc7n(-c7ccccc7)c6cc5n-4c23)cc1 ; CC(C)(C)c1ccc(N2c3cc(-n4c5ccccc5c5ccccc54)cc4c3B(c3sc5cc(C(C)(C)C)ccc5c32)c2cccc3c5c(ccc6c7ccccc7n(-c7ccccc7)c65)n-4c23)cc1]

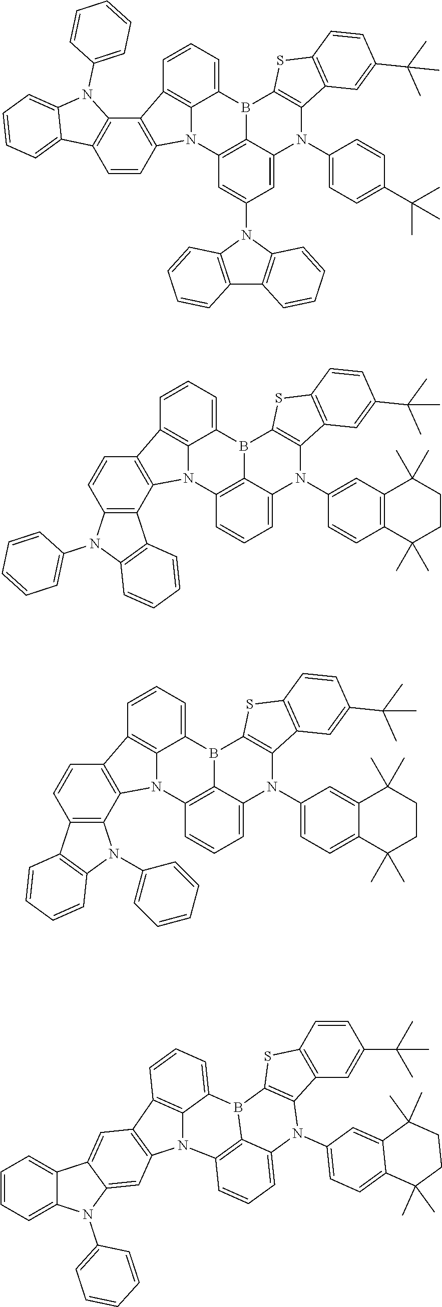 [SMILES: CC(C)(C)c1ccc(N2c3cc(-n4c5ccccc5c5ccccc54)cc4c3B(c3sc5ccc(C(C)(C)C)cc5c32)c2cccc3c5c(ccc6c7ccccc7n(-c7ccccc7)c65)n-4c23)cc1 ; CC(C)(C)c1ccc2sc3c(c2c1)N(c1ccc2c(c1)C(C)(C)CCC2(C)C)c1cccc2c1B3c1cccc3c4ccc5c(c6ccccc6n5-c5ccccc5)c4n-2c13 ; CC(C)(C)c1ccc2sc3c(c2c1)N(c1ccc2c(c1)C(C)(C)CCC2(C)C)c1cccc2c1B3c1cccc3c4ccc5c6ccccc6n(-c6ccccc6)c5c4n-2c13 ; CC(C)(C)c1ccc2sc3c(c2c1)N(c1ccc2c(c1)C(C)(C)CCC2(C)C)c1cccc2c1B3c1cccc3c4cc5c6ccccc6n(-c6ccccc6)c5cc4n-2c13]

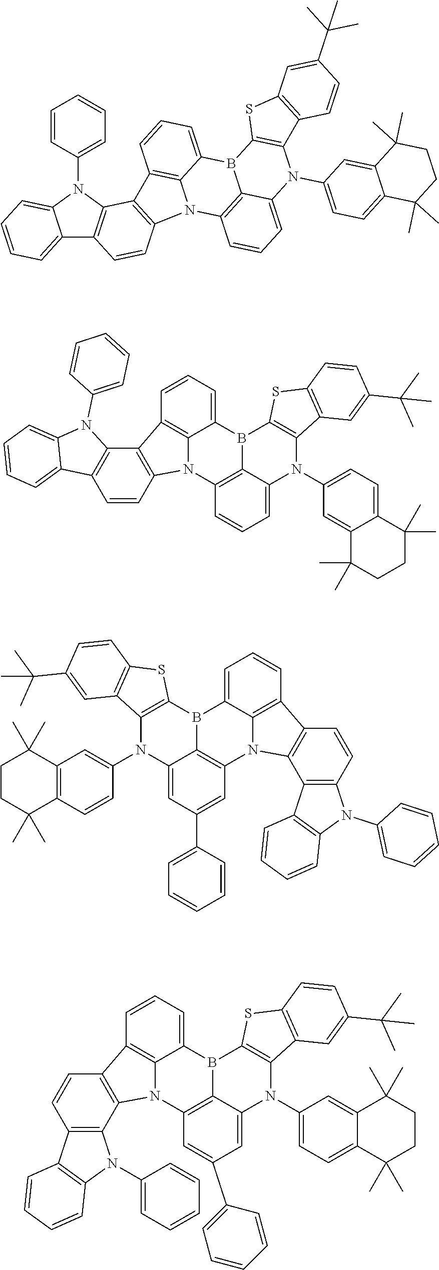 [SMILES: CC(C)(C)c1ccc2c3c(sc2c1)B1c2c(cccc2-n2c4ccc5c6ccccc6n(-c6ccccc6)c5c4c4cccc1c42)N3c1ccc2c(c1)C(C)(C)CCC2(C)C ; CC(C)(C)c1ccc2sc3c(c2c1)N(c1ccc2c(c1)C(C)(C)CCC2(C)C)c1cccc2c1B3c1cccc3c4c(ccc5c6ccccc6n(-c6ccccc6)c54)n-2c13 ; CC(C)(C)c1ccc2sc3c(c2c1)N(c1ccc2c(c1)C(C)(C)CCC2(C)C)c1cc(-c2ccccc2)cc2c1B3c1cccc3c4ccc5c(c6ccccc6n5-c5ccccc5)c4n-2c13 ; CC(C)(C)c1ccc2sc3c(c2c1)N(c1ccc2c(c1)C(C)(C)CCC2(C)C)c1cc(-c2ccccc2)cc2c1B3c1cccc3c4ccc5c6ccccc6n(-c6ccccc6)c5c4n-2c13]

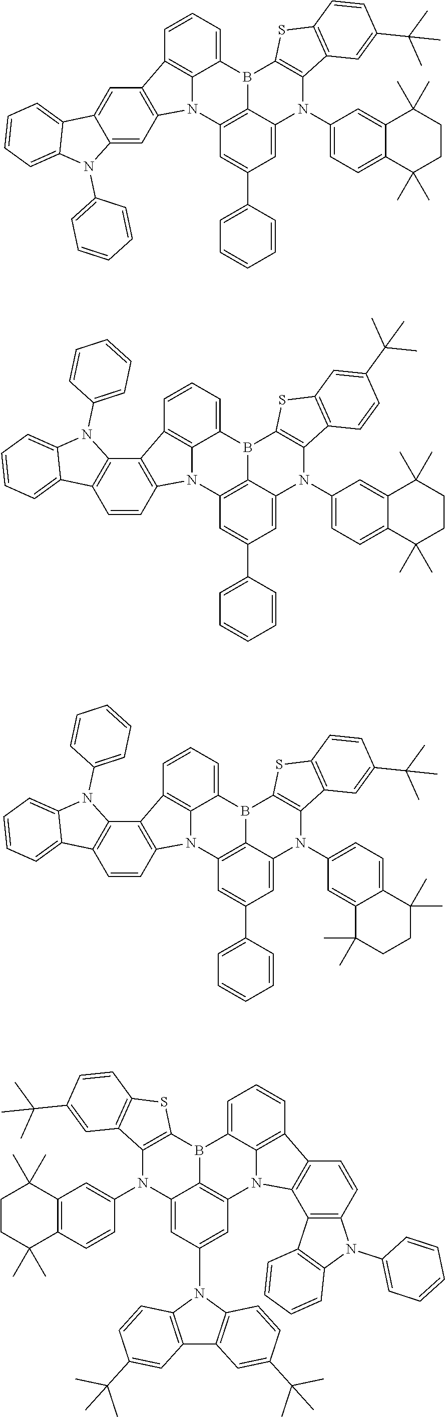

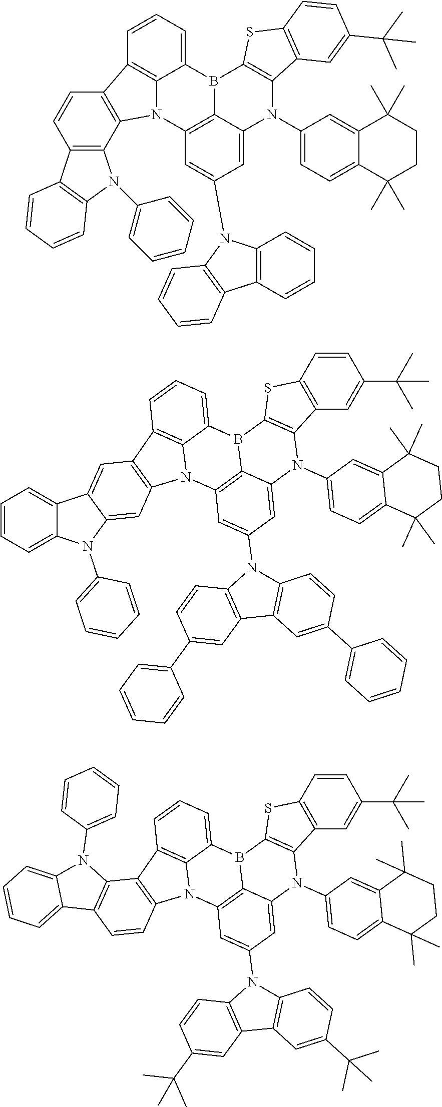 [SMILES: CC(C)(C)c1ccc2sc3c(c2c1)N(c1ccc2c(c1)C(C)(C)CCC2(C)C)c1cc(-n2c4ccccc4c4ccccc42)cc2c1B3c1cccc3c4ccc5c6ccccc6n(-c6ccccc6)c5c4n-2c13 ; CC(C)(C)c1ccc2sc3c(c2c1)N(c1ccc2c(c1)C(C)(C)CCC2(C)C)c1cc(-n2c4ccc(-c5ccccc5)cc4c4cc(-c5ccccc5)ccc42)cc2c1B3c1cccc3c4cc5c6ccccc6n(-c6ccccc6)c5cc4n-2c13 ; CC(C)(C)c1ccc2sc3c(c2c1)N(c1ccc2c(c1)C(C)(C)CCC2(C)C)c1cc(-n2c4ccc(C(C)(C)C)cc4c4cc(C(C)(C)C)ccc42)cc2c1B3c1cccc3c4c(ccc5c6ccccc6n(-c6ccccc6)c54)n-2c13]

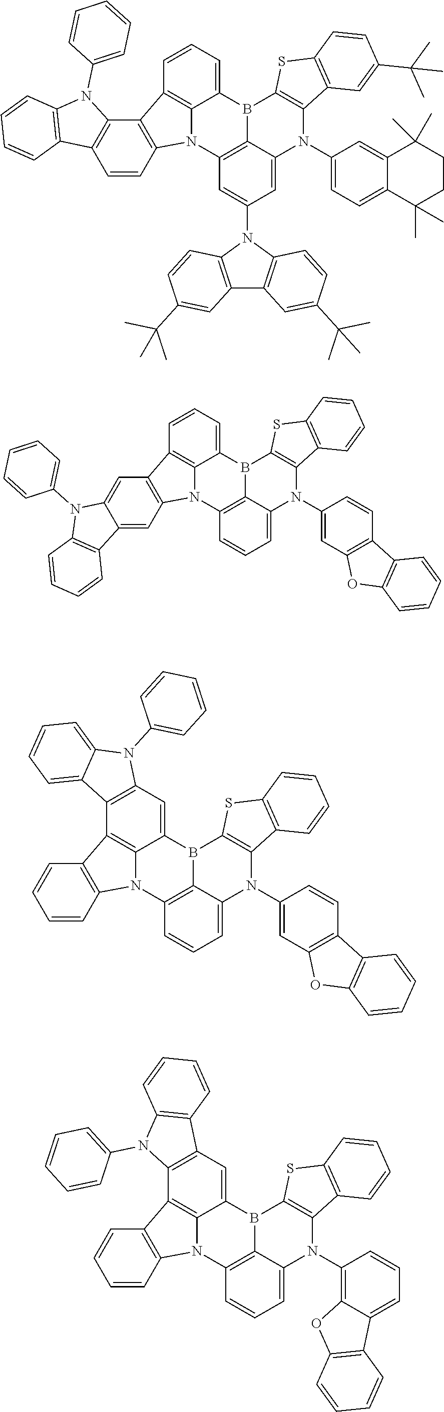

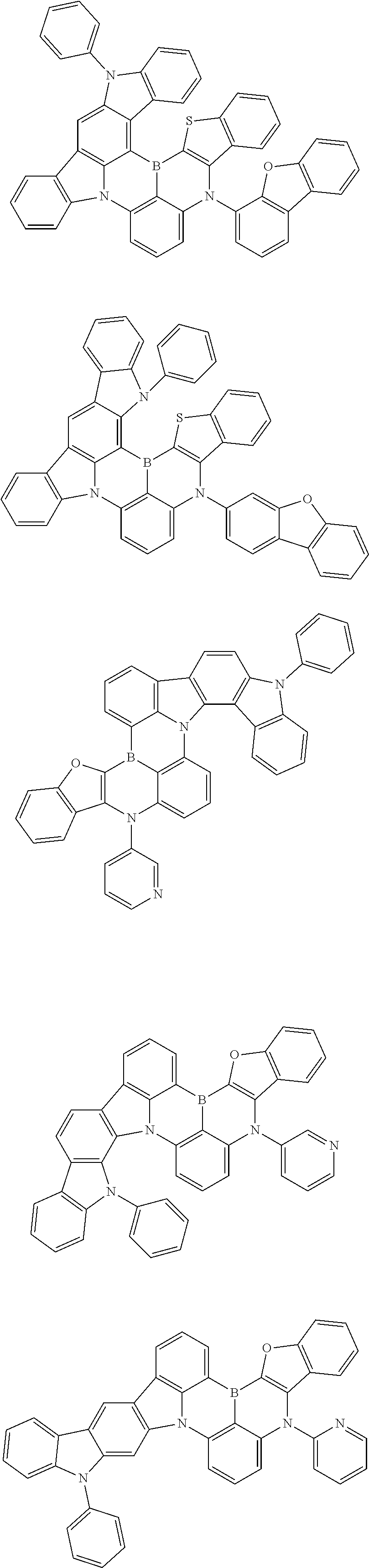

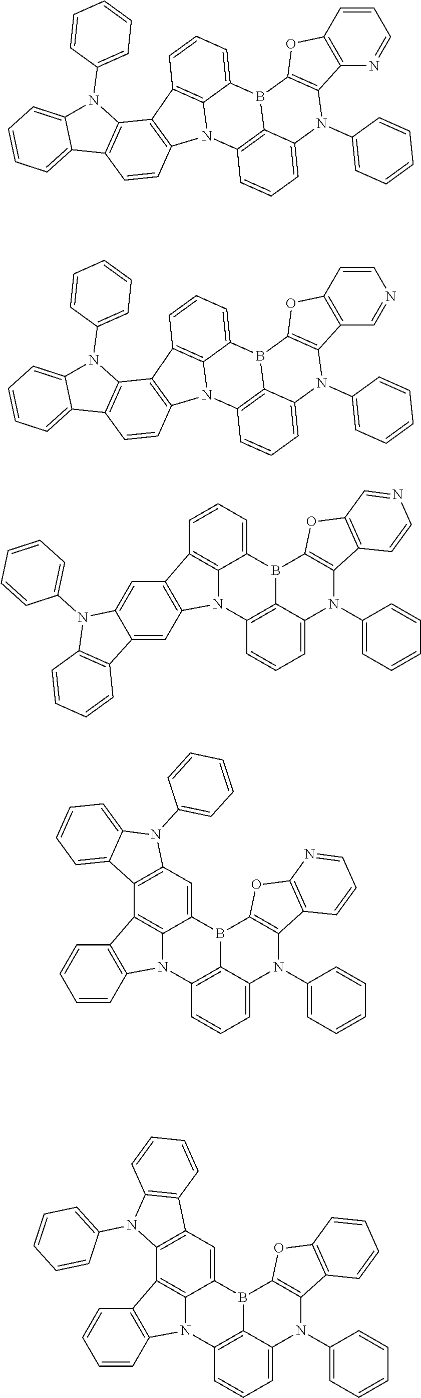 [SMILES: c1ccc(N2c3cccc4c3B(c3oc5cccnc5c32)c2cccc3c5c(ccc6c7ccccc7n(-c7ccccc7)c65)n-4c23)cc1 ; c1ccc(N2c3cccc4c3B(c3oc5ccncc5c32)c2cccc3c5c(ccc6c7ccccc7n(-c7ccccc7)c65)n-4c23)cc1 ; c1ccc(N2c3cccc4c3B(c3oc5cnccc5c32)c2cccc3c5cc6c(cc5n-4c23)c2ccccc2n6-c2ccccc2)cc1 ; c1ccc(N2c3cccc4c3B(c3oc5ncccc5c32)c2cc3c(c5ccccc5n3-c3ccccc3)c3c5ccccc5n-4c23)cc1 ; c1ccc(N2c3cccc4c3B(c3oc5ccccc5c32)c2cc3c5ccccc5n(-c5ccccc5)c3c3c5ccccc5n-4c23)cc1]

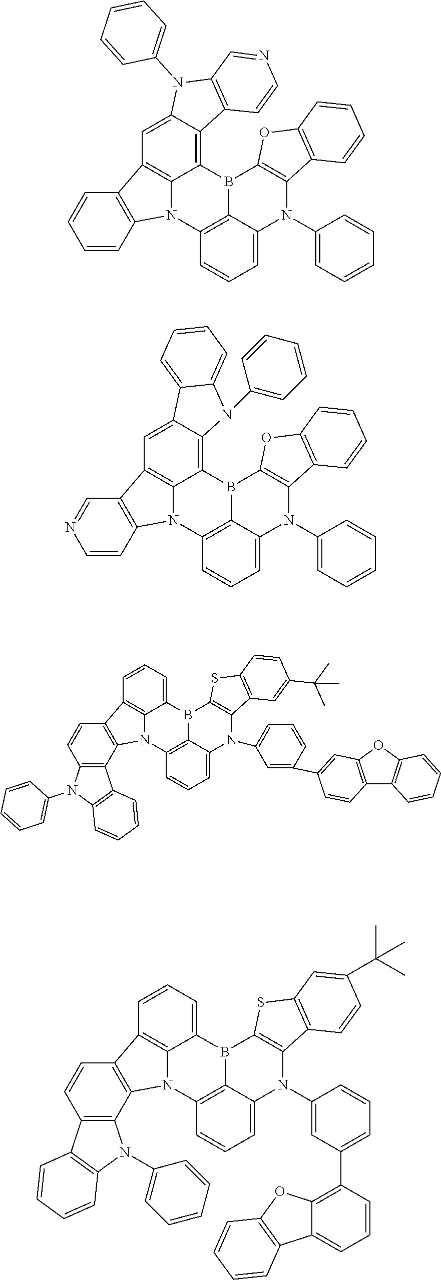 [SMILES: c1ccc(N2c3cccc4c3B(c3oc5ccccc5c32)c2c3c5ccncc5n(-c5ccccc5)c3cc3c5ccccc5n-4c23)cc1 ; c1ccc(N2c3cccc4c3B(c3oc5ccccc5c32)c2c3c(cc5c6cnccc6n-4c25)c2ccccc2n3-c2ccccc2)cc1 ; CC(C)(C)c1ccc2sc3c(c2c1)N(c1cccc(-c2ccc4c(c2)oc2ccccc24)c1)c1cccc2c1B3c1cccc3c4ccc5c(c6ccccc6n5-c5ccccc5)c4n-2c13 ; CC(C)(C)c1ccc2c3c(sc2c1)B1c2c(cccc2-n2c4c1cccc4c1ccc4c5ccccc5n(-c5ccccc5)c4c12)N3c1cccc(-c2cccc3c2oc2ccccc23)c1]

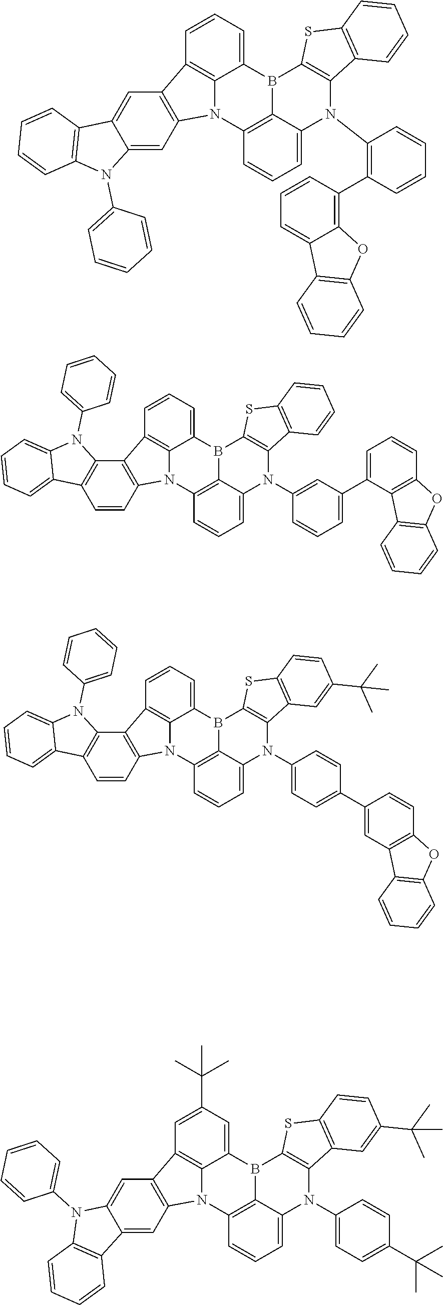 [SMILES: c1ccc(-n2c3ccccc3c3cc4c5cccc6c5n(c4cc32)-c2cccc3c2B6c2sc4ccccc4c2N3c2ccccc2-c2cccc3c2oc2ccccc23)cc1 ; c1ccc(-n2c3ccccc3c3ccc4c(c5cccc6c5n4-c4cccc5c4B6c4sc6ccccc6c4N5c4cccc(-c5cccc6oc7ccccc7c56)c4)c32)cc1 ; CC(C)(C)c1ccc2sc3c(c2c1)N(c1ccc(-c2ccc4oc5ccccc5c4c2)cc1)c1cccc2c1B3c1cccc3c4c(ccc5c6ccccc6n(-c6ccccc6)c54)n-2c13 ; CC(C)(C)c1ccc(N2c3cccc4c3B(c3sc5ccc(C(C)(C)C)cc5c32)c2cc(C(C)(C)C)cc3c5cc6c(cc5n-4c23)c2ccccc2n6-c2ccccc2)cc1]

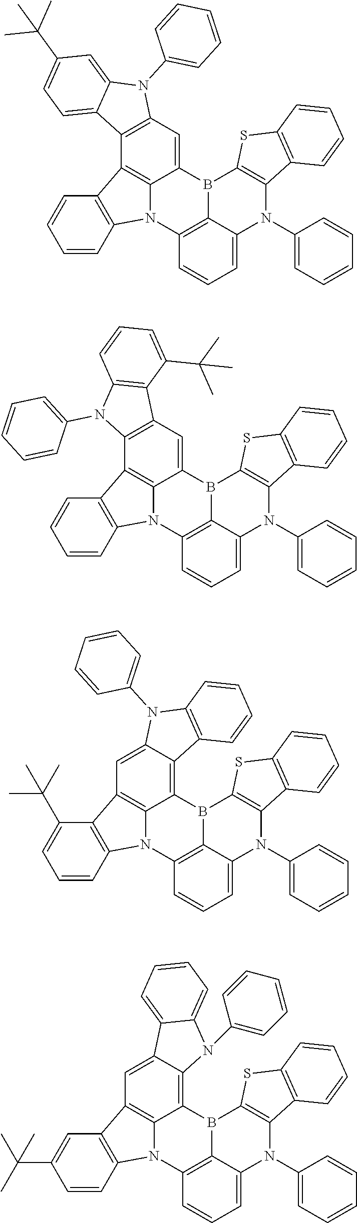 [SMILES: CC(C)(C)c1ccc2c3c4c5ccccc5n5c4c(cc3n(-c3ccccc3)c2c1)B1c2sc3ccccc3c2N(c2ccccc2)c2cccc-5c21 ; CC(C)(C)c1cccc2c1c1cc3c4c(c5ccccc5n4-c4cccc5c4B3c3sc4ccccc4c3N5c3ccccc3)c1n2-c1ccccc1 ; CC(C)(C)c1cccc2c1c1cc3c(c4c1n2-c1cccc2c1B4c1sc4ccccc4c1N2c1ccccc1)c1ccccc1n3-c1ccccc1 ; CC(C)(C)c1ccc2c(c1)c1cc3c4ccccc4n(-c4ccccc4)c3c3c1n2-c1cccc2c1B3c1sc3ccccc3c1N2c1ccccc1]

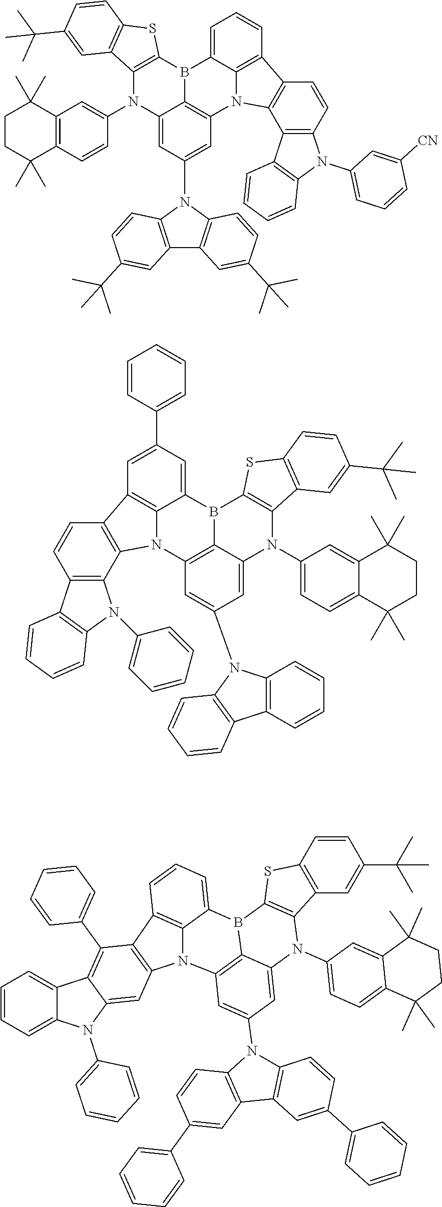 [SMILES: CC(C)(C)c1ccc2sc3c(c2c1)N(c1ccc2c(c1)C(C)(C)CCC2(C)C)c1cc(-n2c4ccc(C(C)(C)C)cc4c4cc(C(C)(C)C)ccc42)cc2c1B3c1cccc3c4ccc5c(c6ccccc6n5-c5cccc(C#N)c5)c4n-2c13 ; CC(C)(C)c1ccc2sc3c(c2c1)N(c1ccc2c(c1)C(C)(C)CCC2(C)C)c1cc(-n2c4ccccc4c4ccccc42)cc2c1B3c1cc(-c3ccccc3)cc3c4ccc5c6ccccc6n(-c6ccccc6)c5c4n-2c13 ; CC(C)(C)c1ccc2sc3c(c2c1)N(c1ccc2c(c1)C(C)(C)CCC2(C)C)c1cc(-n2c4ccc(-c5ccccc5)cc4c4cc(-c5ccccc5)ccc42)cc2c1B3c1cccc3c4c(-c5ccccc5)c5c6ccccc6n(-c6ccccc6)c5cc4n-2c13]

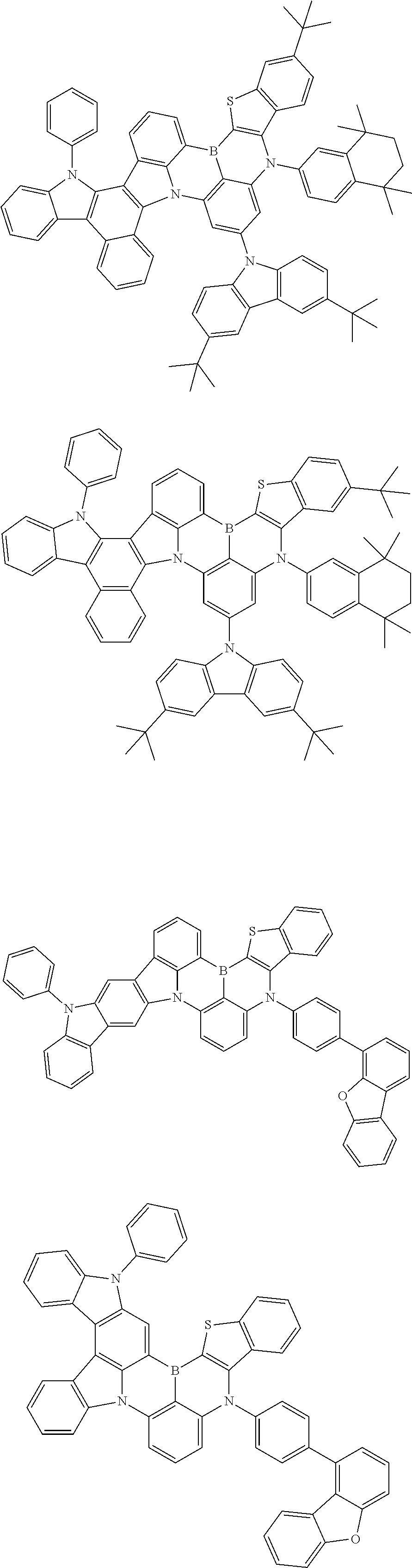

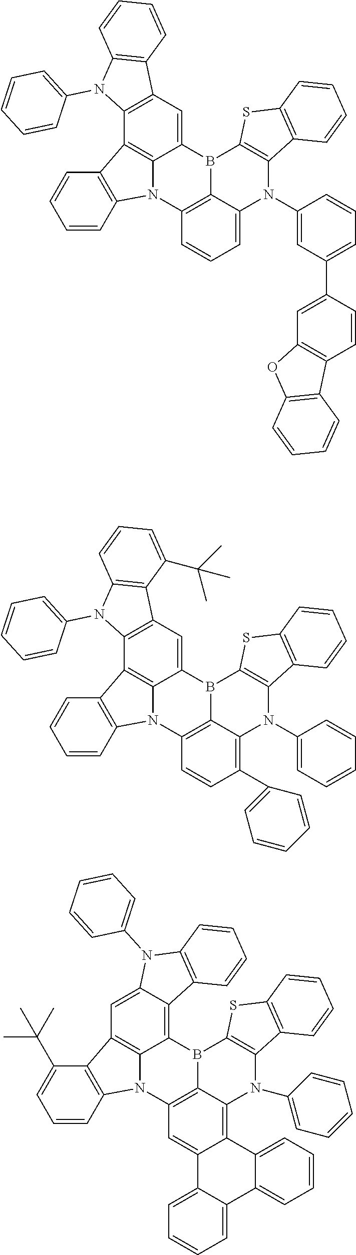 [SMILES: c1ccc(-n2c3ccccc3c3cc4c5c(c6ccccc6n5-c5cccc6c5B4c4sc5ccccc5c4N6c4cccc(-c5ccc6c(c5)oc5ccccc56)c4)c32)cc1 ; CC(C)(C)c1cccc2c1c1cc3c4c(c5ccccc5n4-c4ccc(-c5ccccc5)c5c4B3c3sc4ccccc4c3N5c3ccccc3)c1n2-c1ccccc1 ; CC(C)(C)c1cccc2c1c1cc3c(c4c1n2-c1cc2c5ccccc5c5ccccc5c2c2c1B4c1sc4ccccc4c1N2c1ccccc1)c1ccccc1n3-c1ccccc1]

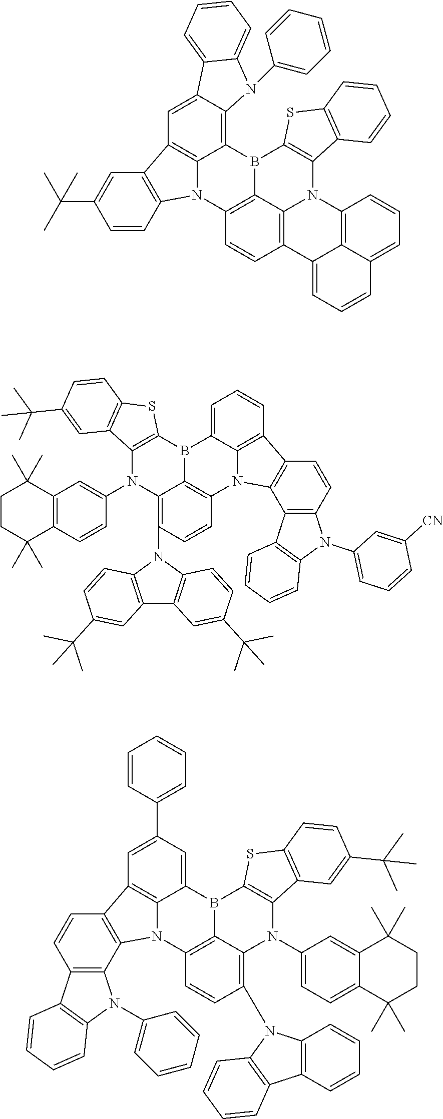 [SMILES: CC(C)(C)c1ccc2c(c1)c1cc3c4ccccc4n(-c4ccccc4)c3c3c1n2-c1ccc2c4c1B3c1sc3ccccc3c1N4c1cccc3cccc-2c13 ; CC(C)(C)c1ccc2sc3c(c2c1)N(c1ccc2c(c1)C(C)(C)CCC2(C)C)c1c(-n2c4ccc(C(C)(C)C)cc4c4cc(C(C)(C)C)ccc42)ccc2c1B3c1cccc3c4ccc5c(c6ccccc6n5-c5cccc(C#N)c5)c4n-2c13 ; CC(C)(C)c1ccc2sc3c(c2c1)N(c1ccc2c(c1)C(C)(C)CCC2(C)C)c1c(-n2c4ccccc4c4ccccc42)ccc2c1B3c1cc(-c3ccccc3)cc3c4ccc5c6ccccc6n(-c6ccccc6)c5c4n-2c13]

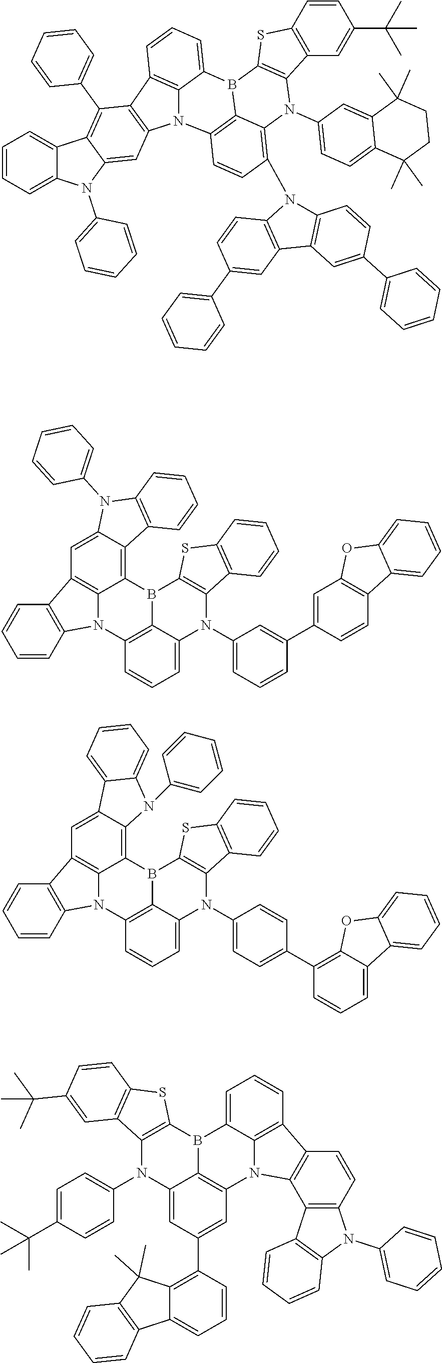

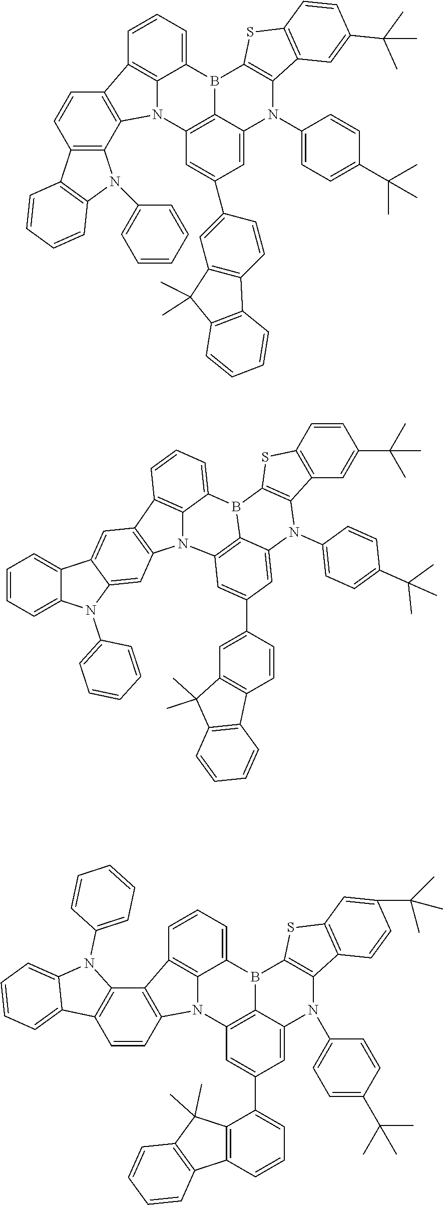 [SMILES: CC(C)(C)c1ccc(N2c3cc(-c4ccc5c(c4)C(C)(C)c4ccccc4-5)cc4c3B(c3sc5ccc(C(C)(C)C)cc5c32)c2cccc3c5ccc6c7ccccc7n(-c7ccccc7)c6c5n-4c23)cc1 ; CC(C)(C)c1ccc(N2c3cc(-c4ccc5c(c4)C(C)(C)c4ccccc4-5)cc4c3B(c3sc5ccc(C(C)(C)C)cc5c32)c2cccc3c5cc6c7ccccc7n(-c7ccccc7)c6cc5n-4c23)cc1 ; CC(C)(C)c1ccc(N2c3cc(-c4cccc5c4C(C)(C)c4ccccc4-5)cc4c3B(c3sc5cc(C(C)(C)C)ccc5c32)c2cccc3c5c(ccc6c7ccccc7n(-c7ccccc7)c65)n-4c23)cc1]

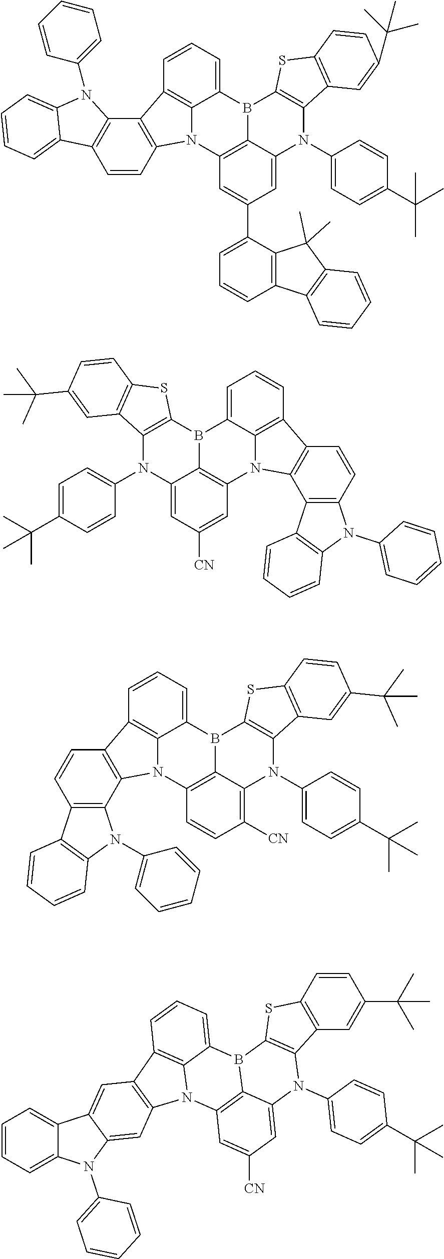

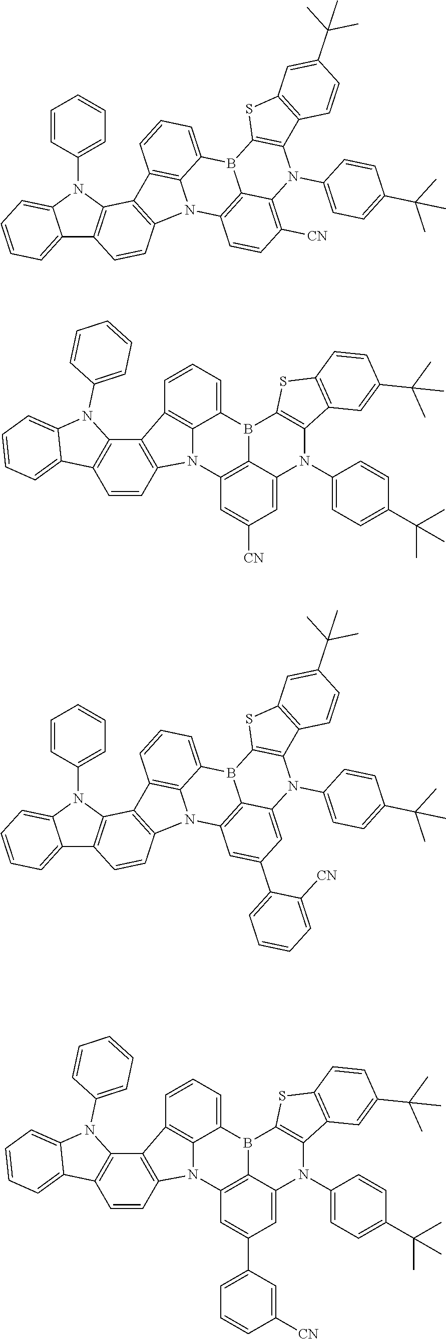 [SMILES: CC(C)(C)c1ccc(N2c3c(C#N)ccc4c3B(c3sc5cc(C(C)(C)C)ccc5c32)c2cccc3c5c(ccc6c7ccccc7n(-c7ccccc7)c65)n-4c23)cc1 ; CC(C)(C)c1ccc(N2c3cc(C#N)cc4c3B(c3sc5ccc(C(C)(C)C)cc5c32)c2cccc3c5c(ccc6c7ccccc7n(-c7ccccc7)c65)n-4c23)cc1 ; CC(C)(C)c1ccc(N2c3cc(-c4ccccc4C#N)cc4c3B(c3sc5cc(C(C)(C)C)ccc5c32)c2cccc3c5c(ccc6c7ccccc7n(-c7ccccc7)c65)n-4c23)cc1 ; CC(C)(C)c1ccc(N2c3cc(-c4cccc(C#N)c4)cc4c3B(c3sc5ccc(C(C)(C)C)cc5c32)c2cccc3c5c(ccc6c7ccccc7n(-c7ccccc7)c65)n-4c23)cc1]

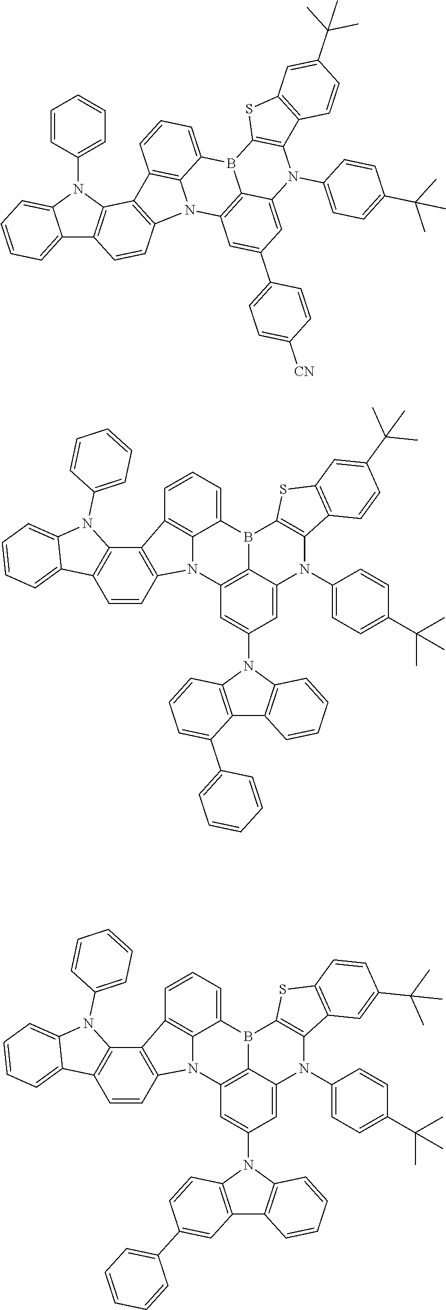 [SMILES: CC(C)(C)c1ccc(N2c3cc(-c4ccc(C#N)cc4)cc4c3B(c3sc5cc(C(C)(C)C)ccc5c32)c2cccc3c5c(ccc6c7ccccc7n(-c7ccccc7)c65)n-4c23)cc1 ; CC(C)(C)c1ccc(N2c3cc(-n4c5ccccc5c5c(-c6ccccc6)cccc54)cc4c3B(c3sc5cc(C(C)(C)C)ccc5c32)c2cccc3c5c(ccc6c7ccccc7n(-c7ccccc7)c65)n-4c23)cc1 ; CC(C)(C)c1ccc(N2c3cc(-n4c5ccccc5c5cc(-c6ccccc6)ccc54)cc4c3B(c3sc5ccc(C(C)(C)C)cc5c32)c2cccc3c5c(ccc6c7ccccc7n(-c7ccccc7)c65)n-4c23)cc1]

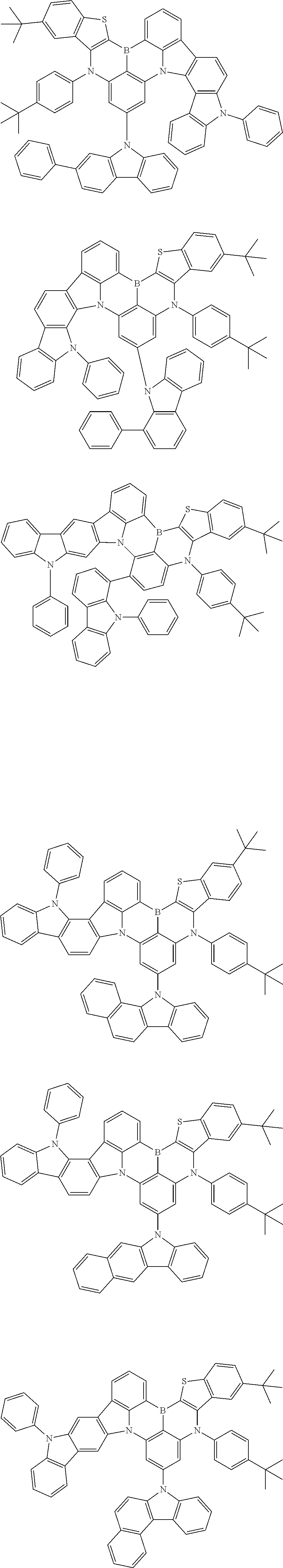

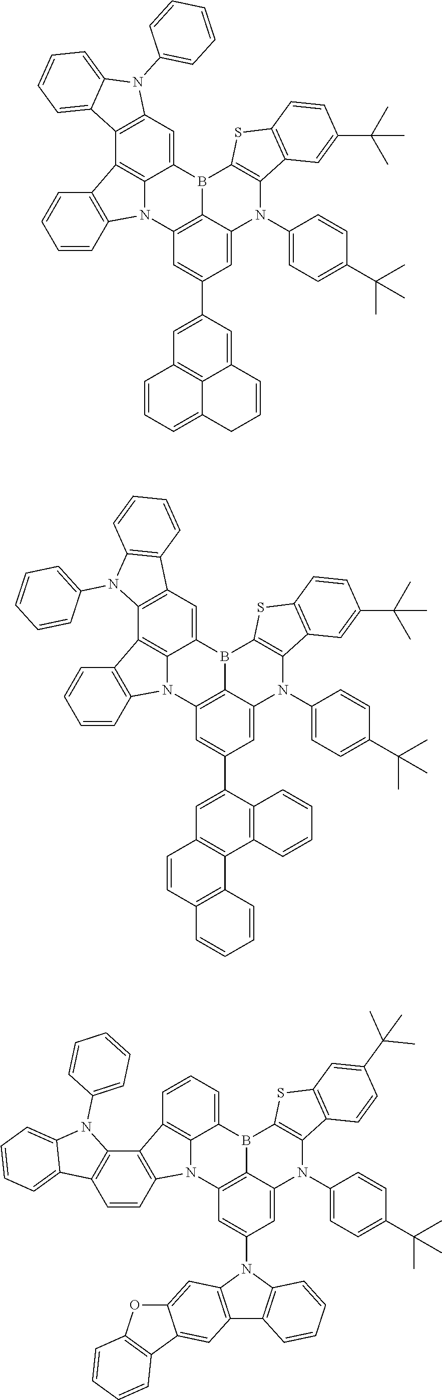 [SMILES: CC(C)(C)c1ccc(N2c3cc(-c4cc5c6c(cccc6c4)CC=C5)cc4c3B(c3sc5ccc(C(C)(C)C)cc5c32)c2cc3c(c5ccccc5n3-c3ccccc3)c3c5ccccc5n-4c23)cc1 ; CC(C)(C)c1ccc(N2c3cc(-c4cc5ccc6ccccc6c5c5ccccc45)cc4c3B(c3sc5ccc(C(C)(C)C)cc5c32)c2cc3c5ccccc5n(-c5ccccc5)c3c3c5ccccc5n-4c23)cc1 ; CC(C)(C)c1ccc(N2c3cc(-n4c5ccccc5c5cc6c(cc54)oc4ccccc46)cc4c3B(c3sc5cc(C(C)(C)C)ccc5c32)c2cccc3c5c(ccc6c7ccccc7n(-c7ccccc7)c65)n-4c23)cc1]

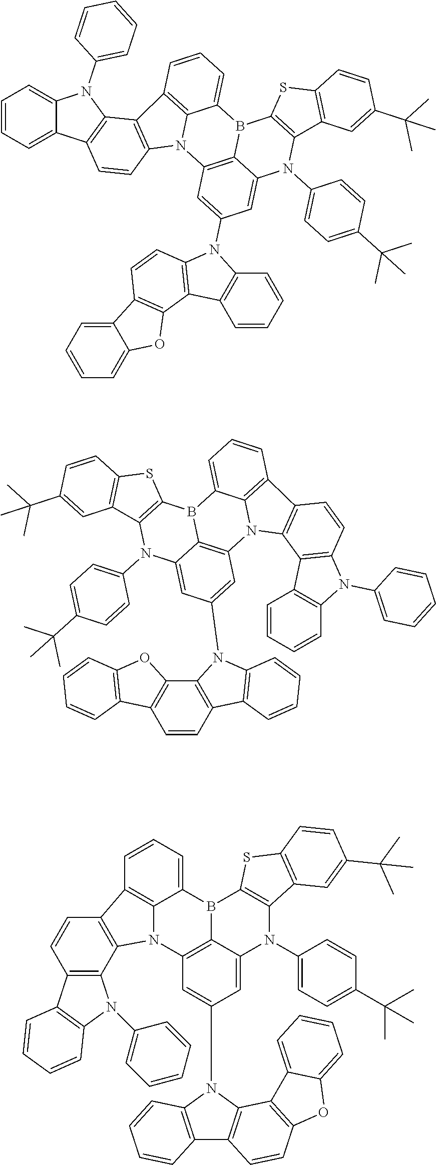

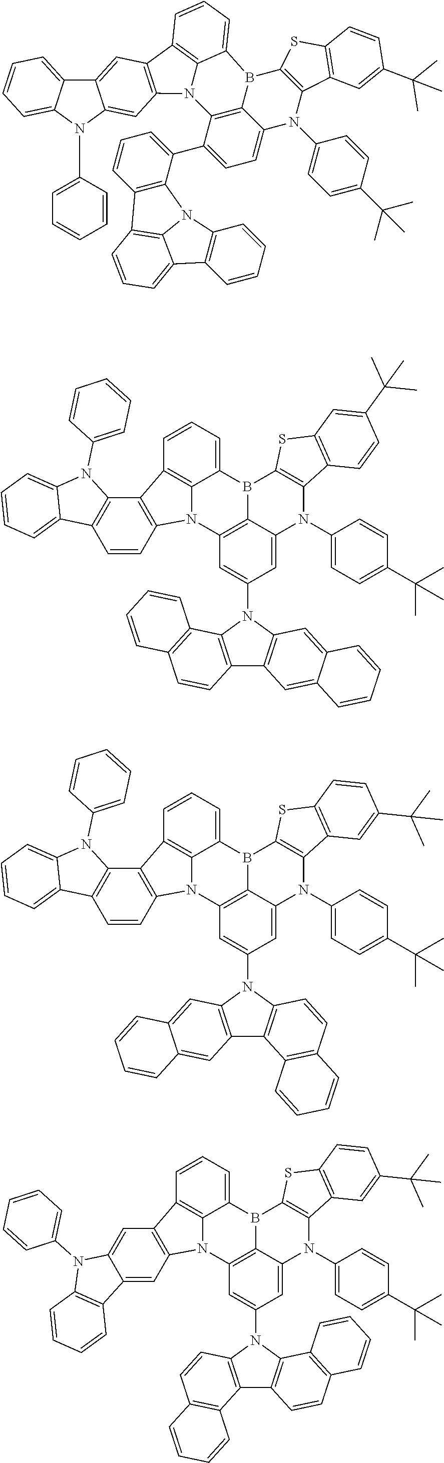

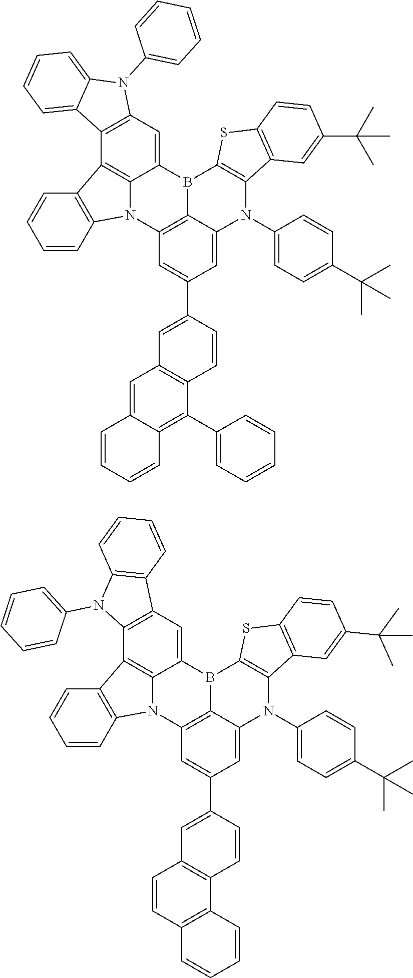

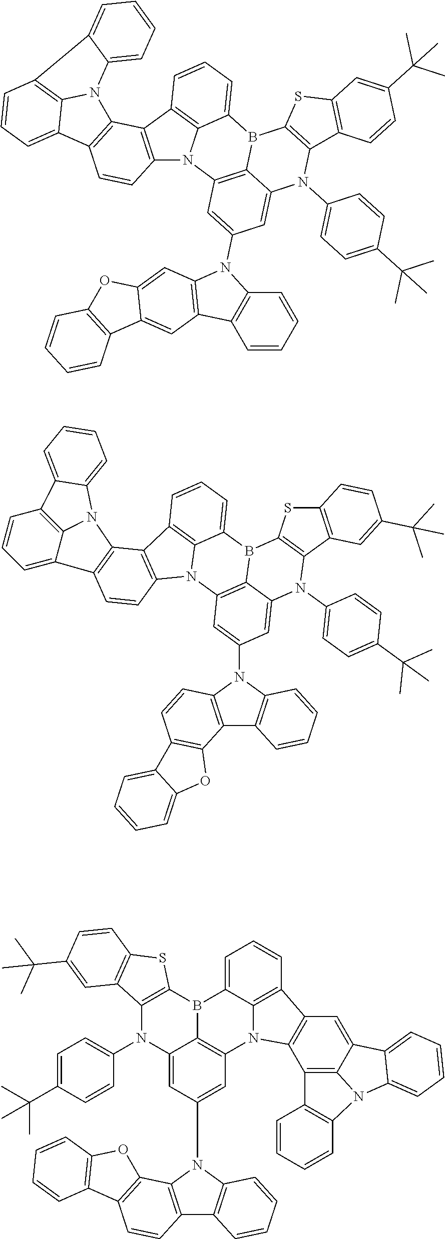

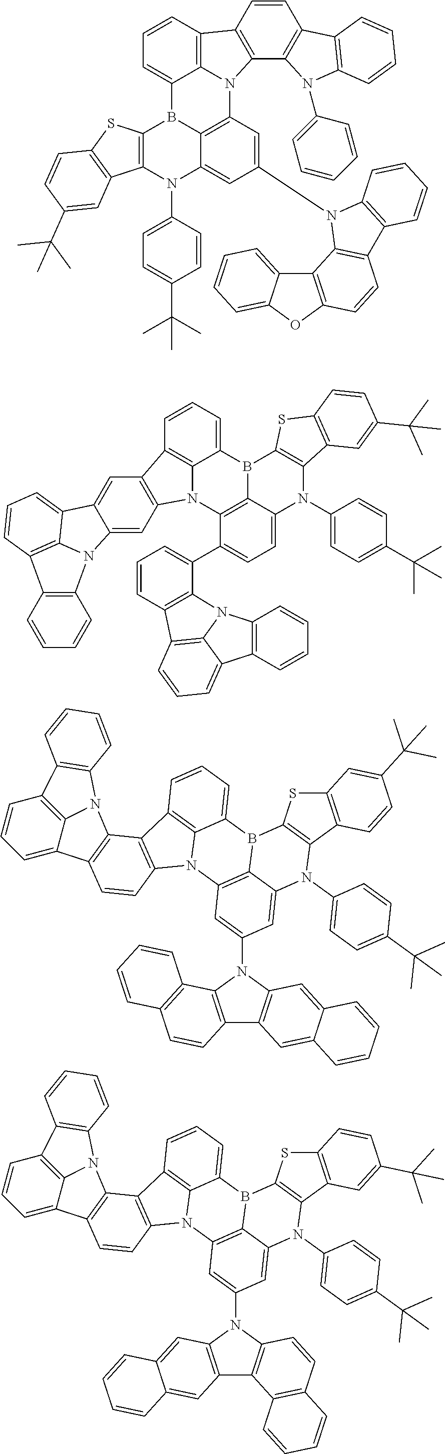

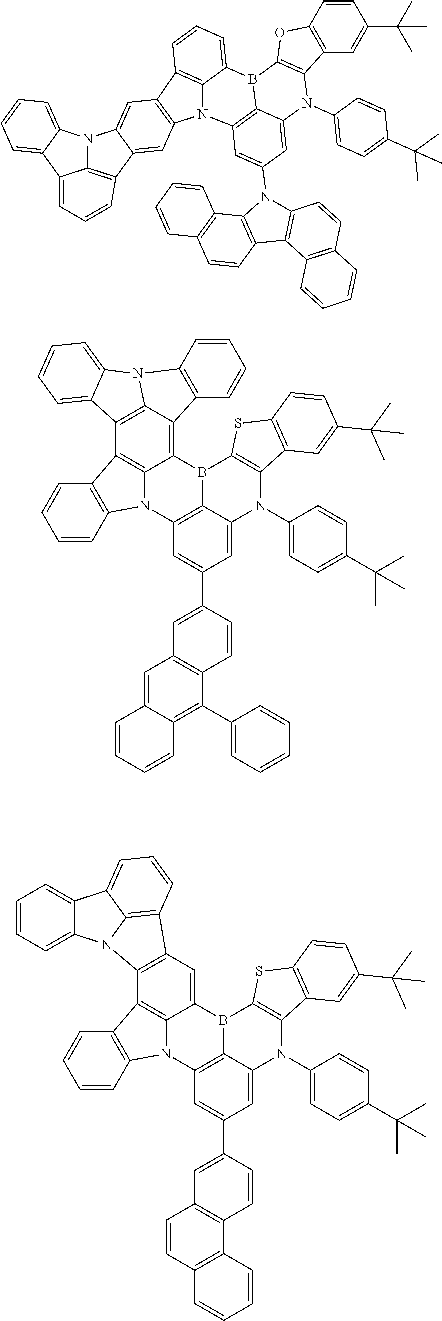 [SMILES: CC(C)(C)c1ccc(N2c3cc(-n4c5ccc6ccccc6c5c5ccc6ccccc6c54)cc4c3B(c3oc5ccc(C(C)(C)C)cc5c32)c2cccc3c5cc6c(cc5n-4c23)c2cccc3c4ccccc4n6c32)cc1 ; CC(C)(C)c1ccc(N2c3cc(-c4ccc5c(-c6ccccc6)c6ccccc6cc5c4)cc4c3B(c3sc5ccc(C(C)(C)C)cc5c32)c2c3c5ccccc5n5c6ccccc6c(c6c7ccccc7n-4c26)c35)cc1 ; CC(C)(C)c1ccc(N2c3cc(-c4ccc5c(ccc6ccccc65)c4)cc4c3B(c3sc5ccc(C(C)(C)C)cc5c32)c2cc3c5cccc6c7ccccc7n(c65)c3c3c5ccccc5n-4c23)cc1]

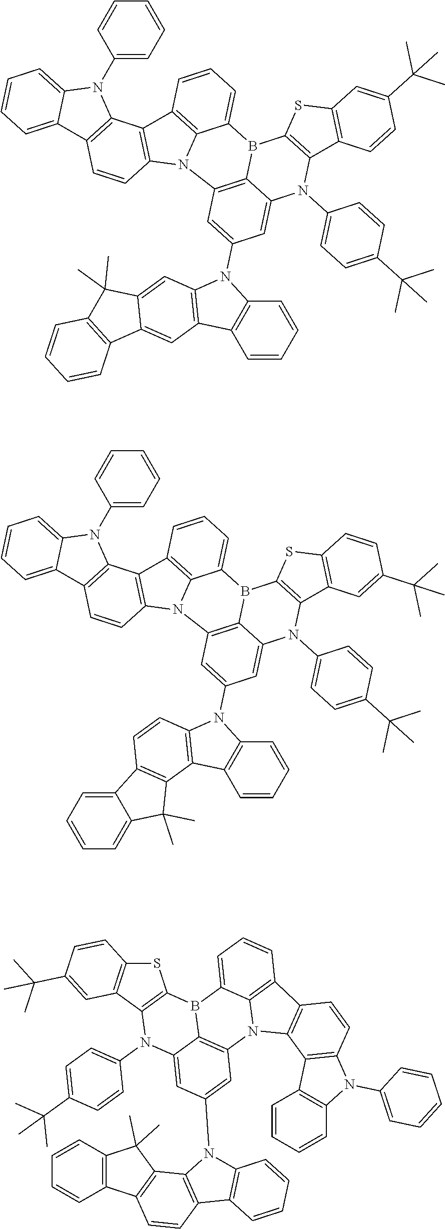

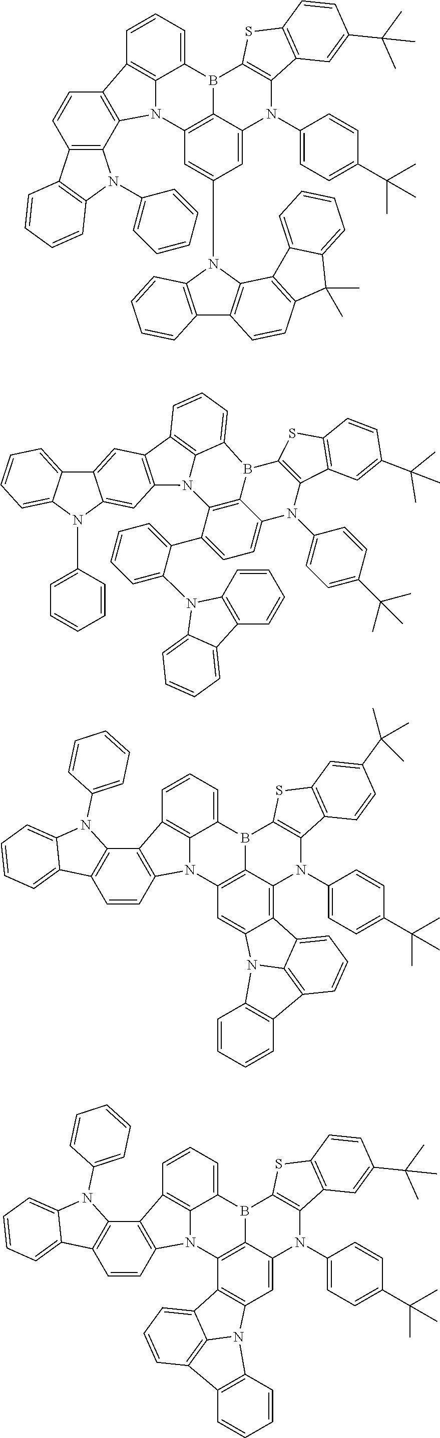

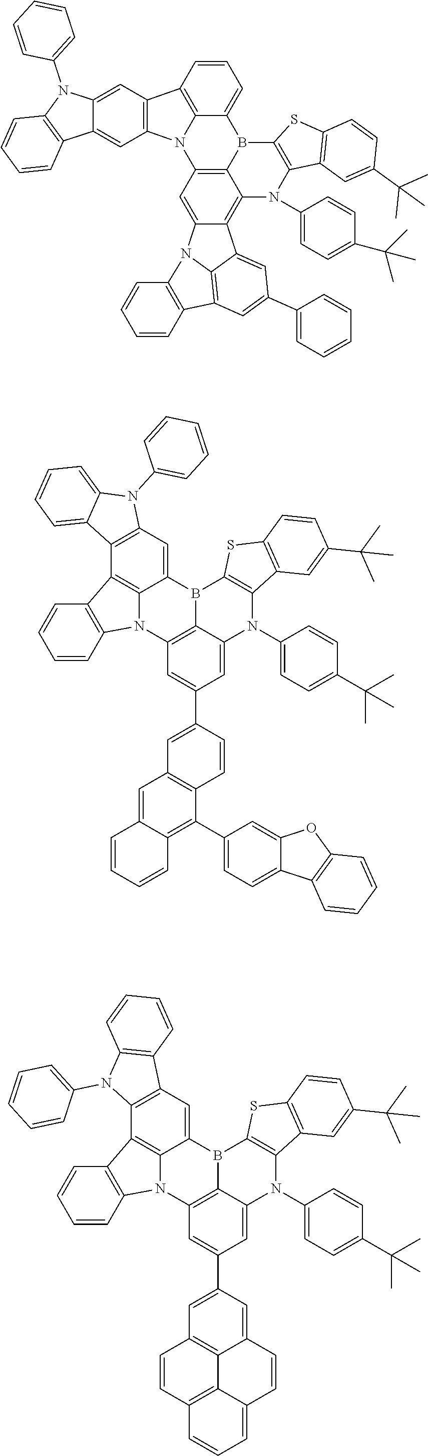 [SMILES: CC(C)(C)c1ccc(N2c3c(sc4ccc(C(C)(C)C)cc34)B3c4c(cc5c(c42)c2cc(-c4ccccc4)cc4c6ccccc6n5c42)-n2c4cc5c6ccccc6n(-c6ccccc6)c5cc4c4cccc3c42)cc1 ; CC(C)(C)c1ccc(N2c3cc(-c4ccc5c(-c6ccc7c(c6)oc6ccccc67)c6ccccc6cc5c4)cc4c3B(c3sc5ccc(C(C)(C)C)cc5c32)c2cc3c(c5ccccc5n3-c3ccccc3)c3c5ccccc5n-4c23)cc1 ; CC(C)(C)c1ccc(N2c3cc(-c4cc5ccc6cccc7ccc(c4)c5c67)cc4c3B(c3sc5ccc(C(C)(C)C)cc5c32)c2cc3c5ccccc5n(-c5ccccc5)c3c3c5ccccc5n-4c23)cc1]

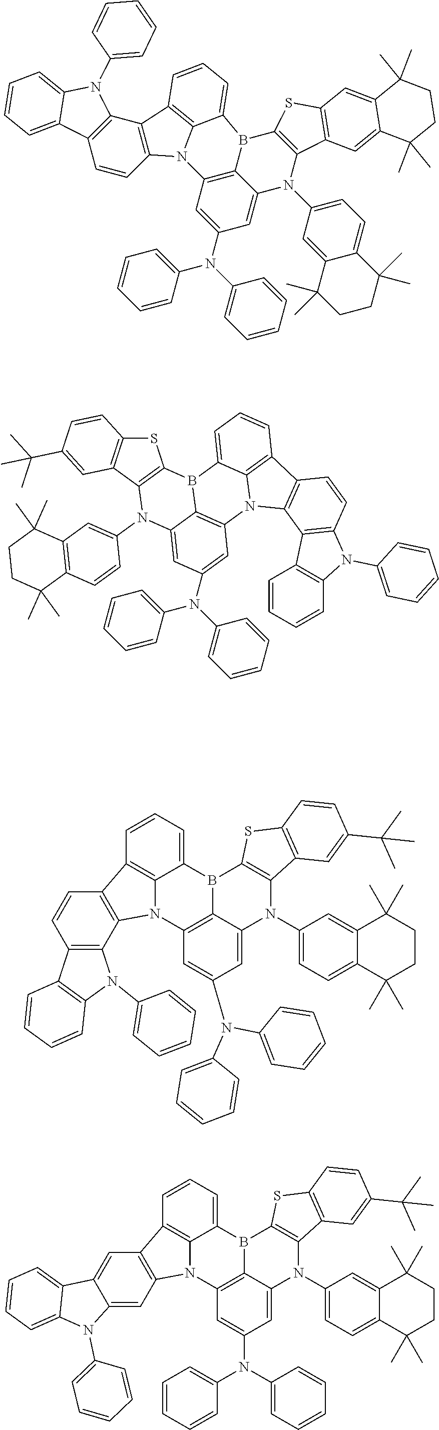

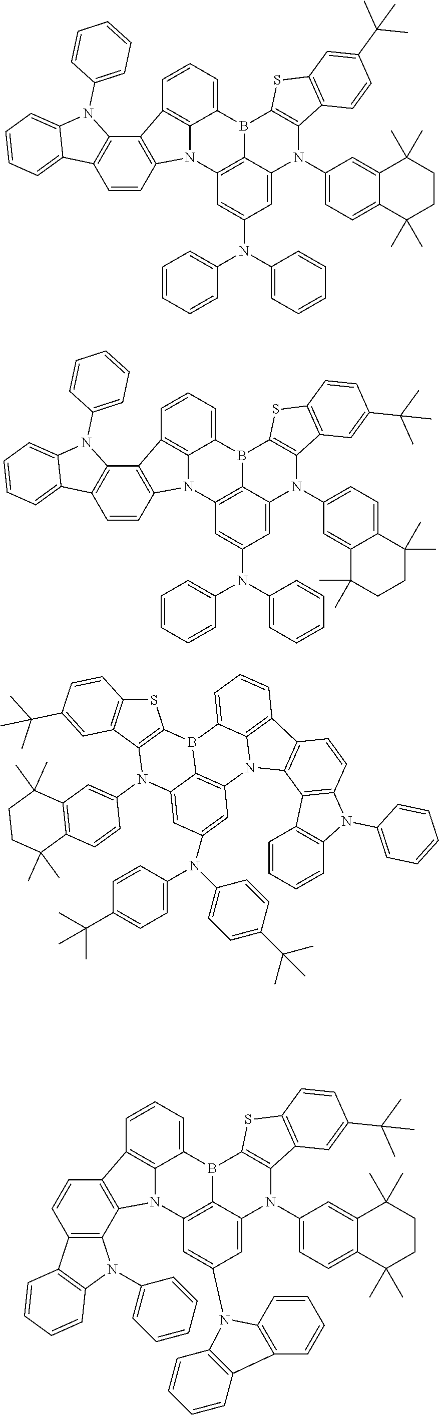

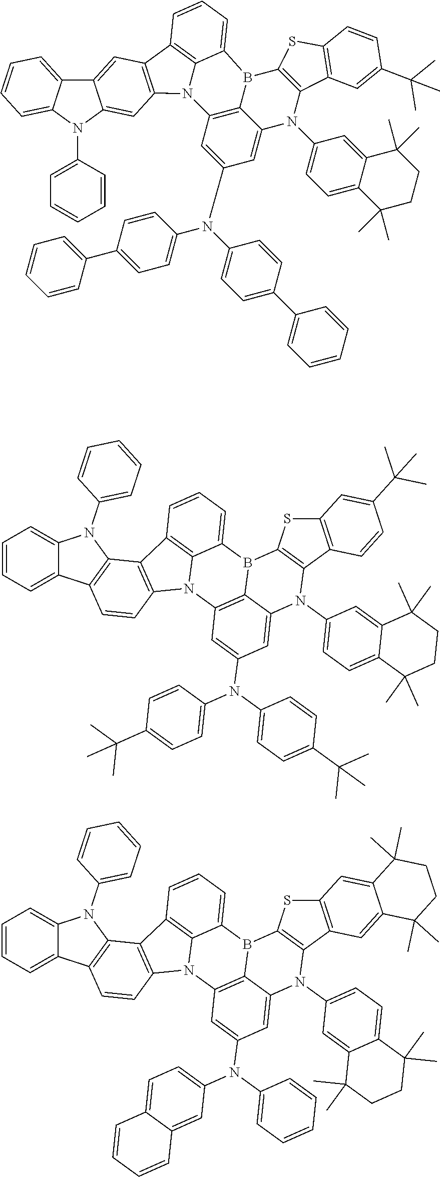 [SMILES: CC(C)(C)c1ccc2sc3c(c2c1)N(c1ccc2c(c1)C(C)(C)CCC2(C)C)c1cc(N(c2ccc(-c4ccccc4)cc2)c2ccc(-c4ccccc4)cc2)cc2c1B3c1cccc3c4cc5c6ccccc6n(-c6ccccc6)c5cc4n-2c13 ; CC(C)(C)c1ccc(N(c2ccc(C(C)(C)C)cc2)c2cc3c4c(c2)-n2c5ccc6c7ccccc7n(-c7ccccc7)c6c5c5cccc(c52)B4c2sc4cc(C(C)(C)C)ccc4c2N3c2ccc3c(c2)C(C)(C)CCC3(C)C)cc1 ; CC1(C)CCC(C)(C)c2cc(N3c4cc(N(c5ccccc5)c5ccc6ccccc6c5)cc5c4B(c4sc6cc7c(cc6c43)C(C)(C)CCC7(C)C)c3cccc4c6c(ccc7c8ccccc8n(-c8ccccc8)c76)n-5c34)ccc21]

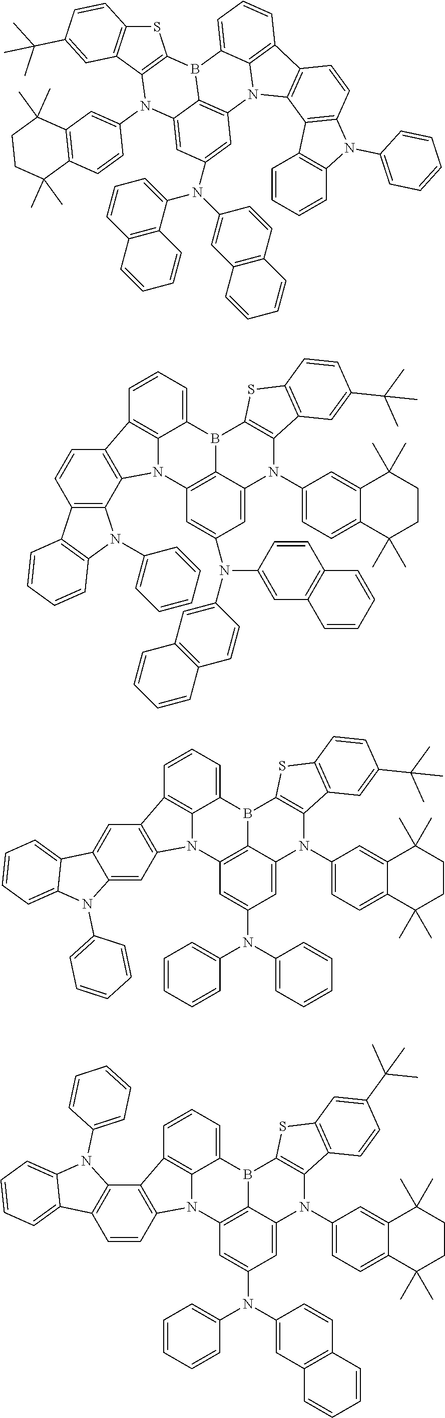

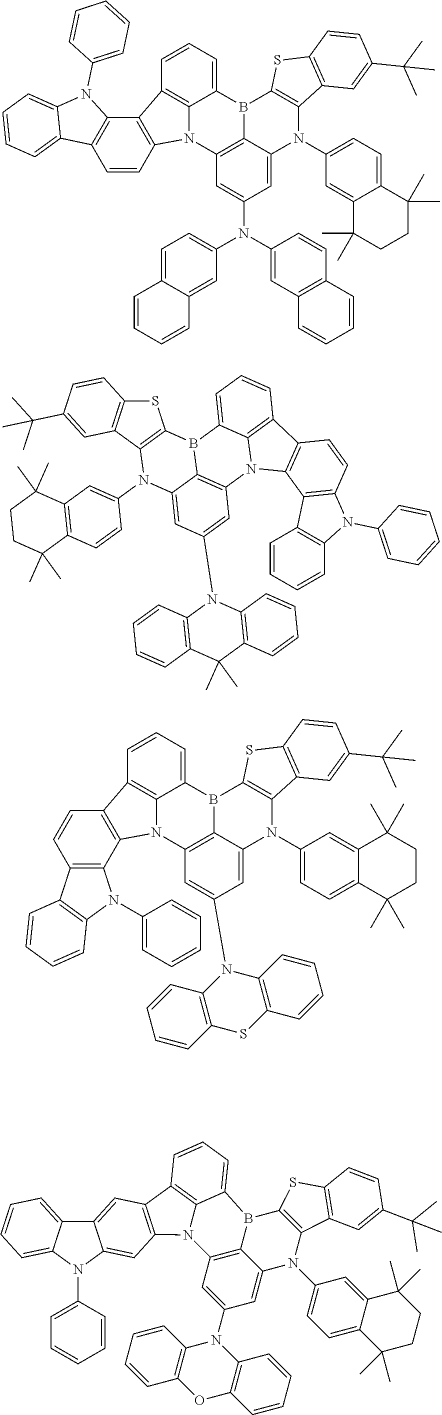

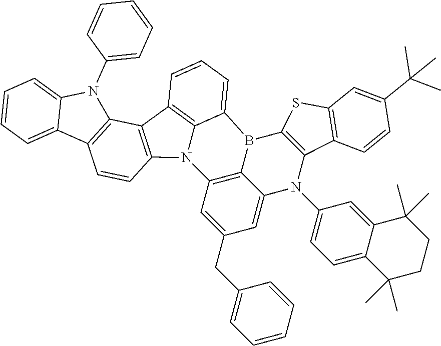 [SMILES: CC(C)(C)c1ccc2c3c(sc2c1)B1c2c(cc(Cc4ccccc4)cc2-n2c4ccc5c6ccccc6n(-c6ccccc6)c5c4c4cccc1c42)N3c1ccc2c(c1)C(C)(C)CCC2(C)C]

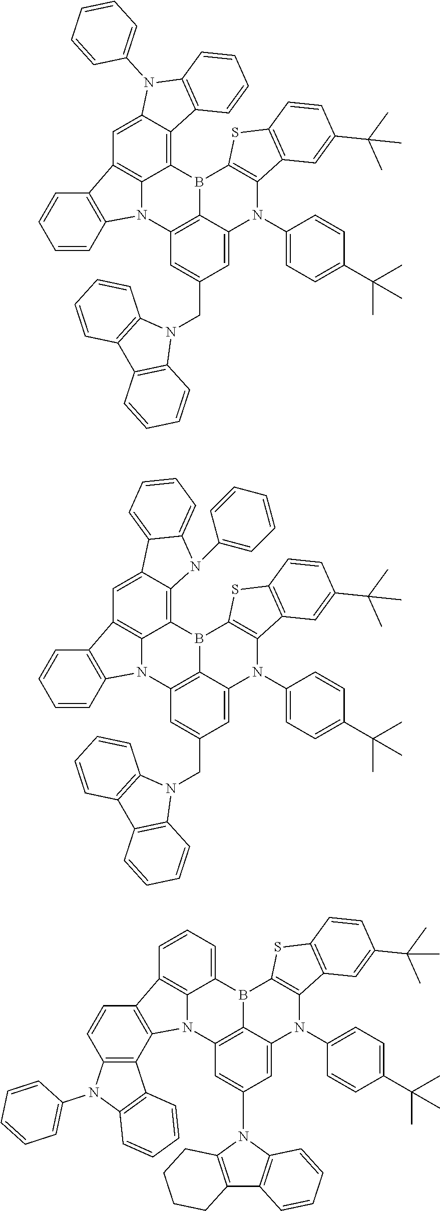 [SMILES: CC(C)(C)c1ccc(N2c3cc(Cn4c5ccccc5c5ccccc54)cc4c3B(c3sc5ccc(C(C)(C)C)cc5c32)c2c3c5ccccc5n(-c5ccccc5)c3cc3c5ccccc5n-4c23)cc1 ; CC(C)(C)c1ccc(N2c3cc(Cn4c5ccccc5c5ccccc54)cc4c3B(c3sc5ccc(C(C)(C)C)cc5c32)c2c3c(cc5c6ccccc6n-4c25)c2ccccc2n3-c2ccccc2)cc1 ; CC(C)(C)c1ccc(N2c3cc(-n4c5c(c6ccccc64)CCCC5)cc4c3B(c3sc5ccc(C(C)(C)C)cc5c32)c2cccc3c5ccc6c(c7ccccc7n6-c6ccccc6)c5n-4c23)cc1]

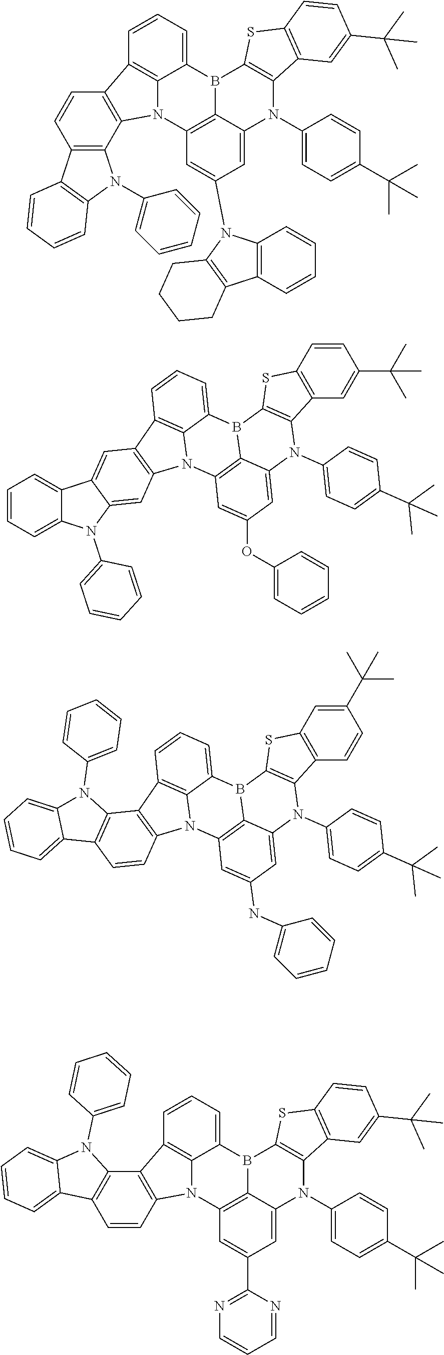 [SMILES: CC(C)(C)c1ccc(N2c3cc(-n4c5c(c6ccccc64)CCCC5)cc4c3B(c3sc5ccc(C(C)(C)C)cc5c32)c2cccc3c5ccc6c7ccccc7n(-c7ccccc7)c6c5n-4c23)cc1 ; CC(C)(C)c1ccc(N2c3cc(Oc4ccccc4)cc4c3B(c3sc5ccc(C(C)(C)C)cc5c32)c2cccc3c5cc6c7ccccc7n(-c7ccccc7)c6cc5n-4c23)cc1 ; CC(C)(C)c1ccc(N2c3cc(Nc4ccccc4)cc4c3B(c3sc5cc(C(C)(C)C)ccc5c32)c2cccc3c5c(ccc6c7ccccc7n(-c7ccccc7)c65)n-4c23)cc1 ; CC(C)(C)c1ccc(N2c3cc(-c4ncccn4)cc4c3B(c3sc5ccc(C(C)(C)C)cc5c32)c2cccc3c5c(ccc6c7ccccc7n(-c7ccccc7)c65)n-4c23)cc1]

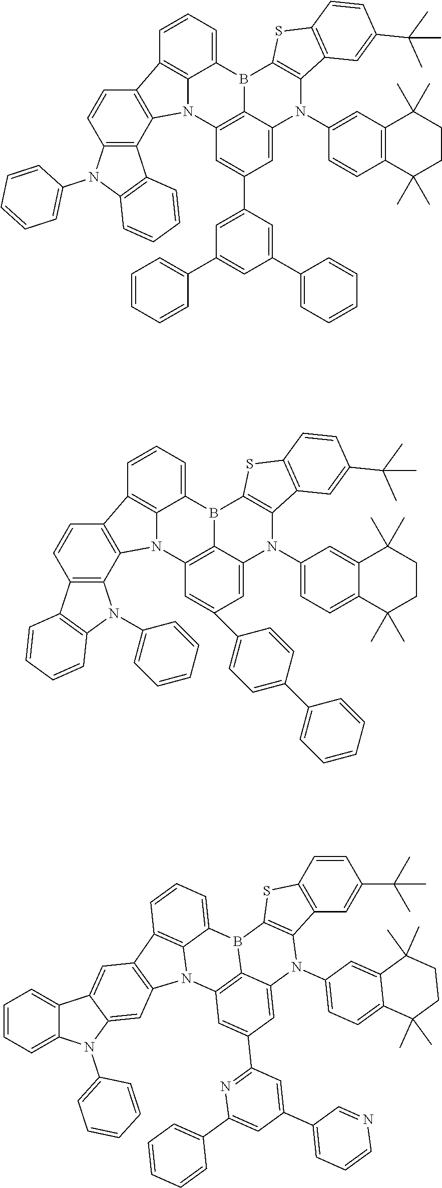 [SMILES: CC(C)(C)c1ccc2sc3c(c2c1)N(c1ccc2c(c1)C(C)(C)CCC2(C)C)c1cc(-c2cc(-c4ccccc4)cc(-c4ccccc4)c2)cc2c1B3c1cccc3c4ccc5c(c6ccccc6n5-c5ccccc5)c4n-2c13 ; CC(C)(C)c1ccc2sc3c(c2c1)N(c1ccc2c(c1)C(C)(C)CCC2(C)C)c1cc(-c2ccc(-c4ccccc4)cc2)cc2c1B3c1cccc3c4ccc5c6ccccc6n(-c6ccccc6)c5c4n-2c13 ; CC(C)(C)c1ccc2sc3c(c2c1)N(c1ccc2c(c1)C(C)(C)CCC2(C)C)c1cc(-c2cc(-c4cccnc4)cc(-c4ccccc4)n2)cc2c1B3c1cccc3c4cc5c6ccccc6n(-c6ccccc6)c5cc4n-2c13]

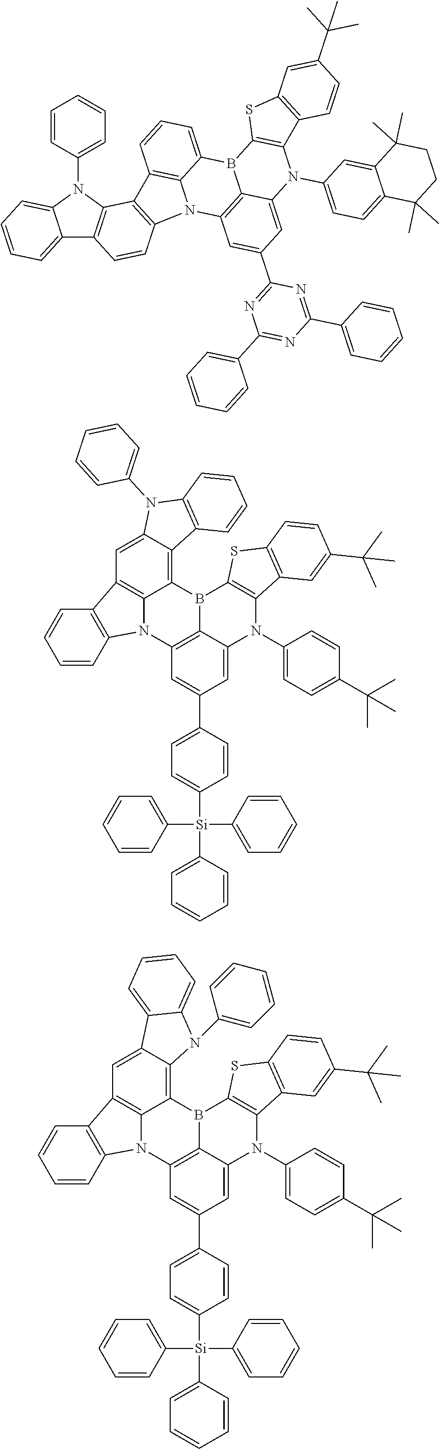

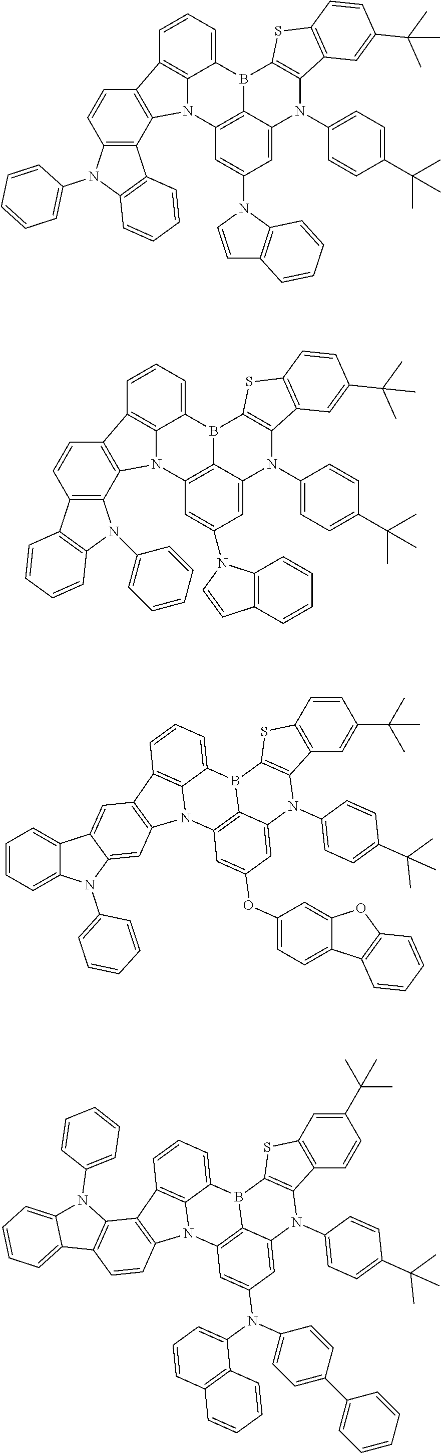

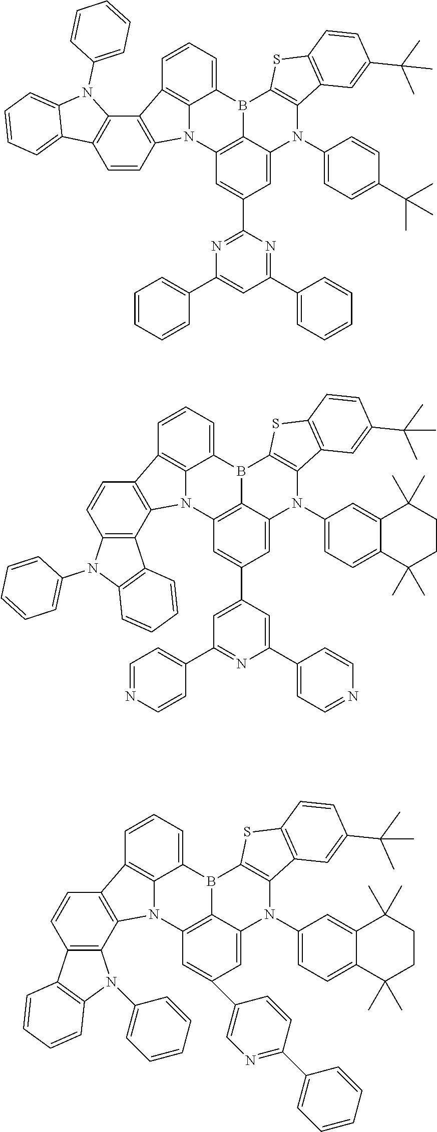 [SMILES: CC(C)(C)c1ccc(N2c3cc(-c4nc(-c5ccccc5)cc(-c5ccccc5)n4)cc4c3B(c3sc5ccc(C(C)(C)C)cc5c32)c2cccc3c5c(ccc6c7ccccc7n(-c7ccccc7)c65)n-4c23)cc1 ; CC(C)(C)c1ccc2sc3c(c2c1)N(c1ccc2c(c1)C(C)(C)CCC2(C)C)c1cc(-c2cc(-c4ccncc4)nc(-c4ccncc4)c2)cc2c1B3c1cccc3c4ccc5c(c6ccccc6n5-c5ccccc5)c4n-2c13 ; CC(C)(C)c1ccc2sc3c(c2c1)N(c1ccc2c(c1)C(C)(C)CCC2(C)C)c1cc(-c2ccc(-c4ccccc4)nc2)cc2c1B3c1cccc3c4ccc5c6ccccc6n(-c6ccccc6)c5c4n-2c13]

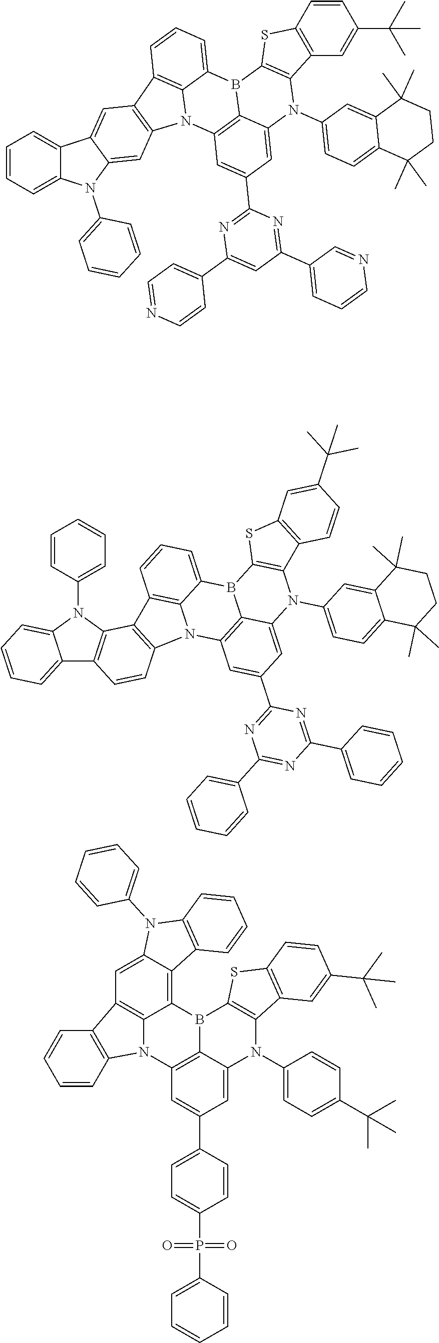

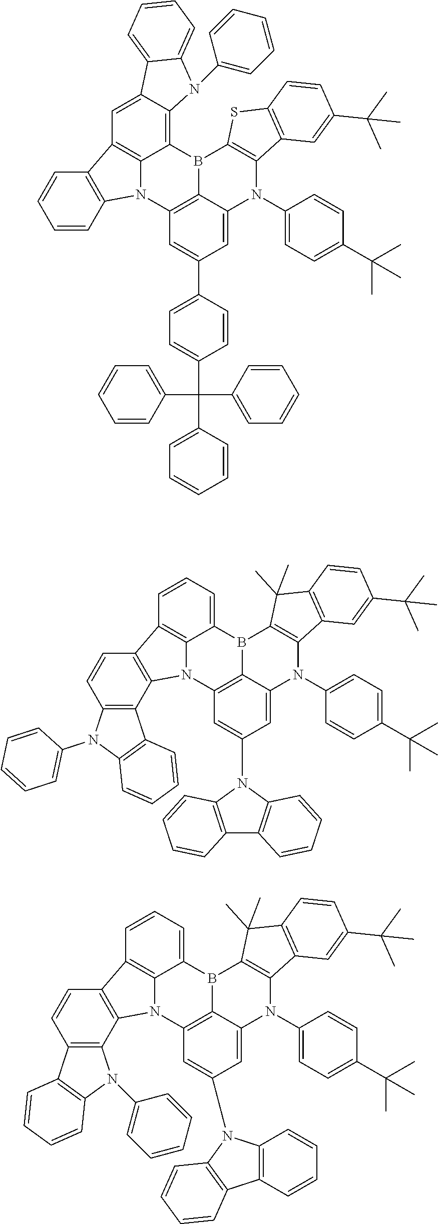

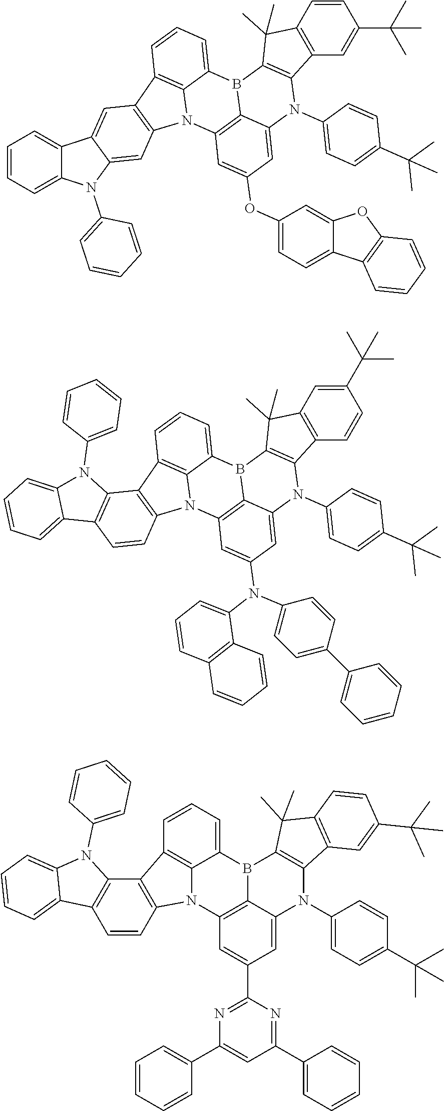

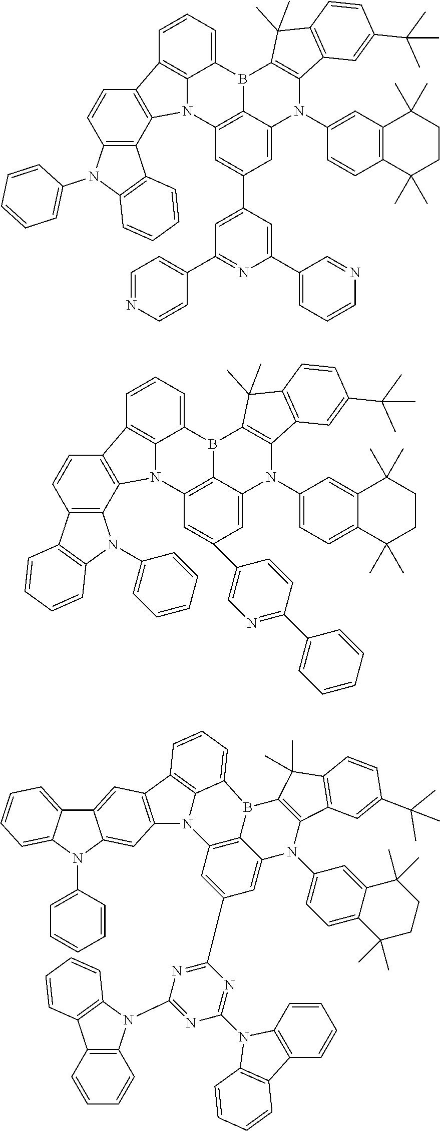 [SMILES: CC(C)(C)c1ccc2c(c1)C1=C(B3c4c(cc(-c5cc(-c6ccncc6)nc(-c6cccnc6)c5)cc4-n4c5c3cccc5c3ccc5c(c6ccccc6n5-c5ccccc5)c34)N1c1ccc3c(c1)C(C)(C)CCC3(C)C)C2(C)C ; CC(C)(C)c1ccc2c(c1)C1=C(B3c4c(cc(-c5ccc(-c6ccccc6)nc5)cc4-n4c5c3cccc5c3ccc5c6ccccc6n(-c6ccccc6)c5c34)N1c1ccc3c(c1)C(C)(C)CCC3(C)C)C2(C)C ; CC(C)(C)c1ccc2c(c1)C1=C(B3c4c(cc(-c5nc(-n6c7ccccc7c7ccccc76)nc(-n6c7ccccc7c7ccccc76)n5)cc4-n4c5cc6c(cc5c5cccc3c54)c3ccccc3n6-c3ccccc3)N1c1ccc3c(c1)C(C)(C)CCC3(C)C)C2(C)C]

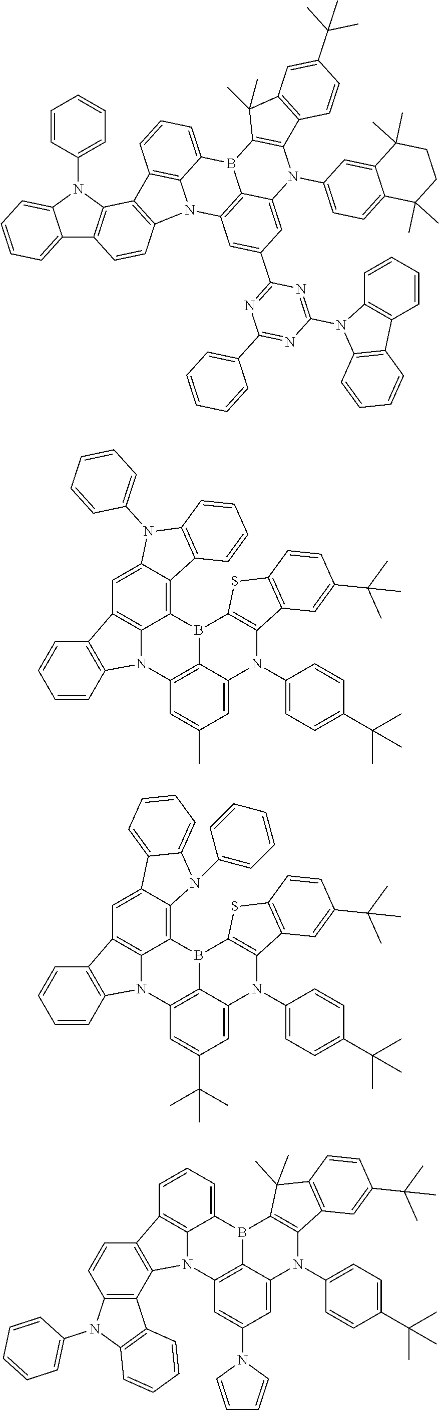

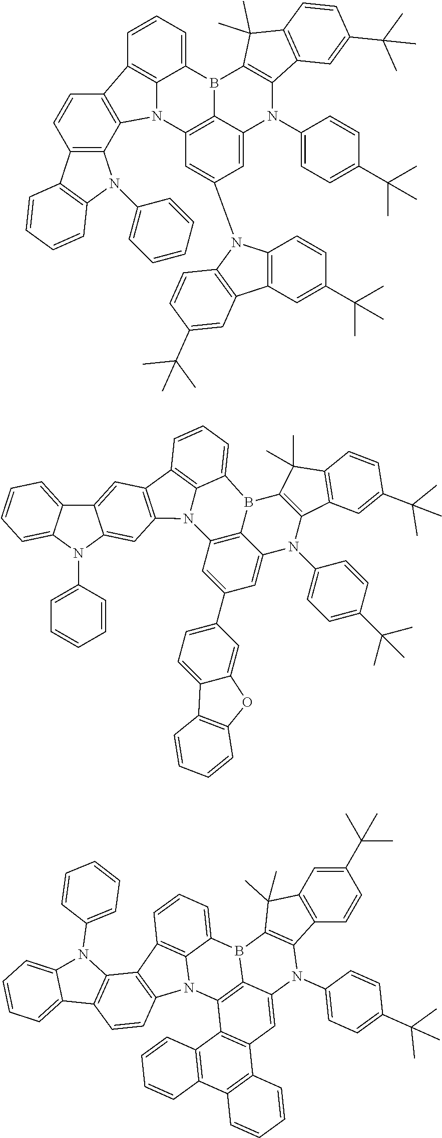

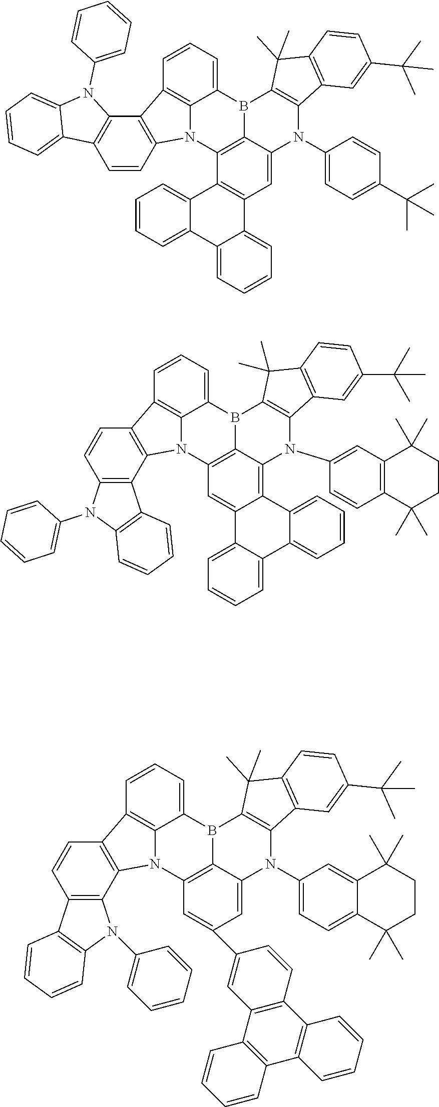 [SMILES: CC(C)(C)c1ccc(N2C3=C(B4c5c2cc2c6ccccc6c6ccccc6c2c5-n2c5ccc6c7ccccc7n(-c7ccccc7)c6c5c5cccc4c52)C(C)(C)c2ccc(C(C)(C)C)cc23)cc1 ; CC(C)(C)c1ccc2c(c1)C1=C(B3c4c(cc5c6ccccc6c6ccccc6c5c4N1c1ccc4c(c1)C(C)(C)CCC4(C)C)-n1c4c3cccc4c3ccc4c(c5ccccc5n4-c4ccccc4)c31)C2(C)C ; CC(C)(C)c1ccc2c(c1)C1=C(B3c4c(cc(-c5ccc6c7ccccc7c7ccccc7c6c5)cc4-n4c5c3cccc5c3ccc5c6ccccc6n(-c6ccccc6)c5c34)N1c1ccc3c(c1)C(C)(C)CCC3(C)C)C2(C)C]

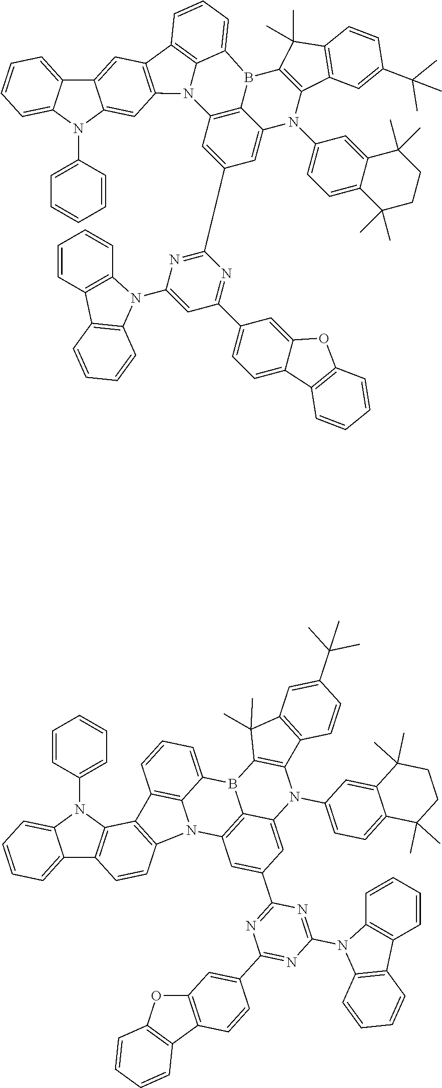 [SMILES: CC(C)(C)c1ccc2c(c1)C1=C(B3c4c(cc(-c5nc(-c6ccc7c(c6)oc6ccccc67)cc(-n6c7ccccc7c7ccccc76)n5)cc4-n4c5cc6c(cc5c5cccc3c54)c3ccccc3n6-c3ccccc3)N1c1ccc3c(c1)C(C)(C)CCC3(C)C)C2(C)C ; CC(C)(C)c1ccc2c(c1)C(C)(C)C1=C2N(c2ccc3c(c2)C(C)(C)CCC3(C)C)c2cc(-c3nc(-c4ccc5c(c4)oc4ccccc45)nc(-n4c5ccccc5c5ccccc54)n3)cc3c2B1c1cccc2c4c(ccc5c6ccccc6n(-c6ccccc6)c54)n-3c12]

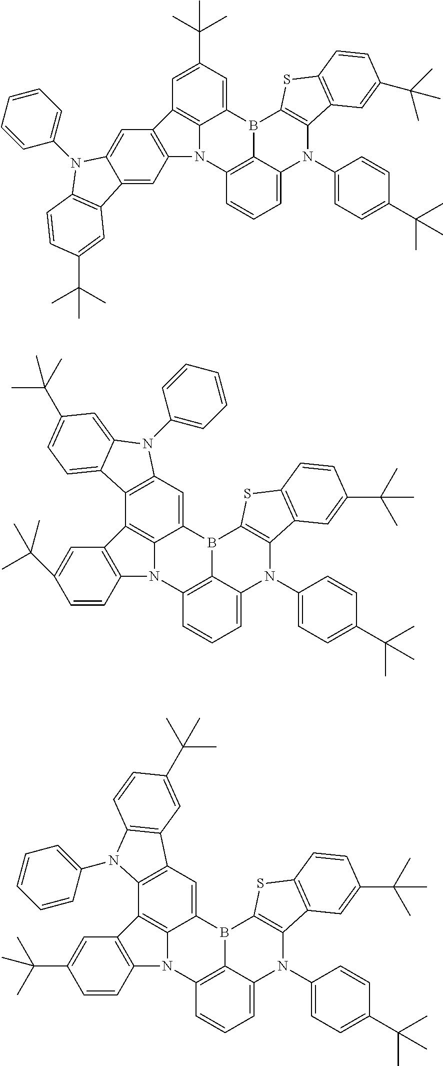

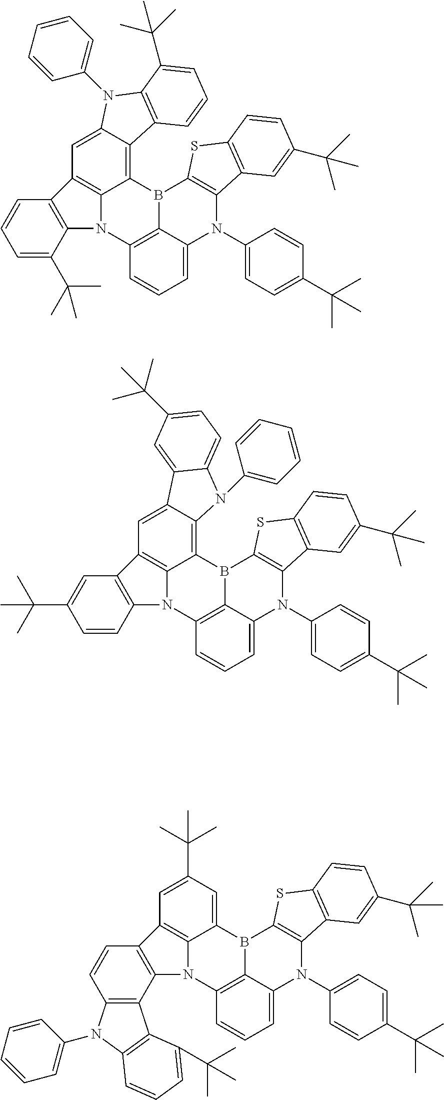

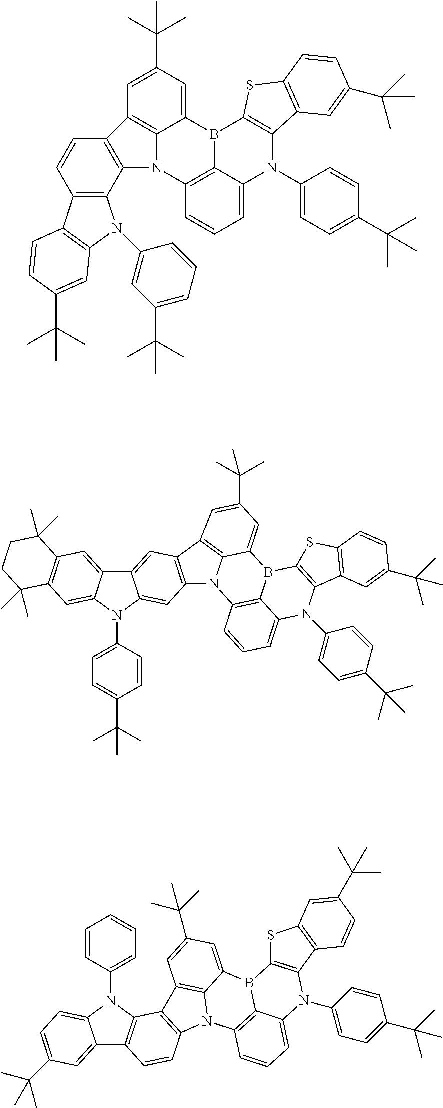

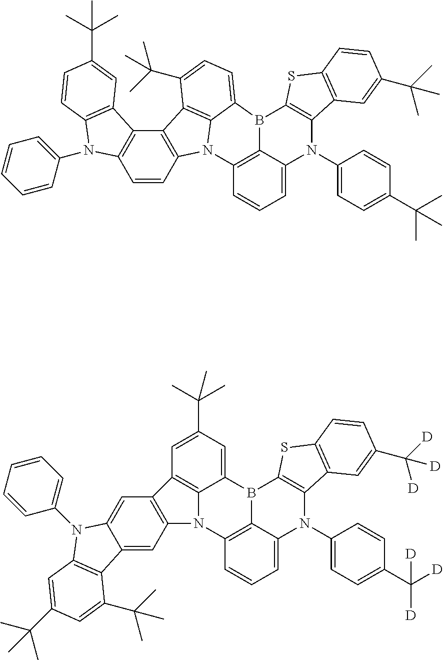

In some embodiments, the boron-nitrogen-containing organic compound as described herein is mainly divided into two types, one is that the compound modifies the boron-nitrogen ring structure by using indolocarbazole as a modifying group to adjust the optical properties of the existing boron-nitrogen skeleton; at the same time, it can effectively regulate the frontier orbital energy level of the organic compound, enhance the multi-resonance effect of the rigid conjugated plane of the boron-nitrogen ring structure, thereby achieving the effect of regulating the emission color of the organic compound and narrowing the FHWM of the emission spectrum. In addition, the carbazole skeleton has stronger rigidity compared to the traditional arylamine skeleton, which can effectively enhance the oscillator strength of the compound; moreover, N and B deposited in the ortho position of the conjugated six-membered ring, and do not undergo free rotation, thereby improving the planarity of the boron-nitrogen-containing organic compound molecules and further narrowing the FWHM of the emission spectrum of the new organic compound.

The other is that the compound modifies the boron-nitrogen ring structure by introducing carbazofuran as a modifying group in the skeleton of the boron-nitrogen ring. Due to the poor electron-donating ability of furan compared to carbazole, it can reduce the electron cloud density around the B atom, thereby improving the luminescence efficiency of the boron-nitrogen-containing organic compound. Moreover, the stability of the compound can be improved by prolonging the conjugated length of the overall molecule.

The boron-nitrogen-containing organic compound as described herein can be used as an organic functional material in electronic devices, especially in light-emitting devices. The light-emitting device may be selected from a color converter, an OLED, an OLEEC, or an organic light emitting field effect transistor; particularly preferably selected from an OLED. The organic functional material may be selected from a color conversion material (CCM), a hole-injection material (HIM), a hole-transport material (HTM), an electron-transport material (ETM), an electron-injection material (EIM), an electron-blocking material (EBM), a hole-blocking material (HBM), a light-emitting material (Emitter), a host material (Host), or an organic dye. In some embodiments, the boron-nitrogen-containing organic compound as described herein can be used as a light-emitting material.

In some embodiments, the emission wavelength of the light-emitting device is between 300 nm and 1500 nm, preferably between 400 nm and 1000 nm, more preferably between 400 nm and 800 nm.

In some embodiments, the boron-nitrogen-containing organic compound as described herein can be used as a fluorescent dopant material (i.e., fluorescent emitting material).

As the fluorescent dopant material, the boron-nitrogen-containing organic compound should have an appropriate singlet energy level, namely S₁. In some embodiments, the boron-nitrogen-containing organic compound as described herein, its S₁≥2.1 eV, preferably ≥2.3 eV, more preferably ≥2.5 eV, further preferably ≥2.7 eV, and most preferably ≥2.8 eV.

As the fluorescent dopant material, the boron-nitrogen-containing organic compound should have high photoluminescence quantum yield, namely PLQY In some embodiments, the boron-nitrogen-containing organic compound as described herein, its PLQY ≥40%, preferably ≥50%, more preferably ≥60%, and most preferably ≥70%.

In some embodiments, the oscillator strength f1 of the boron-nitrogen-containing organic compound ≥0.2, preferably ≥0.3, more preferably ≥0.4, and most preferably ≥0.5.

As an organic functional material, it is desirable to have good thermal stability. Generally, the glass transition temperature (Tg) of the boron-nitrogen-containing organic compound ≥100° C., preferably ≥140° C., more preferably ≥180° C.

In some embodiments, the (HOMO-(HOMO−1)) of the boron-nitrogen-containing organic compound ≥0.2 eV, preferably ≥0.3 eV, more preferably ≥0.4 eV, and most preferably ≥0.45 eV.

In some embodiments, the ((LUMO+1)-LUMO) of the boron-nitrogen-containing organic compound ≥0.15 eV, preferably ≥0.25 eV, more preferably 0.30 eV, and most preferably 0.35 eV.

In another aspect, the present disclosure also provides a polymer comprising at least one first repeating unit, the at least one first repeating unit comprises at least one structure corresponding to a boron-nitrogen-containing organic compound as described herein.

In some embodiments, the polymer further comprises at least one second repeating unit distinct from the first repeating unit.

In some embodiments, the polymer is a conjugated polymer. In some embodiments, the conjugated polymer comprises a second repeating unit, and the second repeating unit is selected from one of the following repeating units:

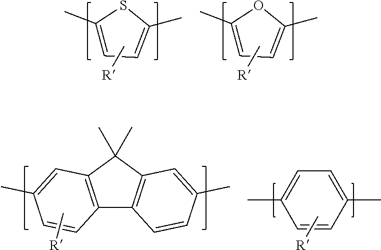

Where each R′ is independently selected from one or combinations of more than one of the following groups: —H, -D, a C₁-C₂₀ linear alkyl group, a C₁-C₂₀ alkoxy group, a C₁-C₂₀ thioalkoxy group, a C₃-C₂₀ branched alkyl group, a C₃-C₂₀ cyclic alkyl group, a C₃-C₂₀ branched alkoxy group, a C₃-C₂₀ cyclic alkoxy group, a C₃-C₂₀ branched thioalkoxy group, a C₃-C₂₀ cyclic thioalkoxy group, a C₃-C₂₀ branched silyl group, a C₃-C₂₀ cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aryl group containing 5 to 60 ring atoms, a substituted/unsubstituted heteroaryl group containing 5 to 60 ring atoms, an aryloxy group containing 5 to 60 ring atoms, a heteroaryloxy group containing 5 to 60 ring atoms.

In some embodiments, the polymer comprises a polymer molecular main chain and a branched chain connected to the polymer molecular main chain, and the branched chain is derived from the boron-nitrogen-containing organic compound as described herein. More preferably, the polymer is a non-conjugated polymer comprising a second repeating unit, the second repeating unit is selected from one of the following repeating units:

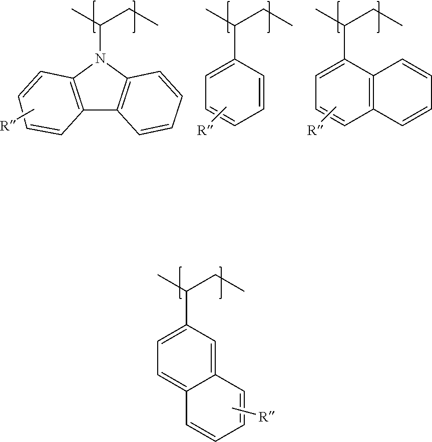

Where each R″ is independently selected from one or combinations of more than one of the following groups: —H, -D, a C₁-C₂₀ linear alkyl group, a C₁-C₂₀ alkoxy group, a C₁-C₂₀ thioalkoxy group, a C₃-C₂₀ branched alkyl group, a C₃-C₂₀ cyclic alkyl group, a C₃-C₂₀ branched alkoxy group, a C₃-C₂₀ cyclic alkoxy group, a C₃-C₂₀ branched thioalkoxy group, a C₃-C₂₀ cyclic thioalkoxy group, a C₃-C₂₀ branched silyl group, a C₃-C₂₀ cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, —I, a cross-linkable group, a substituted/unsubstituted aryl group containing 5 to 60 ring atoms, a substituted/unsubstituted heteroaryl group containing 5 to 60 ring atoms, an aryloxy group containing 5 to 60 ring atoms, a heteroaryloxy group containing 5 to 60 ring atoms.

In some embodiments, the synthetic method of the polymer is selected from the group consisting of SUZUKI-, YAMAMOTO-, STILLE-, NIGESHI-, KUMADA-, HECK-, SONOGASHIRA-, HIYAMA-, FUKUYAMA-, HARTWIG-BUCHWALD-, and ULLMAN-.

In some embodiments, the glass transition temperature (Tg) of the polymer ≥100° C., preferably ≥120° C., more preferably ≥140° C., further preferably ≥160° C., and most preferably ≥180° C.

In some embodiments, the polydispersity index (PDI) of the polymer is preferably from 1 to 5, more preferably 1 to 4, even more preferably 1 to 3, further preferably 1 to 2, and most preferably 1 to 1.5.

In some embodiments, the weight-average molecular weight (M_{w}) of the polymer is preferably from 10 k to 1 million, more preferably 50 k to 500 k, even more preferably 100 k to 400 k, further preferably 150 k to 300 k, and most preferably 200 k to 250 k.

In some embodiments, the boron-nitrogen-containing organic compound or the polymer as described herein has a luminescent function with an emission wavelength between 300 nm and 1000 nm, preferably between 350 nm and 900 nm, more preferably between 400 nm and 800 nm. Herein the emission refers to photoluminescence or electroluminescence.

In yet another aspect, the present disclosure further provides a mixture comprising a boron-nitrogen-containing organic compound or a polymer as described herein, and at least one organic functional material. The at least one organic functional material is selected from at least one of the following: a hole-injection material, a hole-transport material, an electron-transport material, an electron-injection material, an electron-blocking material, a hole-blocking material, a light-emitting material, a host material. Where the light-emitting material is selected from a singlet emitting material (fluorescent emitting material), a triplet emitting material (phosphorescent emitting material), or a thermally activated delayed fluorescence material (TADF material). These organic functional materials are described in detail, for example, in WO2010135519A1, US20090134784A1, and WO2011110277A1. The entire contents of these three documents are hereby incorporated into this document for reference. The at least one organic functional material can be a small molecule and a polymer.

In some embodiments, the mixture comprises at least one boron-nitrogen-containing organic compound or polymer as described herein, and a fluorescent host material. Herein, the boron-nitrogen-containing organic compound as described herein can be used as a fluorescent dopant material, and the weight percentage thereof ≤10 wt %, preferably ≤9 wt %, more preferably ≤8 wt %, further preferably ≤7 wt %, and most preferably ≤5 wt %.

The detailed description of the host material, fluorescent emitting material, TADF material, and other organic functional materials is described in detail in WO2018095395, which is hereby incorporated by reference in its entirety.

It is an object of the present disclosure to provide a material for the evaporation-based OLEDs.

In some embodiments, the molecular weight of the boron-nitrogen-containing organic compound ≤1200 g/mol, preferably ≤1100 g/mol, more preferably ≤1000 g/mol, further preferably ≤950 g/mol, and most preferably ≤900 g/mol.

Another object of the present disclosure is to provide a material for the printed OLEDs.

In some embodiments, the molecular weight of the boron-nitrogen-containing organic compound ≥800 g/mol, preferably ≥1000 g/mol, more preferably 1100 g/mol, and most preferably ≥1200 g/mol.

In some embodiments, the boron-nitrogen-containing organic compound as described herein has a solubility of ≥10 mg/mL in toluene at 25° C., preferably ≥15 mg/mL, and most preferably ≥20 mg/mL.

In yet another aspect, the present disclosure further provides a formulation or an ink comprising at least one boron-nitrogen-containing organic compound or polymer as described herein, and an organic solvent.

The viscosity and surface tension of the ink are important parameters in printing processes. A suitable ink surface tension is required for the specific substrates and the specific printing methods.

In some embodiments, the surface tension of the ink as described herein at 25° C. is in the range of 19 dyne/cm to 50 dyne/cm; more preferably in the range of 22 dyne/cm to 35 dyne/cm; and most preferably in the range of 25 dyne/cm to 33 dyne/cm.

In some embodiments, the viscosity of the ink as described herein at 25° C. is in the range of about 1 cps to 100 cps; preferably in the range of 1 cps to 50 cps; more preferably in the range of 1.5 cps to 20 cps; and most preferably in the range of 4.0 cps to 20 cps. The resulting formulation will be particularly suitable for ink-jet printing.

The viscosity can be adjusted by different methods, such as by the selection of appropriate solvent and the concentration of the functional materials in the ink. In the ink comprising the above-mentioned metal-organic complexes or polymers as described herein facilitate the adjustment of the printing ink in the appropriate range according to the printing method used.

Generally, in the formulation comprising the functional material as described herein, the weight ratio of the functional material ranges from 0.3 wt % to 30 wt %, preferably in the range of 0.5 wt % to 20 wt %, more preferably in the range of 0.5 wt % to 15 wt %, further preferably in the range of 0.5 wt % to 10 wt %, and most preferably in the range of 1 wt % to 5 wt %.

In some embodiments, the organic solvent of the ink as described herein is selected from aromatic-based or heteroaromatic-based solvents, particular in aliphatic chain/ring substituted aromatic solvents, aromatic ketone solvents, or aromatic ether solvents.

Examples of solvents suitable for the present disclosure include, but not limited to aromatic-based or heteroaromatic-based solvents, such as diisopropylbenzene, phenylpentane, tetralin, cyclohexylbenzene, 1-chloronaphthalene, 1,4-dimethylnaphthalene, 3-isopropylbiphenyl, p-methyl cumene, dipentylbenzene, tripentylbenzene, pentyltoluene, o-xylene, m-xylene, p-xylene, 1,2-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, phenyl xylyl ethane, 2-isopropylnaphthalene, benzyl ether, etc; ketone-based solvents, such as 1-tetralone, 2-tetralone, 2-(phenylepoxy)tetralone, 6-(methoxy)tetralone, acetophenone, propiophenone, benzophenone, and derivatives thereof such as 4-methylacetophenone, 3-methylacetophenone, 2-methylacetophenone, 4-methylphenylacetone, 3-methylpropiophenone, 2-methylpropiophenone, isophorone, 2,6,8-trimethyl-4-nonanone, fenchone, 2-nonanone, 3-nonanone, 5-nonanone, 2-decanone, 2,5-hexanedione, phorone, 6-undecanone; aromatic ether solvents, such as 3-phenoxytoluene, butoxybenzene, benzylbutylbenzene, p-anisaldehyde dimethyl acetal, tetrahydro-2-phenoxy-2H-pyran, 1,2-dimethoxy-4-(1-propenyl)benzene, 1,4-benzodioxan, 1,3-diisopropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-anethole, 1,2-dimethoxybenzene, 1-methoxynaphthalene, diphenyl ether, 2-phenoxymethyl ether, 2-phenoxytetrahydrofuran, ethyl-2-naphthyl ether, dipentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, etc; ester solvent, such as alkyl octanoate, alkyl sebacate, alkyl stearate, alkyl benzoate, alkyl phenylacetate, alkyl cinnamate, alkyl oxalate, alkyl maleate, alkyl lactone, alkyl oleate, etc.

Further, in the formulation as described herein, the organic solvent can be selected from aliphatic ketones, such as, 2-nonanone, 3-nonanone, 5-nonanone, 2-decanone, 2,5-hexanedione, 2,6,8-trimethyl-4-nonanone, phoron, 6-undecanone, etc; and the organic solvent as described herein can be selected from aliphatic ether, such as, dipentyl ether, hexyl ether, n-octyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, etc.

In some embodiments, the printing ink further comprises another organic solvent. Examples of the another organic solvents include, but not limited to: methanol, ethanol, 2-methoxyethanol, dichloromethane, trichloromethane, chlorobenzene, 1,2-dichlorobenzene, tetrahydrofuran, anisole, morpholine, toluene, o-xylene, m-xylene, p-xylene, 1,4-dioxane, acetone, 2-butanone, 1,2-dichloroethane, 3-phenoxytoluene, 1,1,1-trichloroethane, 1,1,2,2-tetrachloroethane, ethyl acetate, butyl acetate, N,N-dimethylformamide, N,N-dimethylacetamide, dimethyl sulfoxide, tetraline, decahydronaphthalene, indene, and/or any combination thereof.

In some embodiments, the formulation as described herein is a solution.

In some embodiments, the formulation as described herein is a dispersion.

The formulation in the embodiments of the present disclosure may comprise the boron-nitrogen-containing organic compound or the mixture or the polymer of 0.01 wt % to 20 wt %, preferably 0.1 wt % to 15 wt %, more preferably 0.2 wt % to 10 wt %, and most preferably 0.25 wt % to 5 wt %.

In yet another aspect, the present disclosure further provides the use of the formulation as coatings or printing inks in the preparation of organic electronic devices, particularly preferably by printing or coating processing methods.

Where suitable printing or coating techniques include, but not limited to, ink-jet printing, gravure printing, nozzle printing, typographic printing, screen printing, dip coating, spin coating, blade coating, roller printing, torsion roll printing, planographic printing, flexographic printing, rotary printing, spray coating, brush coating, pad printing, slit die coating, and so on. Preferred techniques are ink-jet printing, nozzle printing, and gravure printing. The solution or dispersion may additionally comprise one or more components, such as surface active compounds, lubricants, wetting agents, dispersing agents, hydrophobic agents, binders, etc., which are used to adjust the viscosity and film forming properties, or to improve adhesion, etc. For more information about printing technologies and their requirements for solutions, such as solvent, concentration, and viscosity, and the like, please refer to Handbook of Print Media: Technologies and Production Methods, edited by Helmut Kipphan, ISBN 3-540-67326-1.

In yet another aspect, the present disclosure further provides an application of a boron-nitrogen-containing organic compound or a polymer as described herein, i.e., the boron-nitrogen-containing organic compound or the polymer is applied to an organic electronic device, and the organic electronic device may be selected from, but not limited to, a color converter, an organic light-emitting diode (OLED), an organic photovoltaic cell (OPV), an organic light emitting electrochemical cell (OLEEC), an organic field effect transistor (OFET), an organic light emitting field effect transistor, an organic laser, an organic spintronic electronic device, an organic sensor, an organic plasmon emitting diode (OPED), etc., particularly preferably is an organic electroluminescent device, such as an OLED, an OLEEC, an organic light emitting field effect transistor. In the embodiments of the present disclosure, it is preferred to use the boron-nitrogen-containing organic compound for the light-emitting layer of the electroluminescent device.

In yet another aspect, the present disclosure further provides an organic electronic device comprising a boron-nitrogen-containing organic compound or a polymer or a mixture as described herein. In general, such organic electronic device comprises a cathode, an anode, and a functional layer disposed between the cathode and the anode, where the functional layer comprises a boron-nitrogen-containing organic compound or a polymer or a mixture as described herein. The organic electronic device may be selected from, but not limited to, a color converter, an organic light-emitting diode (OLED), an organic photovoltaic cell (OPV), an organic light emitting electrochemical cell (OLEEC), an organic field effect transistor (OFET), an organic light emitting field effect transistor, an organic laser, an organic spintronic electronic device, an organic sensor, an organic plasmon emitting diode (OPED), etc., particularly preferably is an organic electroluminescent device, such as an OLED, an OLEEC, an organic light emitting field effect transistor.

In some embodiments, the organic electronic device comprises a light-emitting layer, where the light-emitting layer comprises a boron-nitrogen-containing organic compound as described herein; or comprises a boron-nitrogen-containing organic compound as described herein, and a host material; or comprises a boron-nitrogen-containing organic compound as described herein, a phosphorescent emitter, and a host material.

In some embodiments, the organic electronic device is an organic light-emitting device, where the organic light-emitting device comprises a light-emitting layer, and the dopant material of the light-emitting layer comprises at least one boron-nitrogen-containing organic compound or polymer or mixture as described herein.

In the electroluminescent device as described herein, in particular an OLED, which comprises a substrate, an anode, at least one light-emitting layer, and a cathode.

The substrate should be opaque or transparent. A transparent substrate could be used to produce a transparent light-emitting device (for example: Bulovic et al., Nature, 1996, 380, p29, and Gu et al., Appl. Phys. Lett., 1996, 68, p2606). The substrate can be rigid or flexible, e.g. it can be plastic, metal, semiconductor wafer, or glass. Preferably, the substrate has a smooth surface.

Particularly ideal are substrates without surface defects. In some embodiments, the substrate is flexible and can be selected from a polymer film or plastic with a glass transition temperature (Tg) >150° C., preferably >200° C., more preferably >250° C., and most preferably ≥300° C. Examples of the suitable flexible substrates include poly ethylene terephthalate (PET) and polyethylene glycol (2,6-naphthalene) (PEN).

The anode may be a conductive metal, or a metal oxide, or a conductive polymer. The anode should be able to easily inject holes into a hole-injection layer (HIL), a hole-transport layer (HTL), or a light-emitting layer. In some embodiments, the absolute value of the difference between the work function of the anode and the HOMO energy level/valence band energy level of the emitter of the light-emitting layer or the p-type semiconductor materials of the hole-injection layer (HIL)/hole-transport layer (HTL)/electron-blocking layer (EBL)<0.5 eV, preferably ≤0.3 eV, and most preferably ≤0.2 eV Examples of anode materials may include, but not limited to: Al, Cu, Au, Ag, Mg, Fe, Co, Ni, Mn, Pd, Pt, ITO, aluminum-doped zinc oxide (AZO), etc. Other suitable anode materials are known and can be readily selected for use by the general technicians in this field. The anode materials can be deposited using any suitable technique, such as a suitable physical vapor deposition method including RF magnetron sputtering, vacuum thermal evaporation, e-beam, etc. In some embodiments, the anode is patterned. Patterned conductive ITO substrates are commercially available and can be used to produce the devices as described herein.

The cathode may be a conductive metal or a metal oxide. The cathode should be able to easily inject electrons into the electron-injection layer (EIL), the electron-transport layer (ETL), or the directly into the light-emitting layer. In some embodiments, the absolute value of the difference between the work function of the cathode and the LUMO energy level/conduction band energy level of the emitter of the light-emitting layer, or the n-type semiconductor materials of the electron-injection layer (EIL)/electron-transport layer (ETL)/hole-blocking layer (HBL)<0.5 eV, preferably ≤0.3 eV, and most preferably ≤0.2 eV In principle, all materials those can be used as cathodes for OLEDs may be applied as cathode materials for the devices as described herein. Examples of cathode materials include, but not limited to: Al, Au, Ag, Ca, Ba, Mg, LiF/Al, MgAg alloy, BaF₂/Al, Cu, Fe, Co, Ni, Mn, Pd, Pt, ITO, etc. The cathode materials can be deposited using any suitable technique, such as the suitable physical vapor deposition method including RF magnetron sputtering, vacuum thermal evaporation, e-beam, etc.

The OLED may also comprise other functional layers, such as a hole-injection layer (HIL), a hole-transport layer (HTL), an electron-blocking layer (EBL), an electron-injection layer (EIL), an electron-transport layer (ETL), and a hole-blocking layer (HBL). Materials suitable for use in these functional layers are described in details above and in WO2010135519A1, US20090134784A1 and WO2011110277A1. The entire contents of these three documents are hereby incorporated herein for reference.

In some embodiments, the light-emitting layer of the light-emitting device as described herein is prepared by using a formulation as described herein.

In the light-emitting device as described herein, particularly in OLED, the emission wavelength thereof is between 300 nm and 1500 nm, preferably between 350 nm and 1200 nm, more preferably between 400 nm and 800 nm.

In yet another aspect, the present disclosure further provides the applications of organic electronic devices in various electronic equipment, including, but not limited to, display devices, lighting equipment, light sources, sensors, etc.

In yet another aspect, the present disclosure further provides an electronic equipment comprising an organic electronic device as described herein, including, but not limited to, display devices, lighting equipment, light sources, sensors, etc. In some embodiments, the electronic equipment comprises a shell and a device as described herein deposited on the above-mentioned shell. The electronic equipments may be various terminal equipments equipped with an OLED display screen, including, but not limited to, smartphones, tablet PCs, personal laptops, smart TVs, in-vehicle displays, smartwatches, etc. In some embodiments, the electronic equipment is a smartphone.

The present disclosure will be described below in conjunction with the preferred embodiments, but the present disclosure is not limited to the following embodiments. It should be understood that the scope of the present disclosure is covered by the scope of the claims of the present disclosure, and those skilled in the art should understand that certain changes may be made to the embodiments of the present disclosure.

### Specific Embodiment

### 1. Synthesis of Compounds

### Synthesis of intermediate 1b

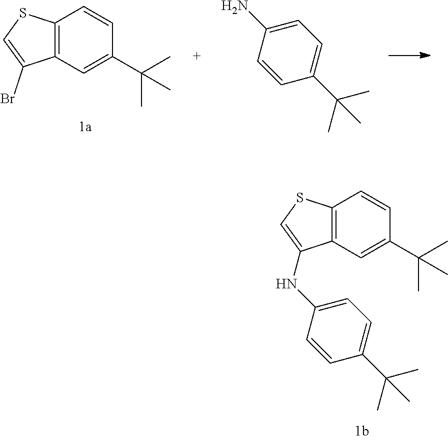 [SMILES: CC(C)(C)c1ccc2scc(Br)c2c1 ; CC(C)(C)c1ccc(N)cc1 ; CC(C)(C)c1ccc(Nc2csc3ccc(C(C)(C)C)cc23)cc1]

1a (100 g), 4-tert-butylaniline (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 126 g (yield: 77%) of intermediate 1b. MS(ASAP)=337.5.

### Synthesis of intermediate 1h

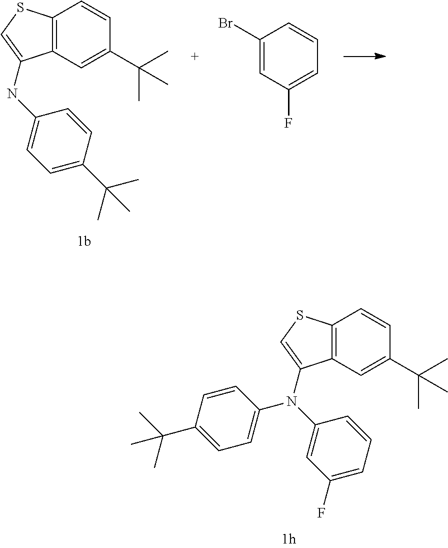 [SMILES: CC(C)(C)c1ccc(Nc2csc3ccc(C(C)(C)C)cc23)cc1 ; Fc1cccc(Br)c1 ; CC(C)(C)c1ccc(N(c2cccc(F)c2)c2csc3ccc(C(C)(C)C)cc23)cc1]

Intermediate 1b (100 g), 3-bromofluorobenzene (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 167 g (yield: 91%) of intermediate 1h. MS(ASAP)=431.6.

### Synthesis of intermediate 1f

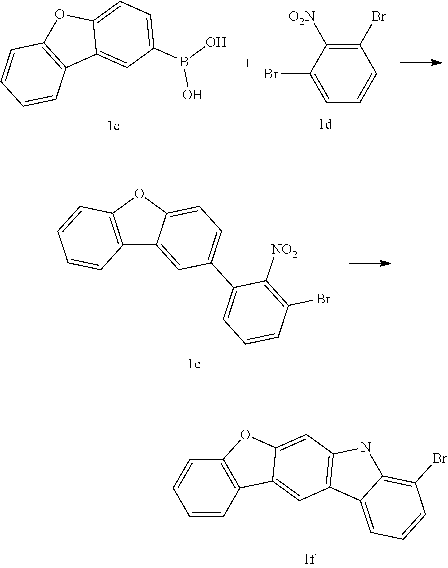 [SMILES: OB(O)c1ccc2oc3ccccc3c2c1 ; O=[N+]([O-])c1c(Br)cccc1Br ; O=[N+]([O-])c1c(Br)cccc1-c1ccc2oc3ccccc3c2c1 ; Brc1cccc2c1[nH]c1cc3oc4ccccc4c3cc12]

1c (100 g), 1d (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 124 g of the crude product (intermediate 1e). After that, the resulting sample was separated by column chromatography (petroleum ether:ethyl acetate=15:1) to yield 123.2 g (yield: 81%) of intermediate 1e.

Intermediate 1e (100 g), triethyl phosphite (50 g), and DMF (1000 mL) were added to a three-necked flask under N₂ atmosphere. After heating up to 150° C., the resulting mixture was refluxed for 24 h and then cooled down. After the extraction with ethyl acetate and deionized-water, the organic phase was washed with water two times, dried, filtered, and the solvent was removed to obtain 80 g of the crude product (intermediate 1f). After that, the resulting sample was separated by column chromatography (petroleum ether:ethyl acetate=15:1) to yield 75 g (yield: 75%) of intermediate 1f MS(ASAP)=335.2.

### Synthesis of intermediate 2c

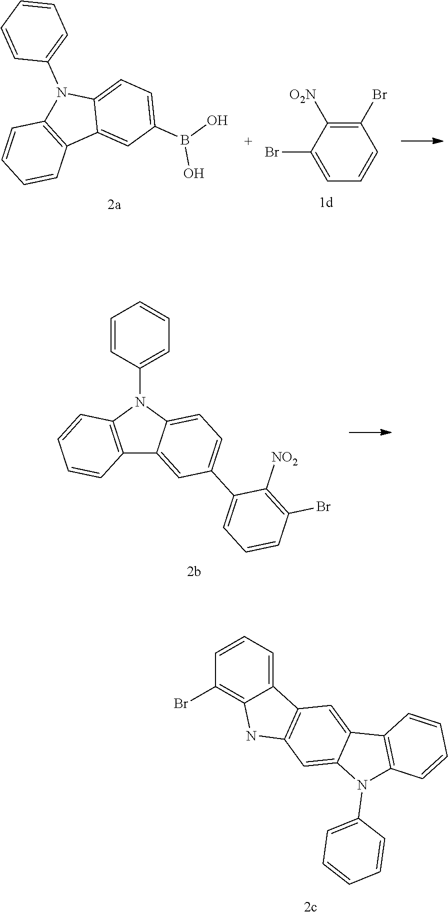 [SMILES: OB(O)c1ccc2c(c1)c1ccccc1n2-c1ccccc1 ; O=[N+]([O-])c1c(Br)cccc1Br ; O=[N+]([O-])c1c(Br)cccc1-c1ccc2c(c1)c1ccccc1n2-c1ccccc1 ; Brc1cccc2c1[nH]c1cc3c(cc12)c1ccccc1n3-c1ccccc1]

2a (100 g), 1d (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 124 g of the crude product (intermediate 2b). After that, the resulting sample was separated by column chromatography (petroleum ether:ethyl acetate=15:1) to yield 114.2 g (yield: 75%) of intermediate 2b.

Intermediate 2b (100 g), triethyl phosphite (50 g), and DMF (1000 mL) were added to a three-necked flask under N₂ atmosphere. After heating up to 150° C., the resulting mixture was refluxed for 24 h and then cooled down. After the extraction with ethyl acetate and deionized-water, the organic phase was washed with water two times, dried, filtered, and the solvent was removed to obtain 75 g of the crude product (intermediate 2c). After that, the resulting sample was separated by column chromatography (petroleum ether:ethyl acetate=15:1) to yield 72 g (yield: 70%) of intermediate 2c. MS(ASAP)=410.3.

### Synthesis of intermediate 3c

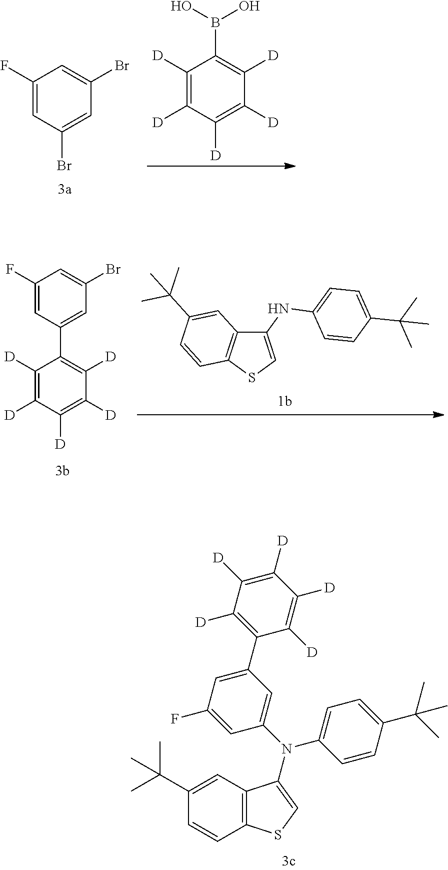

3a (100 g), phenyl-d5-boronic acid (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 180 g of the crude product (intermediate 3b). After that, the resulting sample was separated by column chromatography (petroleum ether:ethyl acetate=15:1) to yield 175 g (yield: 95%) of intermediate 3b.

Intermediate 3b (100 g), intermediate 1b (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further separated by silica gel column chromatography to yield 105 g (yield: 78%) of intermediate 3c. MS(ASAP)=573.6.

### Synthesis of intermediate 4c

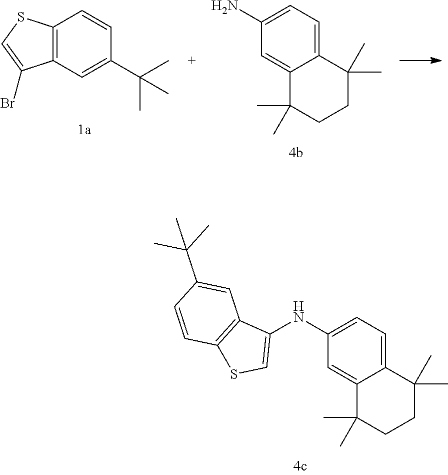 [SMILES: CC(C)(C)c1ccc2scc(Br)c2c1 ; CC1(C)CCC(C)(C)c2cc(N)ccc21 ; CC(C)(C)c1ccc2scc(Nc3ccc4c(c3)C(C)(C)CCC4(C)C)c2c1]

1a (100 g), intermediate 4b (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 167 g (yield: 91%) of intermediate 4c. MS(ASAP)=391.6.

### Synthesis of intermediate 4d

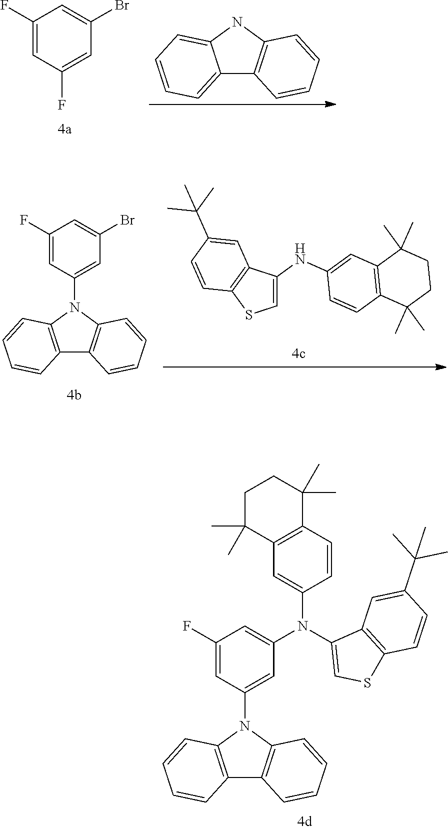

4a (100 g), carbazole (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 150 g of the crude product (intermediate 4b). After that, the resulting sample was separated by column chromatography (petroleum ether:ethyl acetate=15:1) to yield 142 g (yield: 71%) of intermediate 4b.

Intermediate 4b (100 g), intermediate 4c (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 152 g (yield: 85%) of intermediate 4d. MS(ASAP)=650.9.

### Synthesis of intermediate 5b

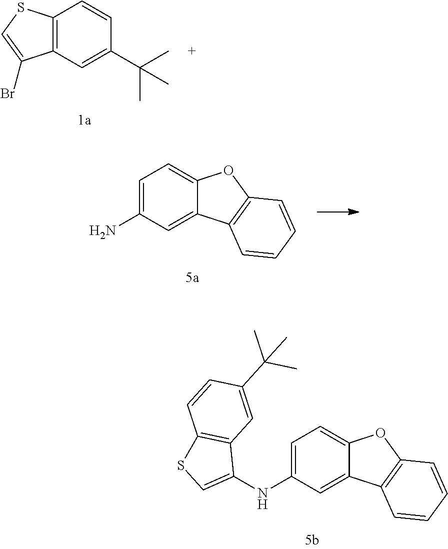

1a (100 g), 5a (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 131 g (yield: 78%) of intermediate 5b. MS(ASAP)=371.5.

### Synthesis of intermediate 5c

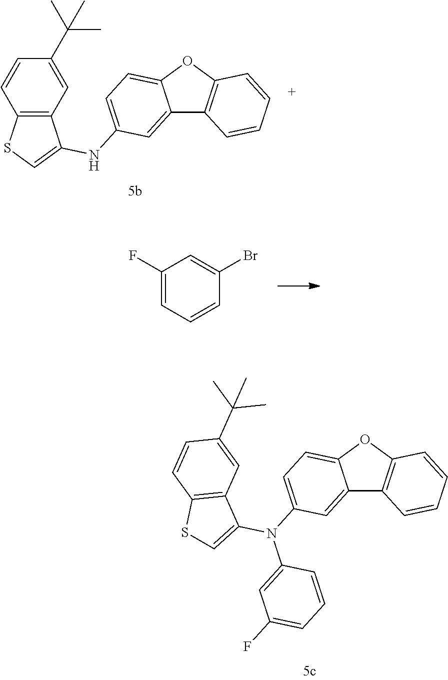 [SMILES: CC(C)(C)c1ccc2scc(Nc3ccc4oc5ccccc5c4c3)c2c1 ; Fc1cccc(Br)c1 ; CC(C)(C)c1ccc2scc(N(c3cccc(F)c3)c3ccc4oc5ccccc5c4c3)c2c1]

Intermediate 5b (100 g), 3-bromofluorobenzene (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 82 g (yield: 70%) of intermediate 5c. MS(ASAP)=465.6.

### Synthesis of intermediate 9d

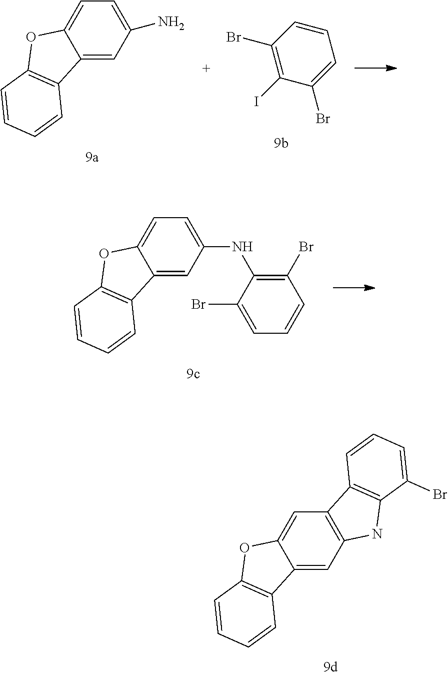 [SMILES: Nc1ccc2oc3ccccc3c2c1 ; Brc1cccc(Br)c1I ; Brc1cccc(Br)c1Nc1ccc2oc3ccccc3c2c1 ; Brc1cccc2c1[nH]c1cc3c(cc12)oc1ccccc13]

9a (100 g), 9b (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 82 g (yield: 71%) of intermediate 9c. MS(ASAP)=417.

Intermediate 9c (7.5 g, 20 mmol), sodium tert-butoxide (17.68 g, 184 mmol), palladium acetate (0.2 g, 1.0 mmol), and tri-tert-butylphosphine tetrafluoroborate (0.53 g, 1.8 mmol) were dissolved in 200 mL of 1,4-dioxane. After heating up to 110° C. under N₂ atmosphere, the resulting mixture was stirred for 18 h. After cooling down to room temperature, the resulting mixture was quenched with hydrochloric acid (2 M, 20 mL), then extracted with dichloromethane, and the organic phase was retained. After removing the organic solvent under reduced pressure distillation, the resulting sample was further purified by silica gel column chromatography to yield 1.4 g (yield: 20%) of intermediate 9d. MS(ASAP)=335.2.

### Synthesis of intermediate 10d

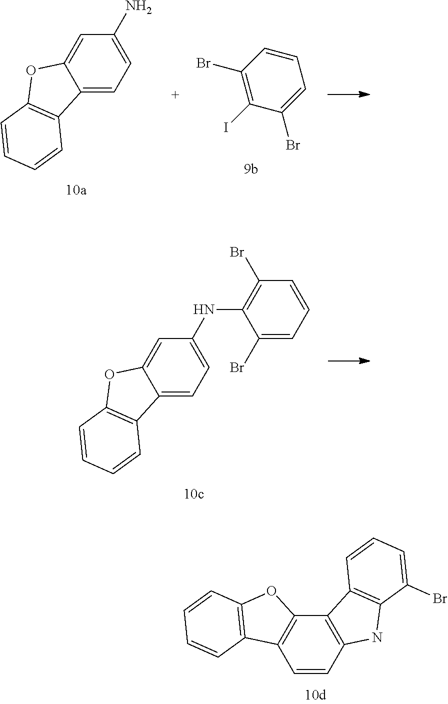 [SMILES: Nc1ccc2c(c1)oc1ccccc12 ; Brc1cccc(Br)c1I ; Brc1cccc(Br)c1Nc1ccc2c(c1)oc1ccccc12 ; Brc1cccc2c1[nH]c1ccc3c4ccccc4oc3c12]

The synthetic method of the intermediate 10d was similar to that of the intermediate 9d. 10a (100 g), 9b (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 85 g (yield: 80%) of intermediate 10c. MS(ASAP)=417.

Intermediate 10c (7.5 g, 20 mmol), sodium tert-butoxide (17.68 g, 184 mmol), palladium acetate (0.2 g, 1.0 mmol), and tri-tert-butylphosphine tetrafluoroborate (0.53 g, 1.8 mmol) were dissolved in 200 mL of 1,4-dioxane. After heating up to 110° C. under N₂ atmosphere, the resulting mixture was stirred for 18 h. After cooling down to room temperature, the resulting mixture was quenched with hydrochloric acid (2 M, 20 mL), then extracted with dichloromethane, and the organic phase was retained. After removing the organic solvent under reduced pressure distillation, the resulting sample was further purified by silica gel column chromatography to yield 1.6 g (yield: 20%) of intermediate 10d. MS(ASAP)=335.2.

### Synthesis of intermediate 11d

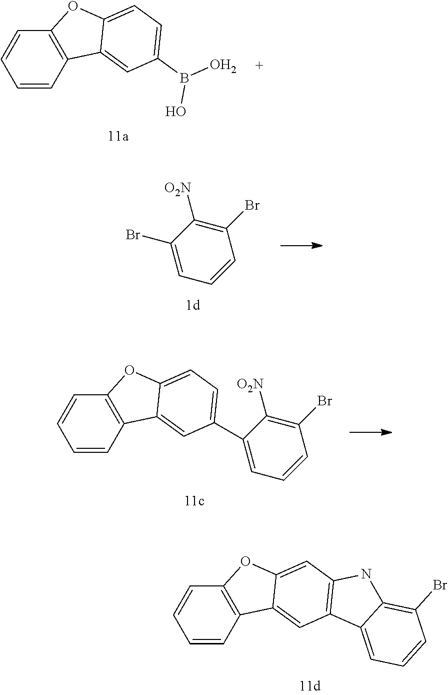 [SMILES: OB(O)c1ccc2oc3ccccc3c2c1 ; O=[N+]([O-])c1c(Br)cccc1Br ; O=[N+]([O-])c1c(Br)cccc1-c1ccc2oc3ccccc3c2c1 ; Brc1cccc2c1[nH]c1cc3oc4ccccc4c3cc12]

1a (100 g), 1d (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 100 g of the crude product (intermediate 11c). After that, the resulting sample was separated by column chromatography (petroleum ether:ethyl acetate=15:1) to yield 94.2 g (yield: 70%) of intermediate 11c.

Intermediate 11c (100 g), triethyl phosphite (50 g), and DMF (1000 mL) were added to a three-necked flask under N₂ atmosphere. After heating up to 150° C., the resulting mixture was refluxed for 24 h and then cooled down. After the extraction with ethyl acetate and deionized-water, the organic phase was washed with water two times, dried, filtered, and the solvent was removed to obtain 75 g of the crude product (intermediate 11d). After that, the resulting sample was separated by column chromatography (petroleum ether:ethyl acetate=15:1) to yield 70 g (yield: 65%) of intermediate 11d. MS(ASAP)=335.2.

### Synthesis of intermediate 12d

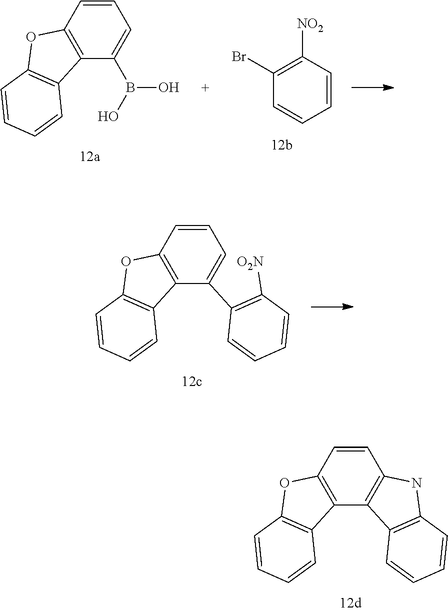 [SMILES: OB(O)c1cccc2oc3ccccc3c12 ; O=[N+]([O-])c1ccccc1Br ; O=[N+]([O-])c1ccccc1-c1cccc2oc3ccccc3c12 ; c1ccc2c(c1)[nH]c1ccc3oc4ccccc4c3c12]

12a (100 g), 12b (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 105 g of the crude product (intermediate 12c). After that, the resulting sample was separated by column chromatography (petroleum ether:ethyl acetate=15:1) to yield 95.2 g (yield: 71%) of intermediate 12c.

Intermediate 12c (100 g), triethyl phosphite (50 g), and DMF (1000 mL) were added to a three-necked flask under N₂ atmosphere. After heating up to 150° C., the resulting mixture was refluxed for 24 h and then cooled down. After the extraction with ethyl acetate and deionized-water, the organic phase was washed with water two times, dried, filtered, and the solvent was removed to obtain 75 g of the crude product (intermediate 12d). After that, the resulting sample was separated by column chromatography (petroleum ether:ethyl acetate=15:1) to yield 78 g (yield: 67%) of intermediate 12d. MS(ASAP)=255.

### Synthesis of intermediate 13b

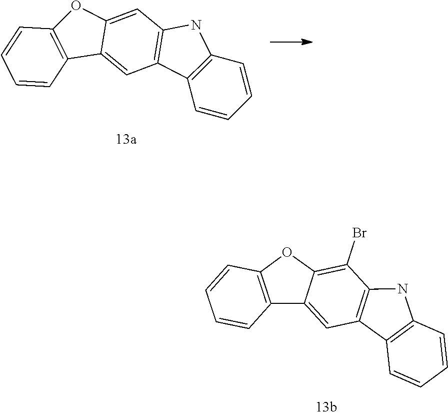

13a (100 g) and dichloro (100 mL) were added to a three-necked flask under N₂ atmosphere, 1 eq of NBS was slowly added to the above mixture, then the resulting mixture was reacted for 2 h. After the extraction with water, the organic phase was washed with water two times, dried, filtered, and the solvent was removed to obtain 15 g of the crude product (intermediate 13b). After that, the resulting sample was separated by column chromatography (petroleum ether:ethyl acetate=15:1) to yield 10 g (yield: 10%) of intermediate 13b. MS(ASAP)=335.2.

### Synthesis of intermediate 14c

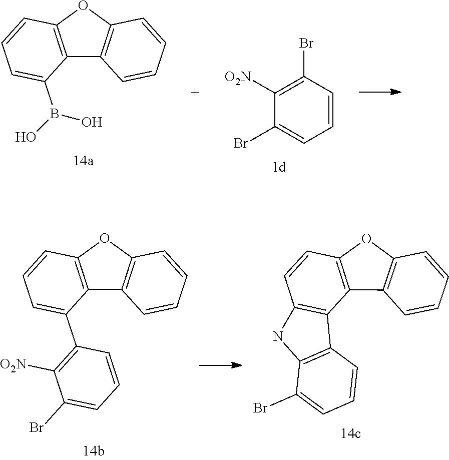

14a (100 g), 1d (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 115 g of the crude product (14b). After that, the resulting sample was separated by column chromatography (petroleum ether:ethyl acetate=15:1) to yield 99.5 g (yield: 80%) of 14b.

14b (100 g), triethyl phosphite (50 g), and DMF (1000 mL) were added to a three-necked flask under N₂ atmosphere. After heating up to 150° C., the resulting mixture was refluxed for 24 h and then cooled down. After the extraction with ethyl acetate and deionized-water, the organic phase was washed with water two times, dried, filtered, and the solvent was removed to obtain 73 g of the crude product (intermediate 14c). After that, the resulting sample was separated by column chromatography (petroleum ether:ethyl acetate=15:1) to yield 69 g (yield: 66%) of intermediate 14c. MS(ASAP)=335.2.

### Synthesis of intermediate 15c

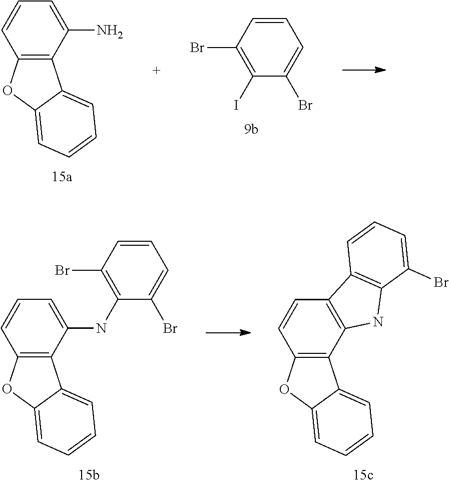

The synthetic method of the intermediate 15c was similar to that of the intermediate 9d. 15a (100 g), 9b (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 83 g (yield: 80%) of intermediate 15b. MS(ASAP)=416.09.

Intermediate 15b (7.5 g, 20 mmol), sodium tert-butoxide (17.68 g, 184 mmol), palladium acetate (0.2 g, 1.0 mmol), and tri-tert-butylphosphine tetrafluoroborate (0.53 g, 1.8 mmol) were dissolved in 200 mL of 1,4-dioxane. After heating up to 110° C. under N₂ atmosphere, the resulting mixture was stirred for 18 h. After cooling down to room temperature, the resulting mixture was quenched with hydrochloric acid (2 M, 20 mL), then extracted with dichloromethane, and the organic phase was retained. After removing the organic solvent under reduced pressure distillation, the resulting sample was further purified by silica gel column chromatography to yield 1.3 g (yield: 18%) of intermediate 15c. MS(ASAP)=335.2.

### Synthesis of intermediate 16d

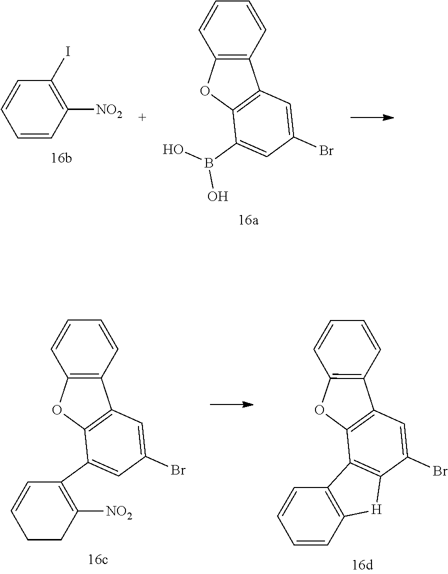

16a (the synthetic method refers to the patent: CN107922837A) (100 g), 16b (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 106 g of the crude product (16c).

After that, the resulting sample was separated by column chromatography (petroleum ether:ethyl acetate=15:1) to yield 93.5 g (yield: 70%) of 16c.

16c (100 g), triethyl phosphite (50 g), and DMF (1000 mL) were added to a three-necked flask under N₂ atmosphere. After heating up to 150° C., the resulting mixture was refluxed for 24 h and then cooled down. After the extraction with ethyl acetate and deionized-water, the organic phase was washed with water two times, dried, filtered, and the solvent was removed to obtain 72 g of the crude product (intermediate 16d). After that, the resulting sample was separated by column chromatography (petroleum ether:ethyl acetate=15:1) to yield 64 g (yield: 65%) of intermediate 16d. MS(ASAP)=335.2.

### Synthesis of intermediate 17c

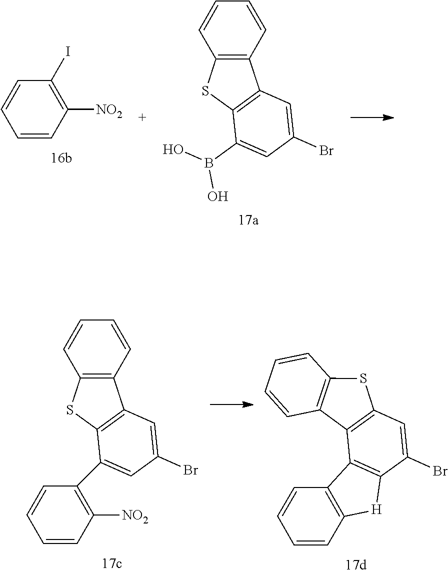

17a (the synthetic method refers to the patent: CN107922837A) (100 g), 16b (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 109 g of the crude product (17b).

After that, the resulting sample was separated by column chromatography (petroleum ether:ethyl acetate=15:1) to yield 94.5 g (yield: 70%) of 17b.

17b (100 g), triethyl phosphite (50 g), and DMF (1000 mL) were added to a three-necked flask under N₂ atmosphere. After heating up to 150° C., the resulting mixture was refluxed for 24 h and then cooled down. After the extraction with ethyl acetate and deionized-water, the organic phase was washed with water two times, dried, filtered, and the solvent was removed to obtain 74 g of the crude product (intermediate 17c). After that, the resulting sample was separated by column chromatography (petroleum ether:ethyl acetate=15:1) to yield 66 g (yield: 65%) of intermediate 17c. MS(ASAP)=335.2.

### Synthesis of intermediate 18c

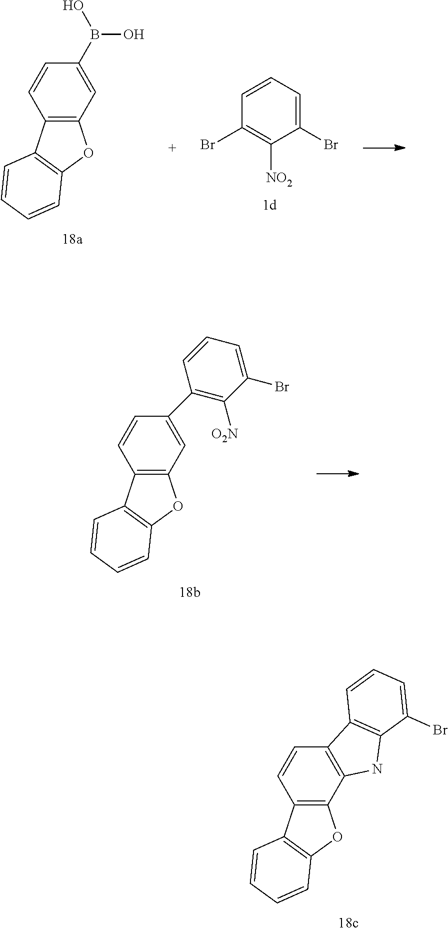 [SMILES: OB(O)c1ccc2c(c1)oc1ccccc12 ; O=[N+]([O-])c1c(Br)cccc1Br ; O=[N+]([O-])c1c(Br)cccc1-c1ccc2c(c1)oc1ccccc12 ; Brc1cccc2c1[nH]c1c2ccc2c3ccccc3oc21]

18a (100 g), 1d (100 g), potassium carbonate (25 g), tetrakis(triphenylphosphine)palladium (3 g), and 1000 mL of toluene/50 mL of ethanol/50 mL of water were added to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 101 g of the crude product (18b). After that, the resulting sample was separated by column chromatography (petroleum ether:ethyl acetate=15:1) to yield 90.5 g (yield: 68%) of 18b.

18b (100 g), triethyl phosphite (50 g), and DMF (1000 mL) were added to a three-necked flask under N₂ atmosphere. After heating up to 150° C., the resulting mixture was refluxed for 24 h and then cooled down. After the extraction with ethyl acetate and deionized-water, the organic phase was washed with water two times, dried, filtered, and the solvent was removed to obtain 70 g of the crude product (intermediate 18c). After that, the resulting sample was separated by column chromatography (petroleum ether:ethyl acetate=15:1) to yield 67 g (yield: 65%) of intermediate 18c. MS(ASAP)=335.2.

### Synthesis of compound 1

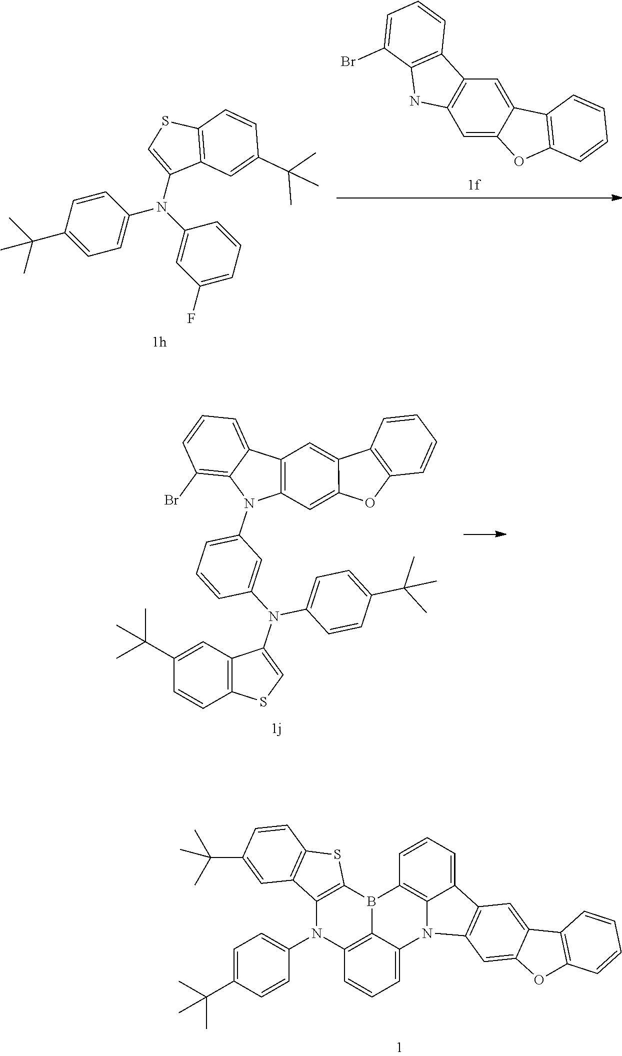 [SMILES: CC(C)(C)c1ccc(N(c2cccc(F)c2)c2csc3ccc(C(C)(C)C)cc23)cc1 ; Brc1cccc2c1[nH]c1cc3oc4ccccc4c3cc12 ; CC(C)(C)c1ccc(N(c2cccc(-n3c4cc5oc6ccccc6c5cc4c4cccc(Br)c43)c2)c2csc3ccc(C(C)(C)C)cc23)cc1 ; CC(C)(C)c1ccc(N2c3cccc4c3B(c3sc5ccc(C(C)(C)C)cc5c32)c2cccc3c5cc6c(cc5n-4c23)oc2ccccc26)cc1]

Intermediate 1h (50 g), intermediate 1f (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 105 g (yield: 92%) of intermediate 1j.

Intermediate 1j (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 3.3 g (yield: 34%) of compound 1. MS(ASAP)=676.7.

### Synthesis of compound 2

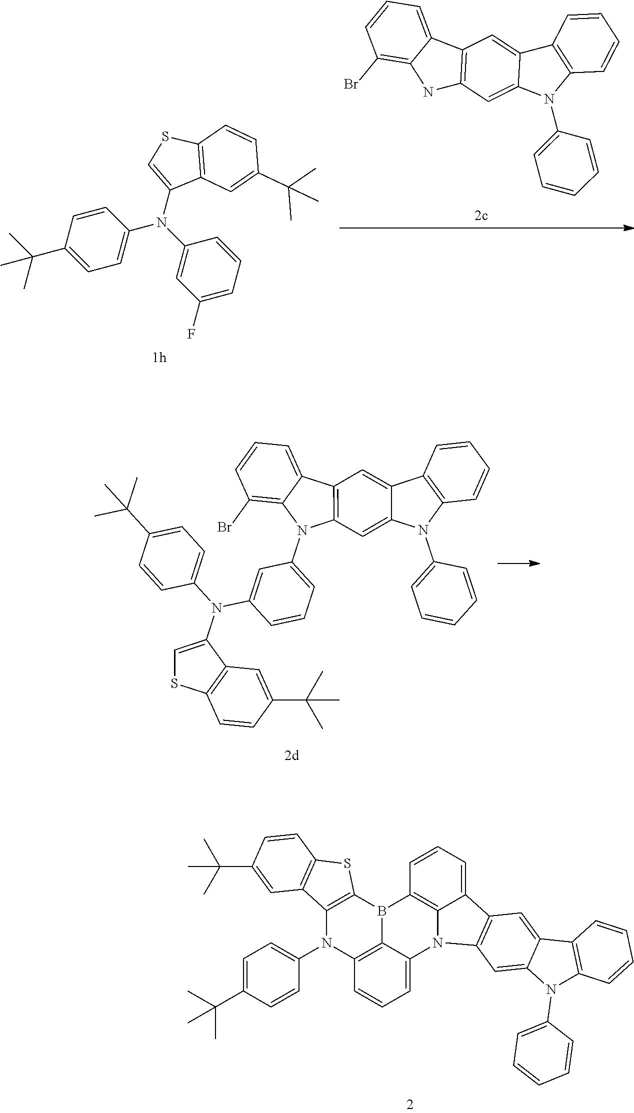 [SMILES: CC(C)(C)c1ccc(N(c2cccc(F)c2)c2csc3ccc(C(C)(C)C)cc23)cc1 ; Brc1cccc2c1[nH]c1cc3c(cc12)c1ccccc1n3-c1ccccc1 ; CC(C)(C)c1ccc(N(c2cccc(-n3c4cc5c(cc4c4cccc(Br)c43)c3ccccc3n5-c3ccccc3)c2)c2csc3ccc(C(C)(C)C)cc23)cc1 ; CC(C)(C)c1ccc(N2c3cccc4c3B(c3sc5ccc(C(C)(C)C)cc5c32)c2cccc3c5cc6c7ccccc7n(-c7ccccc7)c6cc5n-4c23)cc1]

Intermediate 1h (50 g), intermediate 2c (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 112 g (yield: 95%) of intermediate 2d.

Intermediate 2d (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 3.9 g (yield: 41%) of compound 2. MS(ASAP)=751.8.

### Synthesis of compound 3

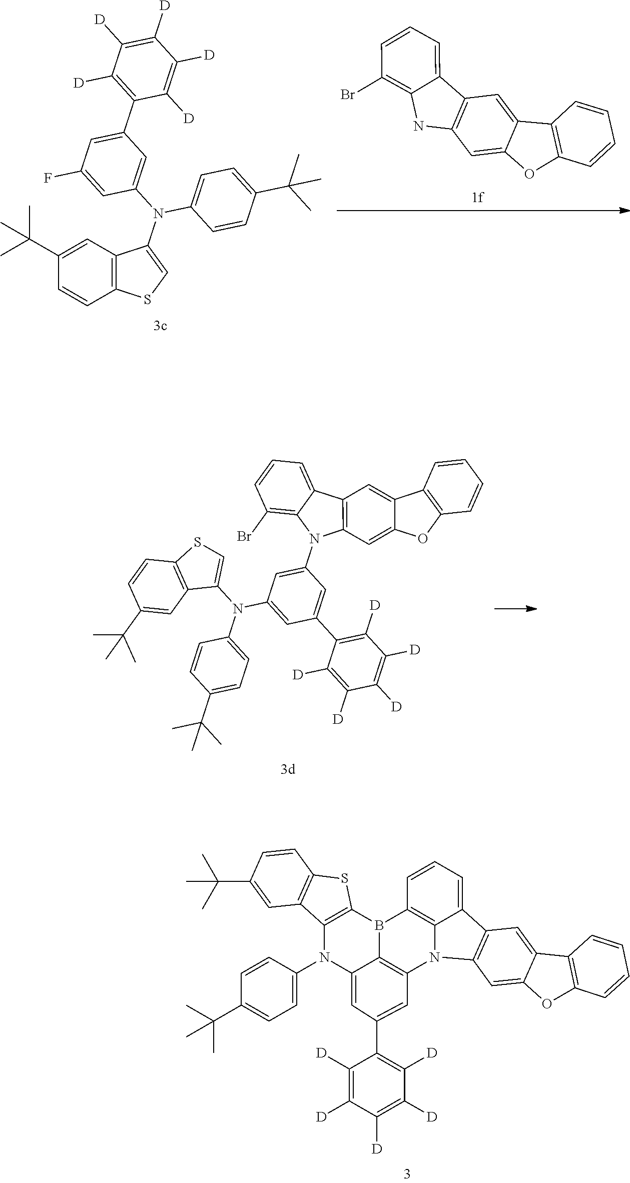 [SMILES: [2H]c1c([2H])c([2H])c(-c2cc(F)cc(N(c3ccc(C(C)(C)C)cc3)c3csc4ccc(C(C)(C)C)cc34)c2)c([2H])c1[2H] ; Brc1cccc2c1[nH]c1cc3oc4ccccc4c3cc12 ; [2H]c1c([2H])c([2H])c(-c2cc(N(c3ccc(C(C)(C)C)cc3)c3csc4ccc(C(C)(C)C)cc34)cc(-n3c4cc5oc6ccccc6c5cc4c4cccc(Br)c43)c2)c([2H])c1[2H] ; [2H]c1c([2H])c([2H])c(-c2cc3c4c(c2)-n2c5cc6oc7ccccc7c6cc5c5cccc(c52)B4c2sc4ccc(C(C)(C)C)cc4c2N3c2ccc(C(C)(C)C)cc2)c([2H])c1[2H]]

Intermediate 1f (50 g), intermediate 3c (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 101 g (yield: 95%) of intermediate 3d.

Intermediate 3d (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 2.1 g (yield: 24%) of compound 3. MS(ASAP)=757.81.

### Synthesis of compound 4

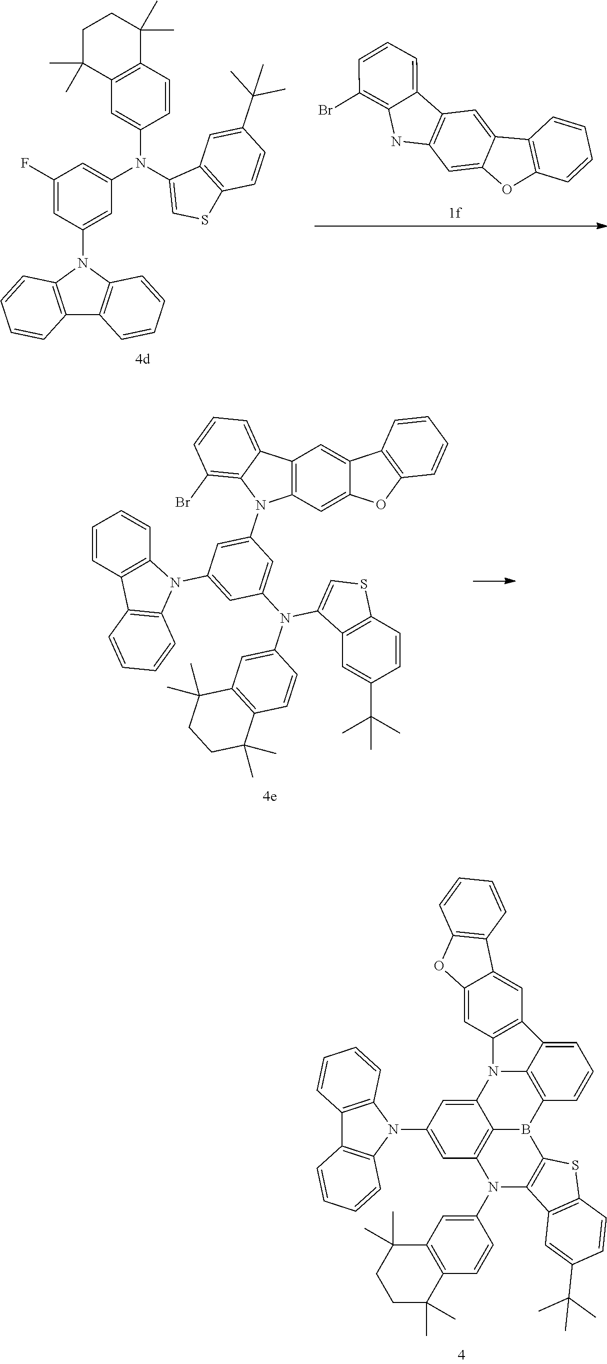 [SMILES: CC(C)(C)c1ccc2scc(N(c3cc(F)cc(-n4c5ccccc5c5ccccc54)c3)c3ccc4c(c3)C(C)(C)CCC4(C)C)c2c1 ; Brc1cccc2c1[nH]c1cc3oc4ccccc4c3cc12 ; CC(C)(C)c1ccc2scc(N(c3cc(-n4c5ccccc5c5ccccc54)cc(-n4c5cc6oc7ccccc7c6cc5c5cccc(Br)c54)c3)c3ccc4c(c3)C(C)(C)CCC4(C)C)c2c1 ; CC(C)(C)c1ccc2sc3c(c2c1)N(c1ccc2c(c1)C(C)(C)CCC2(C)C)c1cc(-n2c4ccccc4c4ccccc42)cc2c1B3c1cccc3c4cc5c(cc4n-2c13)oc1ccccc15]

Intermediate 4d (50 g), intermediate 1f (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 43 g (yield: 53%) of intermediate 4e.

Intermediate 4e (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 2.6 g (yield: 30%) of compound 4. MS(ASAP)=895.9.

### Synthesis of compound 5

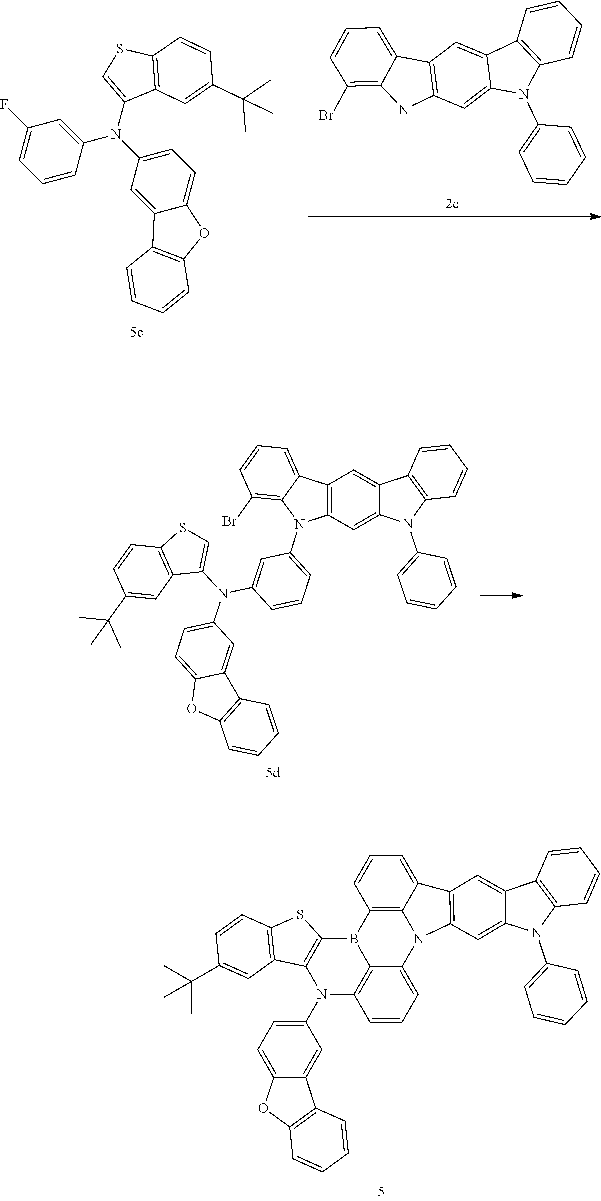 [SMILES: CC(C)(C)c1ccc2scc(N(c3cccc(F)c3)c3ccc4oc5ccccc5c4c3)c2c1 ; Brc1cccc2c1[nH]c1cc3c(cc12)c1ccccc1n3-c1ccccc1 ; CC(C)(C)c1ccc2scc(N(c3cccc(-n4c5cc6c(cc5c5cccc(Br)c54)c4ccccc4n6-c4ccccc4)c3)c3ccc4oc5ccccc5c4c3)c2c1 ; CC(C)(C)c1ccc2sc3c(c2c1)N(c1ccc2oc4ccccc4c2c1)c1cccc2c1B3c1cccc3c4cc5c6ccccc6n(-c6ccccc6)c5cc4n-2c13]

Intermediate 5c (50 g), intermediate 2c (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 52 g (yield: 64%) of intermediate 5d.

Intermediate 5d (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 2.5 g (yield: 30%) of compound 5. MS(ASAP)=785.7.

### Synthesis of compound 6

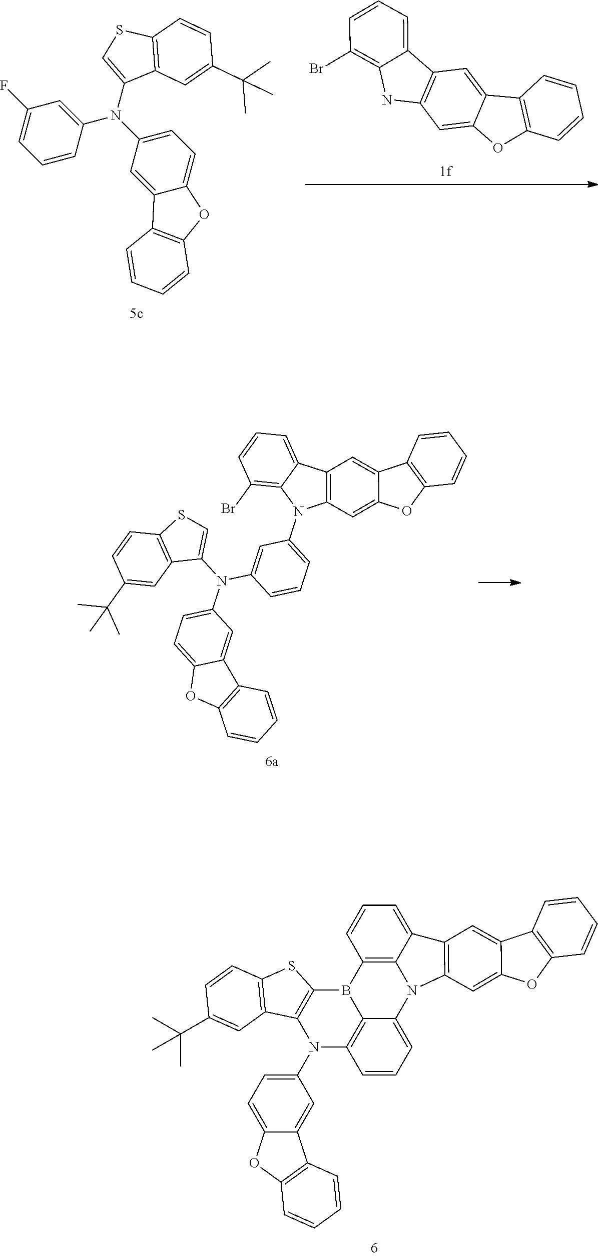 [SMILES: CC(C)(C)c1ccc2scc(N(c3cccc(F)c3)c3ccc4oc5ccccc5c4c3)c2c1 ; Brc1cccc2c1[nH]c1cc3oc4ccccc4c3cc12 ; CC(C)(C)c1ccc2scc(N(c3cccc(-n4c5cc6oc7ccccc7c6cc5c5cccc(Br)c54)c3)c3ccc4oc5ccccc5c4c3)c2c1 ; CC(C)(C)c1ccc2sc3c(c2c1)N(c1ccc2oc4ccccc4c2c1)c1cccc2c1B3c1cccc3c4cc5c(cc4n-2c13)oc1ccccc15]

Intermediate 5c (50 g), intermediate 1f (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 54 g (yield: 65%) of intermediate 6a.

Intermediate 6a (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 2.4 g (yield: 30%) of compound 6. MS(ASAP)=710.6.

### Synthesis of compound 7

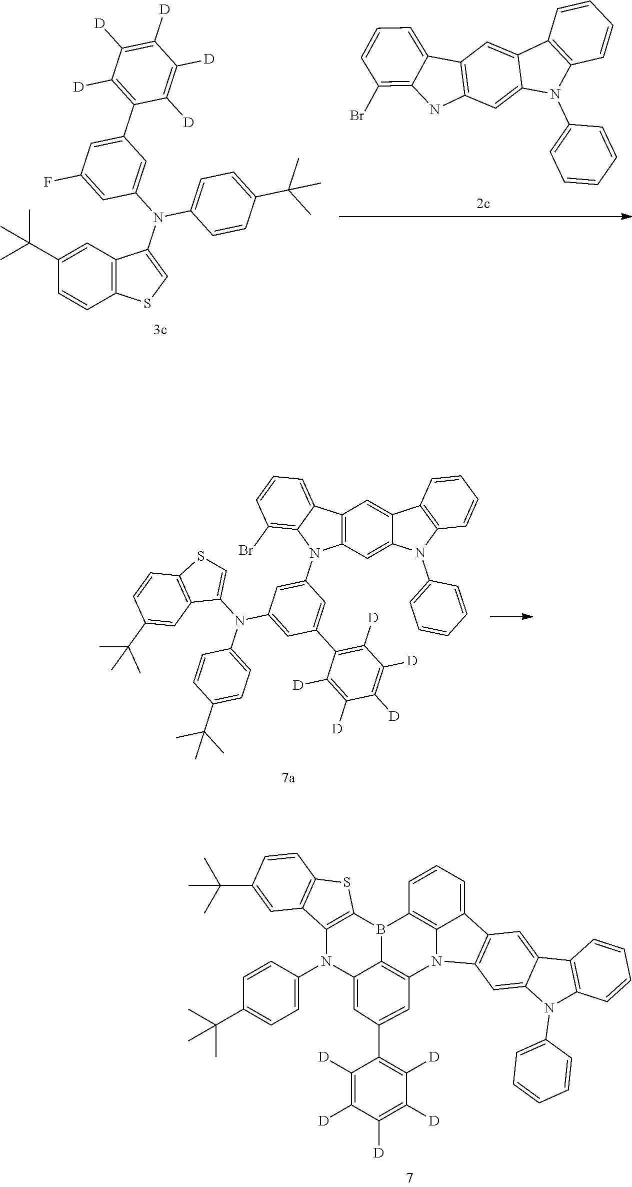 [SMILES: [2H]c1c([2H])c([2H])c(-c2cc(F)cc(N(c3ccc(C(C)(C)C)cc3)c3csc4ccc(C(C)(C)C)cc34)c2)c([2H])c1[2H] ; Brc1cccc2c1[nH]c1cc3c(cc12)c1ccccc1n3-c1ccccc1 ; [2H]c1c([2H])c([2H])c(-c2cc(N(c3ccc(C(C)(C)C)cc3)c3csc4ccc(C(C)(C)C)cc34)cc(-n3c4cc5c(cc4c4cccc(Br)c43)c3ccccc3n5-c3ccccc3)c2)c([2H])c1[2H] ; [2H]c1c([2H])c([2H])c(-c2cc3c4c(c2)-n2c5cc6c(cc5c5cccc(c52)B4c2sc4ccc(C(C)(C)C)cc4c2N3c2ccc(C(C)(C)C)cc2)c2ccccc2n6-c2ccccc2)c([2H])c1[2H]]

Intermediate 3c (50 g), intermediate 2c (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 59 g (yield: 67%) of intermediate 7a.

Intermediate 7a (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 2.5 g (yield: 30%) of compound 7. MS(ASAP)=832.9.

### Synthesis of compound 8

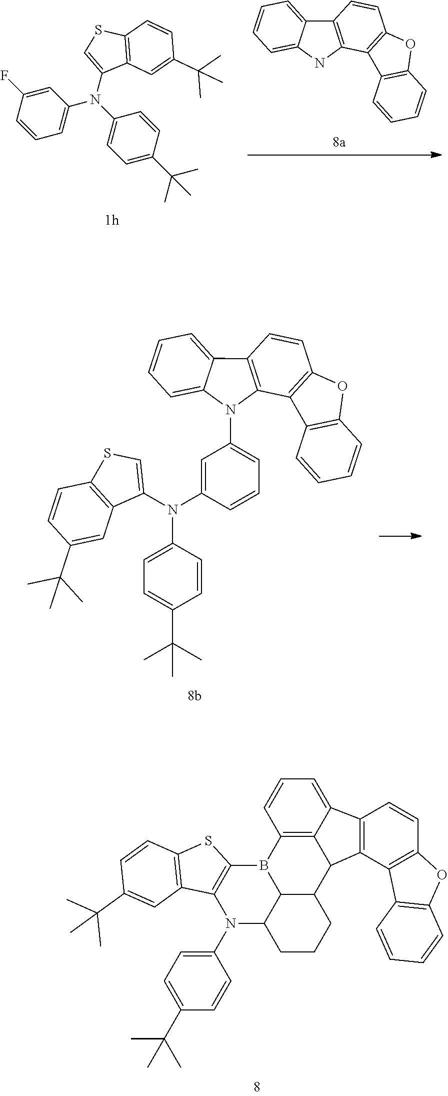

Intermediate 1h (50 g), 8a (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 54 g (yield: 65%) of intermediate 8b.

Intermediate 8b (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 2.4 g (yield: 30%) of compound 8. MS(ASAP)=676.7.

### Synthesis of compound 9

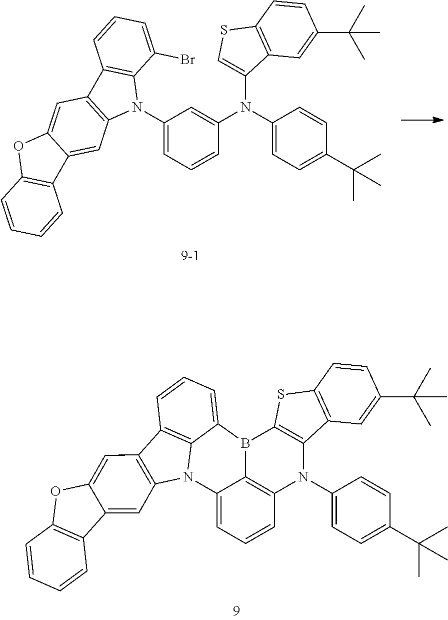 [SMILES: CC(C)(C)c1ccc(N(c2cccc(-n3c4cc5c(cc4c4cccc(Br)c43)oc3ccccc35)c2)c2csc3ccc(C(C)(C)C)cc23)cc1 ; CC(C)(C)c1ccc(N2c3cccc4c3B(c3sc5ccc(C(C)(C)C)cc5c32)c2cccc3c5cc6oc7ccccc7c6cc5n-4c23)cc1]

The synthetic method of the compound 9 was similar to that of the compound 1 (intermediate 1f was replaced with intermediate 9d, intermediate 1j was replaced with intermediate 9-1, i.e., intermediate 9-1 was first formed under the action of base), Li salt was formed under the action of n-butyllithium, and then under the action of BBr₃, the final product compound 9 was formed with a yield of 8%, MS(ASAP)=676.7.

### Synthesis of compound 10

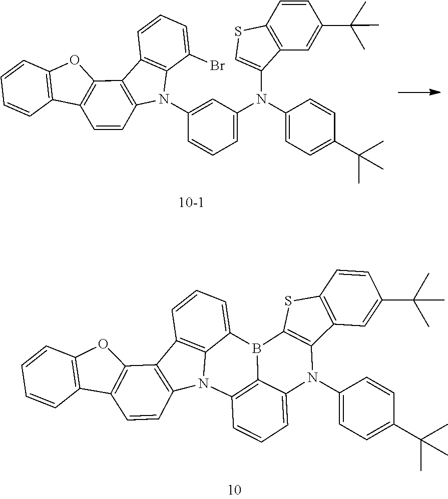 [SMILES: CC(C)(C)c1ccc(N(c2cccc(-n3c4ccc5c6ccccc6oc5c4c4cccc(Br)c43)c2)c2csc3ccc(C(C)(C)C)cc23)cc1 ; CC(C)(C)c1ccc(N2c3cccc4c3B(c3sc5ccc(C(C)(C)C)cc5c32)c2cccc3c5c6oc7ccccc7c6ccc5n-4c23)cc1]

The synthetic method of the compound 10 was similar to that of the compound 1 (intermediate 1f was replaced with intermediate 10d, intermediate 1j was replaced with intermediate 10-1, i.e., intermediate 10-1 was first formed under the action of base), Li salt was formed under the action of n-butyllithium, and then under the action of BBr₃, the final product compound 10 was formed with a yield of 6%, MS(ASAP)=676.7.

### Synthesis of compound 11

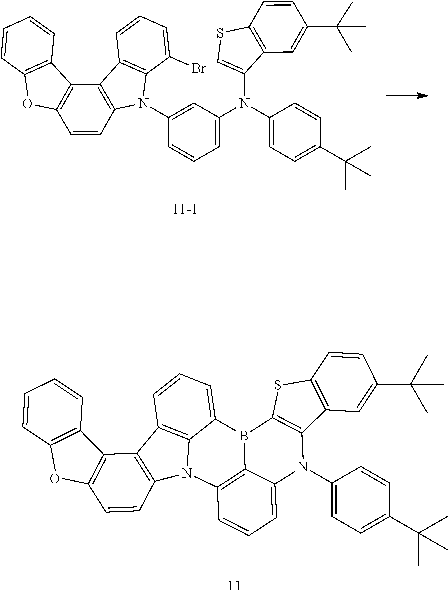 [SMILES: CC(C)(C)c1ccc(N(c2cccc(-n3c4ccc5oc6ccccc6c5c4c4cccc(Br)c43)c2)c2csc3ccc(C(C)(C)C)cc23)cc1 ; CC(C)(C)c1ccc(N2c3cccc4c3B(c3sc5ccc(C(C)(C)C)cc5c32)c2cccc3c5c6c(ccc5n-4c23)oc2ccccc26)cc1]

The synthetic method of the compound 11 was similar to that of the compound 1 (intermediate 1f was replaced with intermediate 11d, intermediate 1j was replaced with intermediate 11-1, i.e., intermediate 11-1 was first formed under the action of base), then Li salt was formed under the action of n-butyllithium, and then under the action of BBr₃, the final product compound 11 was formed with a yield of 10%, MS(ASAP)=676.7.

### Synthesis of compound 12

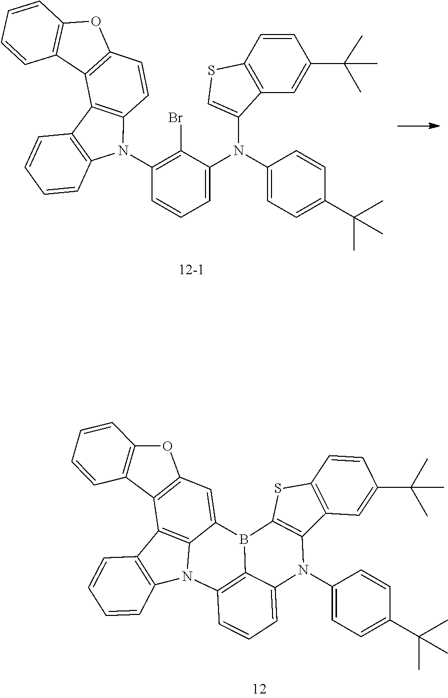 [SMILES: CC(C)(C)c1ccc(N(c2cccc(-n3c4ccccc4c4c5c(ccc43)oc3ccccc35)c2Br)c2csc3ccc(C(C)(C)C)cc23)cc1 ; CC(C)(C)c1ccc(N2c3cccc4c3B(c3sc5ccc(C(C)(C)C)cc5c32)c2cc3oc5ccccc5c3c3c5ccccc5n-4c23)cc1]

The synthetic method of the compound 12 was similar to that of the compound 1 (intermediate 1f was replaced with intermediate 12d, intermediate 1j was replaced with intermediate 12-1, i.e., intermediate 12-1 was first formed under the action of base), Li salt was formed under the action of n-butyllithium, and then under the action of BBr₃, the final product compound 12 was formed with a yield of 20%, MS(ASAP)=676.7.

### Synthesis of compound 13

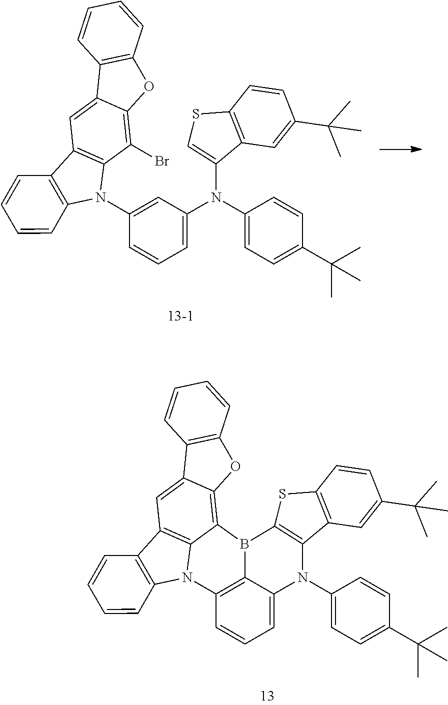 [SMILES: CC(C)(C)c1ccc(N(c2cccc(-n3c4ccccc4c4cc5c(oc6ccccc65)c(Br)c43)c2)c2csc3ccc(C(C)(C)C)cc23)cc1 ; CC(C)(C)c1ccc(N2c3cccc4c3B(c3sc5ccc(C(C)(C)C)cc5c32)c2c3oc5ccccc5c3cc3c5ccccc5n-4c23)cc1]

The synthetic method of the compound 13 was similar to that of the compound 1 (intermediate 1f was replaced with intermediate 13b, intermediate 1j was replaced with intermediate 13-1, i.e., intermediate 13-1 was first formed under the action of base), Li salt was formed under the action of n-butyllithium, and then under the action of BBr₃, the final product compound 13 was formed with a yield of 8%, MS(ASAP)=676.7.

### Synthesis of compound 14

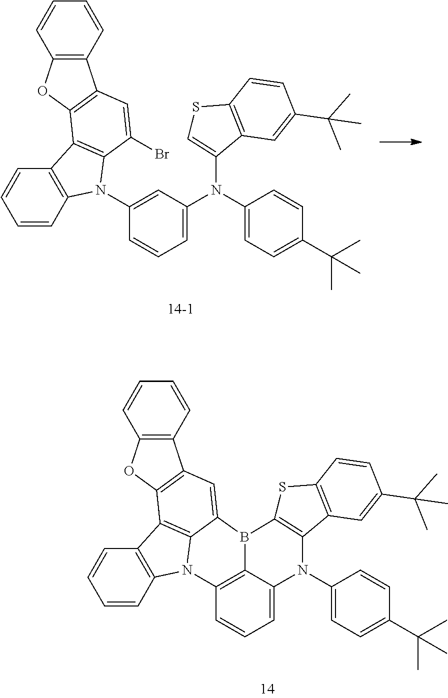 [SMILES: CC(C)(C)c1ccc(N(c2cccc(-n3c4ccccc4c4c5oc6ccccc6c5cc(Br)c43)c2)c2csc3ccc(C(C)(C)C)cc23)cc1 ; CC(C)(C)c1ccc(N2c3cccc4c3B(c3sc5ccc(C(C)(C)C)cc5c32)c2cc3c5ccccc5oc3c3c5ccccc5n-4c23)cc1]

The synthetic method of the compound 14 was similar to that of the compound 1 (intermediate 1f is replaced with intermediate 14c, intermediate 1j is replaced with intermediate 14-1, i.e., intermediate 14-1 was first formed under the action of base), Li salt was formed under the action of n-butyllithium, and then under the action of BBr₃, the final product compound 14 was formed with a yield of 5%, MS(ASAP)=676.7.

### Synthesis of compound 15

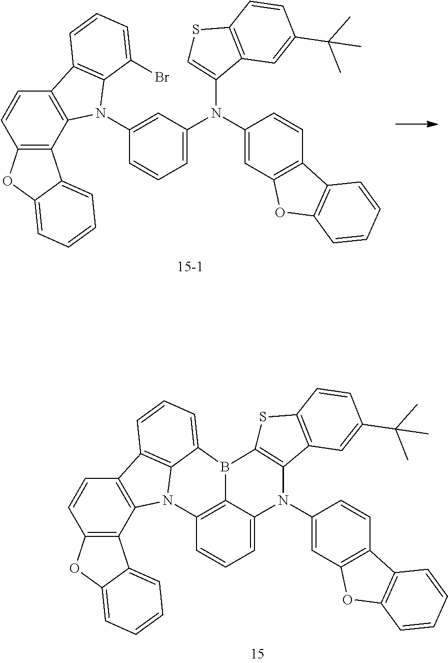 [SMILES: CC(C)(C)c1ccc2scc(N(c3cccc(-n4c5c(Br)cccc5c5ccc6oc7ccccc7c6c54)c3)c3ccc4c(c3)oc3ccccc34)c2c1 ; CC(C)(C)c1ccc2sc3c(c2c1)N(c1ccc2c(c1)oc1ccccc12)c1cccc2c1B3c1cccc3c4ccc5oc6ccccc6c5c4n-2c13]

The synthetic method of the compound 15 was similar to that of the compound 5 (intermediate 2c was replaced with intermediate 15c, intermediate 5d was replaced with intermediate 15-1, i.e., intermediate 15-1 was first formed under the action of base), Li salt was formed under the action of n-butyllithium, and then under the action of BBr₃, the final product compound 15 was formed with a yield of 7%, MS(ASAP)=710.6.

### Synthesis of compound 16

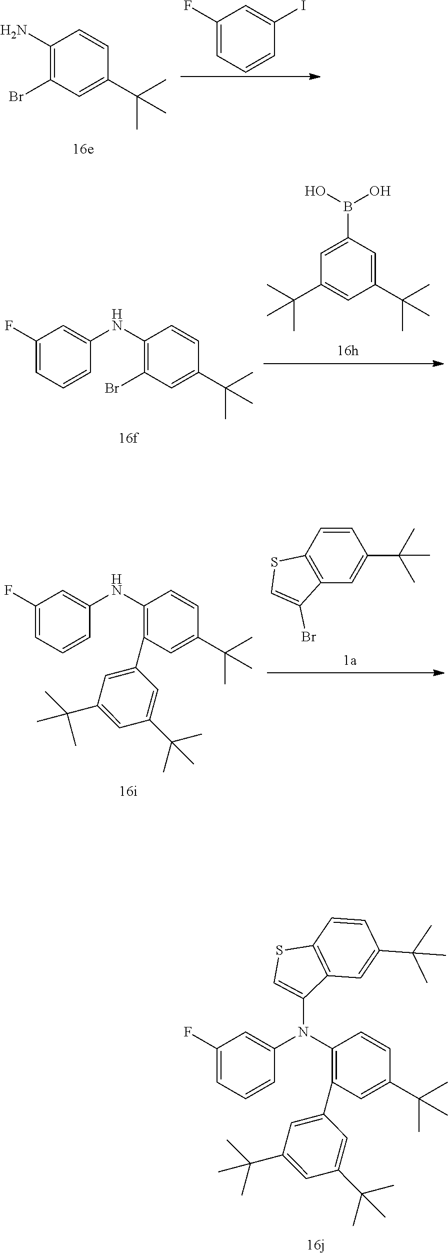

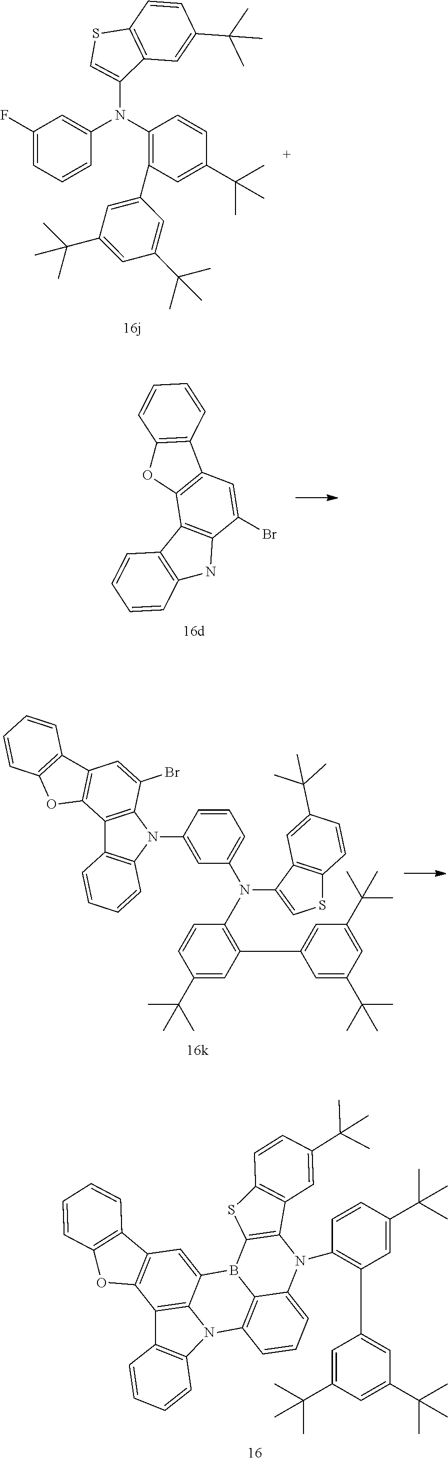 [SMILES: CC(C)(C)c1cc(-c2cc(C(C)(C)C)ccc2N(c2cccc(F)c2)c2csc3ccc(C(C)(C)C)cc23)cc(C(C)(C)C)c1 ; Brc1cc2c3ccccc3oc2c2c1[nH]c1ccccc12 ; CC(C)(C)c1cc(-c2cc(C(C)(C)C)ccc2N(c2cccc(-n3c4ccccc4c4c5oc6ccccc6c5cc(Br)c43)c2)c2csc3ccc(C(C)(C)C)cc23)cc(C(C)(C)C)c1 ; CC(C)(C)c1cc(-c2cc(C(C)(C)C)ccc2N2c3cccc4c3B(c3sc5ccc(C(C)(C)C)cc5c32)c2cc3c5ccccc5oc3c3c5ccccc5n-4c23)cc(C(C)(C)C)c1]

16e (100 g), 1-fluoro-3-iodobenzene (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 116 g (yield: 89%) of intermediate 16f.

Intermediate 16f (100 g), 16h (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 98 g (yield: 85%) of intermediate 16i.

Intermediate 16i (100 g), 1a (100 g), tris(dibenzylideneacetone)dipalladium (16 g), and anhydrous sodium tert-butoxide (67 g) were dissolved in 500 mL of toluene, and the resulting mixture was stirred at 90° C. for 2 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 96 g (yield: 80%) of intermediate 16j.

Intermediate 16j (50 g), intermediate 16d (110 g), and anhydrous cesium carbonate (285 g) were dissolved in 500 mL of anhydrous N,N-dimethylformamide, the resulting mixture was stirred at 100° C. for 8 h. After cooling down to room temperature, the reaction was extracted with a large amount of deionized-water and dichloromethane, then the organic phase was retained. After removing the organic solvent under reduced pressure distillation, the resulting sample was further purified by silica gel column chromatography to yield 55 g (yield: 67%) of intermediate 16 k.

Intermediate 16 k (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained.

After removing the organic solvent under reduced pressure distillation, the resulting sample was further purified by silica gel column chromatography to yield 2.5 g (yield: 6%) of compound 16.

MS(ASAP)=865.

### Synthesis of compound 17

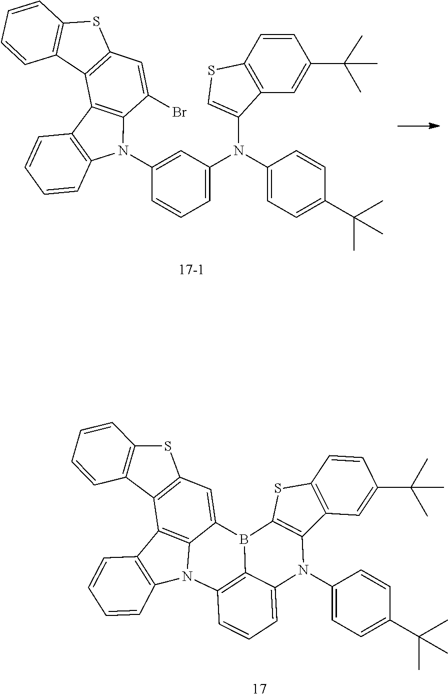 [SMILES: CC(C)(C)c1ccc(N(c2cccc(-n3c4ccccc4c4c5c(cc(Br)c43)sc3ccccc35)c2)c2csc3ccc(C(C)(C)C)cc23)cc1 ; CC(C)(C)c1ccc(N2c3cccc4c3B(c3sc5ccc(C(C)(C)C)cc5c32)c2cc3sc5ccccc5c3c3c5ccccc5n-4c23)cc1]

The synthetic method of the compound 17 was similar to that of the compound 1 (intermediate 1f was replaced with intermediate 17c, intermediate 1j was replaced with intermediate 17-1, i.e., intermediate 17-1 was first formed under the action of base), Li salt was formed under the action of n-butyllithium, and then under the action of BBr₃, the final product compound 17 was formed with a yield of 4%, MS(ASAP)=692.75.

### Synthesis of compound 18

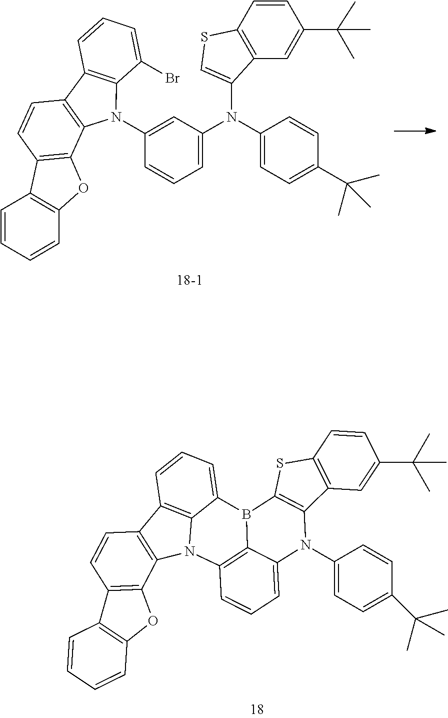 [SMILES: CC(C)(C)c1ccc(N(c2cccc(-n3c4c(Br)cccc4c4ccc5c6ccccc6oc5c43)c2)c2csc3ccc(C(C)(C)C)cc23)cc1 ; CC(C)(C)c1ccc(N2c3cccc4c3B(c3sc5ccc(C(C)(C)C)cc5c32)c2cccc3c5ccc6c7ccccc7oc6c5n-4c23)cc1]

The synthetic method of the compound 18 was similar to that of the compound 1 (intermediate 1f was replaced with intermediate 18c, intermediate 1j was replaced with intermediate 18-1, i.e., intermediate 18-1 was first formed under the action of base), Li salt was formed under the action of n-butyllithium, and then under the action of BBr₃, the final product compound 18 was formed with a yield of 8%, MS(ASAP)=710.6.

Comparative compound 1 (DB1)

The structure of the existing boron-nitrogen material is as follows.

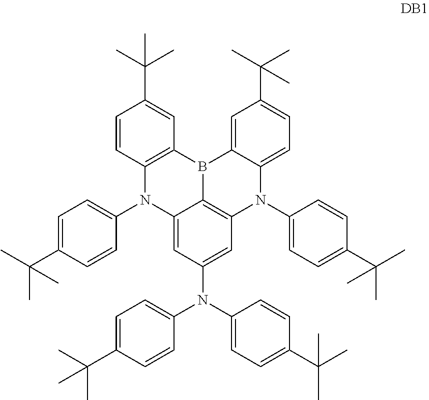 [SMILES: CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1]

The specific synthetic method of this existing boron-nitrogen material is sufficient to adopt the existing synthesis method, and the present disclosure will not be described in detail.

Comparative compound 2 (DB2)

The existing boron-nitrogen structure is as follows:

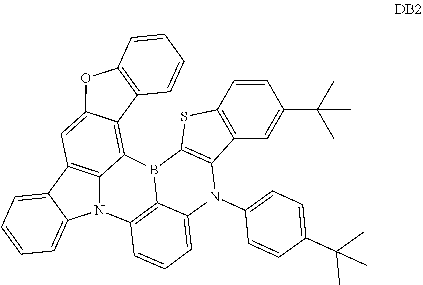 [SMILES: CC(C)(C)c1ccc(N2c3cccc4c3B(c3sc5ccc(C(C)(C)C)cc5c32)c2c3c(cc5c6ccccc6n-4c25)oc2ccccc23)cc1]

### Synthesis of comparative compound 2

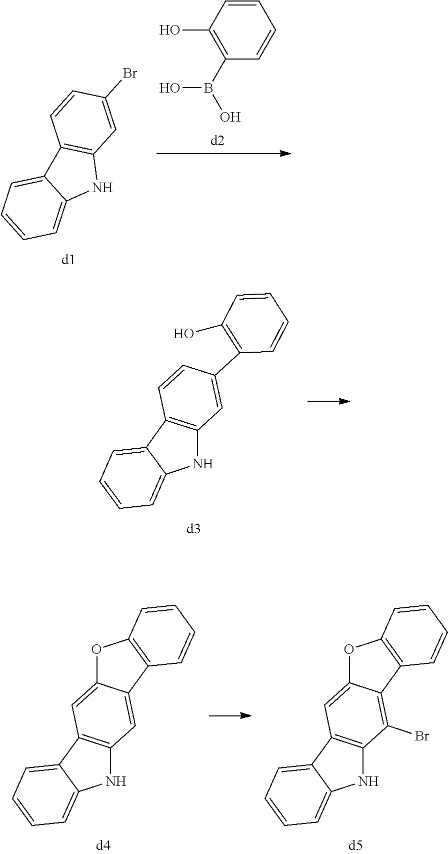 [SMILES: Brc1ccc2c(c1)[nH]c1ccccc12 ; OB(O)c1ccccc1O ; Oc1ccccc1-c1ccc2c(c1)[nH]c1ccccc12 ; c1ccc2c(c1)[nH]c1cc3c(cc12)oc1ccccc13 ; Brc1c2[nH]c3ccccc3c2cc2oc3ccccc3c12]

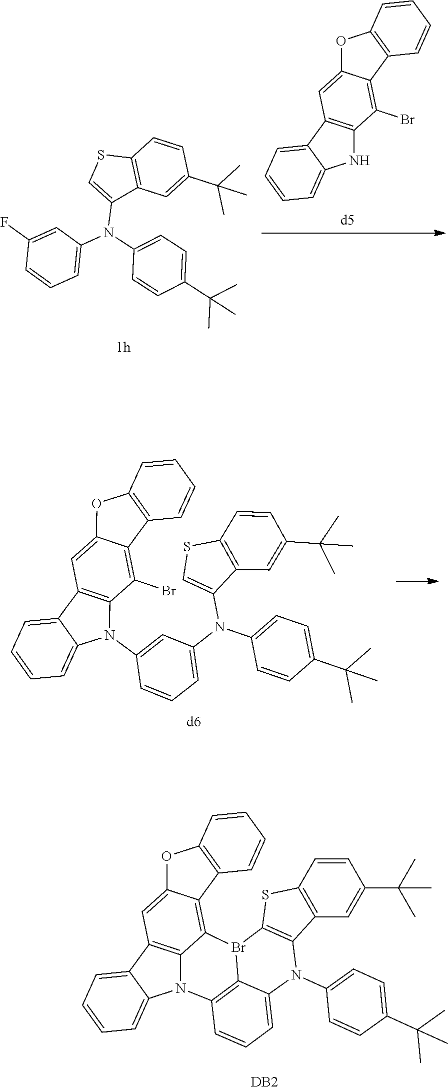

d1 (100 g), d2 (100 g), potassium carbonate (25 g), tetrakis(triphenylphosphine)palladium (3 g) and 1000 mL of toluene/50 mL of ethanol/50 mL of water were dded to a three-necked flask under N₂ atmosphere. After heating up to 100° C., the resulting mixture was refluxed for 12 h and then cooled down. After the extraction with ethyl acetate and deionized-water, the organic phase was washed with water two times, dried, filtered, and the solvent was removed to obtain 80 g of the crude product (d3). After that, the resulting sample was separated by column chromatography (petroleum ether:ethyl acetate=15:1) to yield 75 g (yield: 38%) of d3.

The synthesis of the compound d4 is described in the reference “Synthesis of Dibenzofurans via Palladium-Catalyzed Phenol-Directed C—H Activation/C—O Cyclization”, which will not be reiterated here.

Compound d4 (100 g) and dichloro (100 mL) were added to a three-necked flask under N₂ atmosphere, 1 eq of NBS was slowly added to the above mixture. After reacting for 2 h, the resulting mixture was extracted with water, the organic phase was washed with water two times, dried, filtered, and the solvent was removed to obtain 80 g of the crude product (d5). After that, the resulting sample was separated by column chromatography (petroleum ether:ethyl acetate=15:1) to yield 10 g (yield: 10%) of d5. MS(ASAP)=335.2.

Intermediate 1h (50 g), d5 (110 g) and anhydrous cesium carbonate (285 g) were dissolved in 500 mL of anhydrous N,N-dimethylformamide, the resulting mixture was stirred at 100° C. for 8 h. After cooling down to room temperature, the reaction solution was extracted with a large amount of deionized-water and dichloromethane, then the organic phase was retained. After removing the organic solvent under reduced pressure distillation, the resulting sample was further purified by silica gel column chromatography to yield 51 g (yield: 63%) of intermediate d6.

Intermediate d6 (10 g) was dissolved in 300 mL of tert-butylbenzene, and tert-butyllithium (16 mL, 1.3 M of n-hexane solution) was added dropwise to the above mixture in an ice bath. After heating up to 100° C., the reaction mixture was stirred for 2 h, cooled the reaction to below 0° C. by ice bath, then boron tribromide (5.2 mL) was added dropwise. After the addition was completed, the resulting mixture was heated at 180° C. and stirred for 8 h, then N,N-diisopropylethylamine (24 mL) was added dropwise to the above reaction in an ice bath. After stirring overnight at 180° C., the resulting mixture was cooled down to room temperature, extracted with a large amount of deionized-water and dichloromethane, then the organic phase was retained. After removing the organic solvent under reduced pressure distillation, the resulting sample was further purified by silica gel column chromatography to yield 1.2 g (yield: 12%) of comparative compound 2 (DB2). MS(ASAP)=676.7.

### 2. Energy Structure of Compounds

The energy level of the organic compound can be calculated by quantum computation, for example, using TD-DFT (time-dependent density functional theory) by Gaussian 09W (Gaussian Inc.), the specific simulation methods of which can be found in WO2011141110. Firstly, the molecular geometry is optimized by semi-empirical method “Ground State/Semi-empirical/Default Spin/AM1” (Charge 0/Spin Singlet), then the energy structure of organic molecules is calculated by TD-DFT (time-dependent density functional theory) “TD-SCF/DFT/Default Spin/B3PW91” and the basis set “6-31G (d)” (Charge 0/Spin Singlet). The HOMO and LUMO energy levels are calculated using the following calibration formula, where S₁, T₁, and oscillator strength f(S₁) are used directly.

$$\begin{matrix}HOMO ( eV ) = ( ( HOMO ( G ) \times 27.212 ) - 0.9899 ) / 1.1206 \\ LUMO ( eV ) = ( ( LUMO ( G ) \times 27.212 ) - 2.0041 ) / 1.385\end{matrix}$$

Where HOMO(G) and LUMO(G) are the direct calculation results of Gaussian 09W, in units of Hartree. The results are shown in Table 1 below:

TABLE 1

| | Homo | Lumo | □HOMO | □LUMO | S₁ | |
|---|---|---|---|---|---|---|
| Materials | [eV] | [eV] | [eV] | [eV] | [eV] | f(S₁) |
| Compound 1 | −5.33 | −2.59 | 0.59 | 0.40 | 2.95 | 0.48 |
| Compound 2 | −5.22 | −2.53 | 0.30 | 0.46 | 2.91 | 0.48 |
| Compound 3 | −5.34 | −2.64 | 0.58 | 0.45 | 2.90 | 0.47 |
| Compound 4 | −5.44 | −2.68 | 0.29 | 0.44 | 2.96 | 0.49 |
| Compound 5 | −5.25 | −2.57 | 0.29 | 0.06 | 2.90 | 0.43 |
| Compound 6 | −5.36 | −2.62 | 0.59 | 0.09 | 2.94 | 0.49 |
| Compound 7 | −5.24 | −2.58 | 0.30 | 0.50 | 2.87 | 0.47 |
| Compound 8 | −5.36 | −2.61 | 0.54 | 0.47 | 2.95 | 0.36 |
| Compound 9 | −5.32 | −2.63 | 0.57 | 0.36 | 2.87 | 0.38 |
| Compound 10 | −5.32 | −2.63 | 0.57 | 0.60 | 2.89 | 0.54 |
| Compound 11 | −5.32 | −2.66 | 0.59 | 0.40 | 2.85 | 0.46 |
| Compound 12 | −5.31 | −2.75 | 0.57 | 0.63 | 2.73 | 0.47 |
| Compound 13 | −5.26 | −2.59 | 0.55 | 0.50 | 2.86 | 0.32 |
| Compound 14 | −5.31 | −2.60 | 0.56 | 0.57 | 2.92 | 0.49 |
| Compound 15 | −5.39 | −2.65 | 0.52 | 0.12 | 2.91 | 0.32 |
| Compound 16 | −5.30 | −2.63 | 0.58 | 0.35 | 2.85 | 0.35 |
| Compound 17 | −5.32 | −2.76 | 0.43 | 0.62 | 2.71 | 0.42 |
| Compound 18 | −5.29 | −2.62 | 0.58 | 0.51 | 2.86 | 0.40 |
| DB1 | −5.09 | −2.25 | 0.08 | 0.50 | 3.09 | 0.21 |
| DB2 | −5.28 | −2.75 | 0.52 | 0.63 | 2.68 | 0.30 |

### 3. Optical Properties of the Compounds

The optical properties of compound 1-compound 18, DB1, and DB2 in the synthesis examples are shown in Table 2.

TABLE 2

| | | | Photoluminescence |
|---|---|---|---|
| | Luminescence | | Quantum Yield |
| Materials | Peak (nm) | FWHM (nm) | (PLQY) (%) |
| Compound 1 | 461 | 20 | 91 |
| Compound 2 | 463 | 21 | 90 |
| Compound 3 | 465 | 20 | 88 |
| Compound 4 | 454 | 22 | 92 |
| Compound 5 | 463 | 21 | 87 |
| Compound 6 | 461 | 19 | 86 |
| Compound 7 | 471 | 19 | 88 |
| Compound 8 | 465 | 33 | 67 |
| Compound 9 | 471 | 28 | 73 |
| Compound 10 | 467 | 28 | 95 |
| Compound 11 | 478 | 30 | 81 |
| Compound 12 | 494 | 28 | 80 |
| Compound 13 | 467 | 30 | 70 |
| Compound 14 | 460 | 27 | 92 |
| Compound 15 | 459 | 33 | 89 |
| Compound 16 | 472 | 28 | 80 |
| Compound 17 | 497 | 33 | 91 |
| Compound 18 | 465 | 33 | 89 |
| DB1 | 453 | 26 | 85 |
| DB2 | 507 | 28 | 80 |

Note:
The wavelength range of 407 nm~505 nm is the blue light region, and the wavelength range of 505 nm~525 nm is the green light region.

As shown in Table 2, the synthesized compounds 2, 5, and 7 exhibit efficient blue emission with a narrow FWHM by employing an indolocarbazole group as a modifying group connected to the B atom, which effectively inhibits the rotation and vibration of their internal free radicals to narrow the FWHM of the emission spectrum and improve the quantum efficiency. Among them, the compound 7 adopts a deuterated benzene ring as a modifying group to modify the benzene ring at the para position of the B atom, enhancing the electron cloud density of the benzene ring at the para position of the B atom, thereby tuning the luminescence color.

In the compounds 1, 3, 4, 6, and 8-18, the carbazolofuryl group used in the boron-nitrogen ring structure skeleton is connected to the B atom as a modifying group. Due to the electron withdrawing effect of the oxygen atom, the electron cloud density of the benzene ring adjacent to the B atom can be reduced, and the super-resonance effect of the whole compound can be improved.

This not only effectively narrows the FWHM of the emission spectrum of the new organic compound, but also causes a slight blue shift in the light of the new B—N organic compound. In the compound 17, a carbazolothiophene group is used as a modifying group in the boron-nitrogen ring structure skeleton, which is connected to the B atom and has a similar effect to the use of carbazofuran.

The emission spectrum of the comparative compound 2 exhibits green emission, which indicates that the position of the fused ring has a significant impact on the maximum emission peak of the molecule.

### 4. Preparation and Characterization of OLEDs

### Example 1 (Preparation of OLED Device 1)

Step S1: the transparent glass was used as a glass substrate, the anode (ITO (15 nm)/Ag (150 nm)/ITO (15 nm)) on it was cleaned by ultrasonic cleaning with stripping solution, pure water, and isopropyl alcohol in sequence, then treated with ozone in argon after drying.

Step S2: the cleaned substrate was mounted on a vacuum deposition apparatus in high vacuum (1×10⁻⁶ mbar), PD and HT-1 at a weight ratio of 3:100 was co-deposited to form a hole-injection layer (HIL) having a thickness of 10 nm.

Step S3: the hole-transport material (i.e., compound HT-1) was vacuum evaporated on the hole-injection layer to form a hole-transport layer having a thickness of 125 nm.

Step S4: the electron-blocking material (i.e., compound HT-2) was vacuum evaporated on the hole-injection layer to form an electron-blocking layer having a thickness of 10 nm.

Step S5: BH (host) and compound 1 (dopant) were vacuum evaporated on the electron-blocking layer at a weight ratio of 98:2 to form a light-emitting layer having a thickness of 25 nm.

Step S6: the hole-blocking material (i.e., compound ET-1) was vacuum evaporated on the light-emitting layer to form a hole-blocking layer having a thickness of 2 nm.

Step S7: compound ET-2 and Liq were vacuum evaporated on the hole-blocking layer at a weight ratio of 50:50 to form an electron-transport layer having a thickness of 35 nm.

Step S8: Yb was vacuum evaporated on the electron-transport layer to form an electron-injection layer having a thickness of 1.5 nm.

Step S9: Mg:Ag (1:9) alloy was evaporated on the electron-injection layer to form a cathode having a thickness of 17 nm.

Step S10: CPL with a thickness of 55 nm was evaporated on the cathode layer.

The structural formulas of the materials used for each functional layer are shown below:

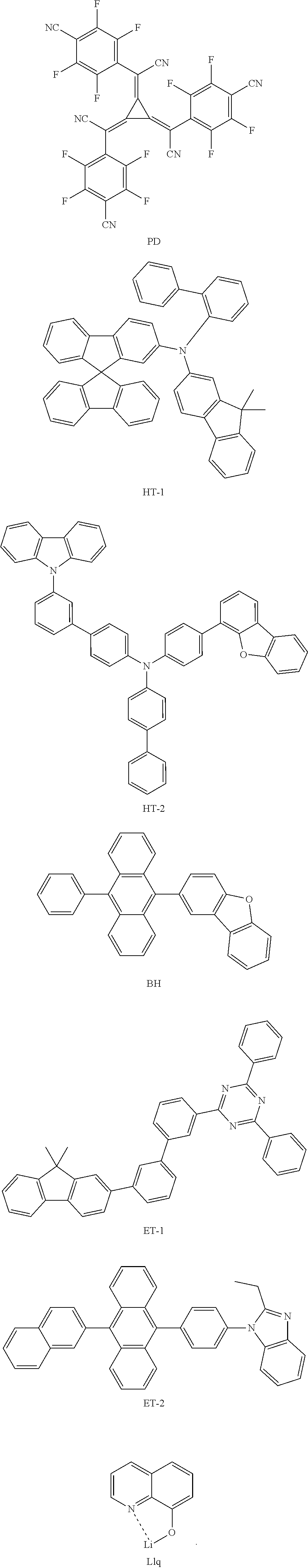

### Example 2 (Preparation of OLED Device 2)

The difference between Example 2 and Example 1 lies in:
in Step S3, the hole-transport material (i.e., compound HT-1) was vacuum evaporated on the hole-injection layer to form a hole-transport layer having a thickness of 120 nm, and the compound 2 was adopted as the dopant material in step S5. Other steps are the same as in the example 1, please refer to the above-mentioned Example 1 for details.

### Example 3 (Preparation of OLED Device 3)

The difference between Example 3 and Example 1 lies in:
in Step S3, the hole-transport material (i.e., compound HT-1) was vacuum evaporated on the hole-injection layer to form a hole-transport layer having a thickness of 122 nm, and the compound 3 was adopted as the dopant material in step S5. Other steps are the same as in the example 1, please refer to the above-mentioned Example 1 for details.

### Example 4 (Preparation of OLED Device 4)

The difference between Example 4 and Example 1 lies in:
in Step S3, the hole-transport material (i.e., compound HT-1) was vacuum evaporated on the hole-injection layer to form a hole-transport layer having a thickness of 122 nm, and the compound 8 was adopted as the dopant material in step S5. Other steps are the same as in the example 1, please refer to the above-mentioned Example 1 for details.

### Example 5 (Preparation of OLED Device 5)

The difference between Example 5 and Example 1 lies in:
in Step S3, the hole-transport material (i.e., compound HT-1) was vacuum evaporated on the hole-injection layer to form a hole-transport layer having a thickness of 122 nm, and the compound 13 was adopted as the dopant material in step S5. Other steps are the same as in the example 1, please refer to the above-mentioned Example 1 for details.

### Example 6 (Preparation of OLED Device 6)

The difference between Example 6 and Example 1 lies in:
in Step S3, the hole-transport material (i.e., compound HT-1) was vacuum evaporated on the hole-injection layer to form a hole-transport layer having a thickness of 122 nm, and the compound 14 was adopted as the dopant material in step S5. Other steps are the same as in the example 1, please refer to the above-mentioned Example 1 for details.

### Example 7 (Preparation of OLED Device 7)

The difference between Example 7 and Example 1 lies in:
in Step S3, the hole-transport material (i.e., compound HT-1) was vacuum evaporated on the hole-injection layer to form a hole-transport layer having a thickness of 122 nm, and the compound 16 was adopted as the dopant material in step S5. Other steps are the same as in the example 1, please refer to the above-mentioned Example 1 for details.

### Comparative Example 1 (Preparation of OLED Comparative Device 1)

The difference between Comparative Example 1 and Example 1 lies in:
in Step S3, the hole-transport material (i.e., compound HT-1) was vacuum evaporated on the hole-injection layer to form a hole-transport layer having a thickness of 121 nm, and the existing boron-nitrogen material corresponding to the comparative compound 1 is adopted as the dopant material in step S5. Other steps are the same as in the example 1, please refer to the above-mentioned Example 1 for details.

As shown in Table 3, the device performance of the example 1-example 7 and the comparative example 1 was tested; the current efficiency and LT95 were normalized by taking comparative example 1 as 100%.

TABLE 3

| | | Current | Lumines- | | |
|---|---|---|---|---|---|
| | Voltage | Efficiency | cence | FWHM | LT95@1000 |
| | (V) | (cd/A) | Peak (nm) | (nm) | nit (h) |
| Example 1 | 3.75 | 141% | 460 | 19.0 | 111% |
| Example 2 | 3.32 | 148% | 463 | 21.0 | 100% |
| Example 3 | 3.31 | 153% | 465 | 20.0 | 127% |
| Example 4 | 3.25 | 155% | 465 | 25.0 | 130% |
| Example 5 | 3.3 | 150% | 467 | 22.0 | 120% |
| Example 6 | 3.41 | 160% | 460 | 20.0 | 128% |
| Example 7 | 3.32 | 153% | 472 | 25.0 | 160% |
| Comparative | 3.38 | 100% | 461 | 18.0 | 100% |
| Example 1 | | | | | |

Note:
LT95@1000 nit refers to the operating time until 5% luminance decay occurs at 1000 nits brightness.

As can be seen from the current efficiency, the FWHM of the emission spectrum, and the device operational lifetime at 1000 brightness (operating time at which 5% maximum brightness loss occurs) of the devices of examples 1 to 7 and comparative example 1 in Table 3, the OLED devices of Examples 1 to 7 employing the boron-nitrogen-containing organic compound as described herein exhibit higher luminescence efficiency, longer operational lifetime, and higher device stability compared to comparative example 1.

It should be noted that the above description is only a specific embodiment of the present disclosure, but the scope of protection of the present disclosure is not limited thereto. Any person skilled in the art may easily conceive of modifications or substitutions within the technical scope disclosed by the present disclosure, which shall all fall within the protection scope of the present disclosure. In the case of no conflict, the embodiments of the present disclosure and the features in the embodiments may be combined with each other. Therefore, the protection scope of the present disclosure shall be subject to the scope defined by the claims.

What is claimed is:

1. A boron-nitrogen-containing organic compound, wherein a structure of the boron-nitrogen-containing organic compound is represented by a combination of formula (I-1) and formula (I-2): 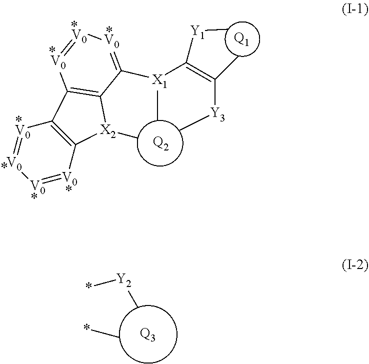
wherein:
each * independently represents a linkage site where formula (I-1) is fused with formula (I-2);
Q₁ ring, Q₂ ring, and Q₃ ring are each independently selected from a substituted/unsubstituted aryl group, a substituted/unsubstituted heteroaryl group, or a substituted/unsubstituted fused-ring structure;
each of X₁ and X₂ is independently selected from B, N, P, P═O, or Al;
each of Y₁ and Y₂ is independently selected from C═O, N—R₁, O, S, Se, P, P═O, or P═S;
each Y₃ is independently selected from C═O, N—R₁, O, Se, P, P═O, or P═S;
V₀ at each occurrence is independently C—R₂ or N—R₃;
each of R₁ to R₃ at each occurrence is independently selected from —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 60 ring atoms, an aryloxy or heteroaryloxy group containing 5 to 60 ring atoms, or any combination thereof.

2. The boron-nitrogen-containing organic compound according to claim 1, wherein the structure of the boron-nitrogen-containing organic compound is represented by a combination of formula (I-1a) and formula (I-2a):

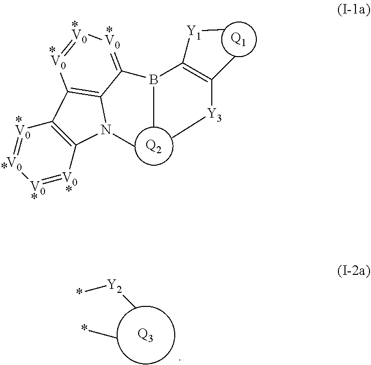

3. The boron-nitrogen-containing organic compound according to claim 1, wherein the boron-nitrogen-containing organic compound comprises a structure of one of formulas (II-1)-(II-10): 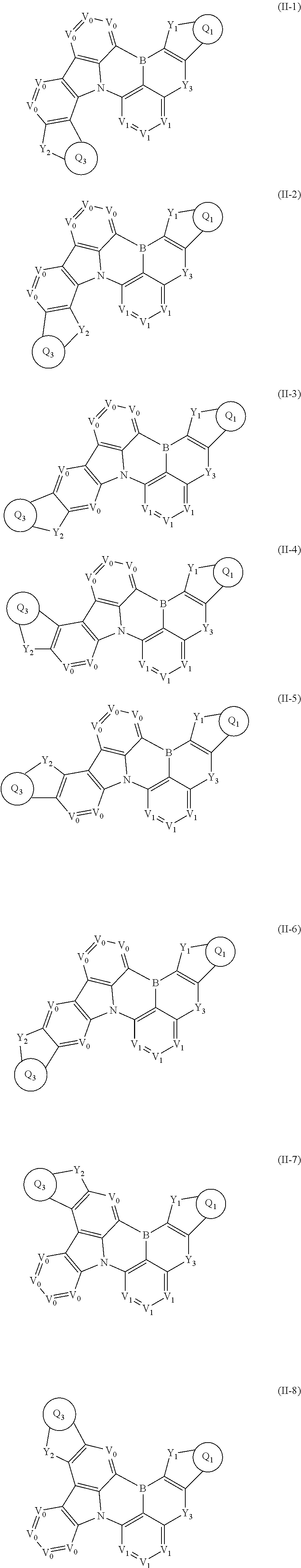 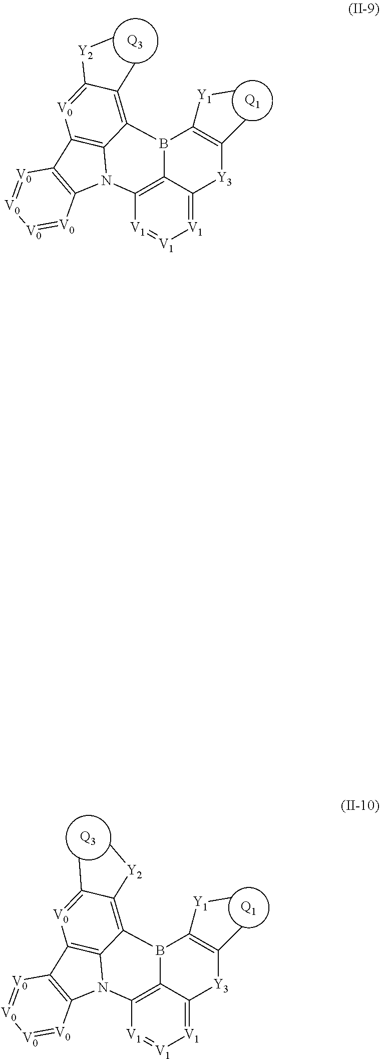
wherein, V₁ at each occurrence is independently C—R₂ or N—R₃.

4. The boron-nitrogen-containing organic compound according to claim 2, wherein the boron-nitrogen-containing organic compound comprises a structure of one of formulas (II-1)-(II-10): 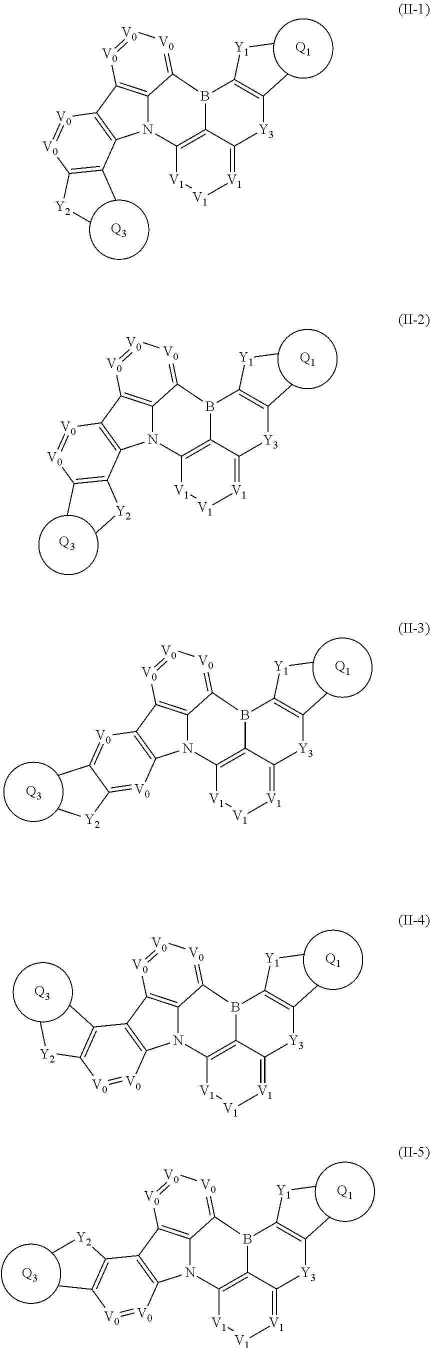 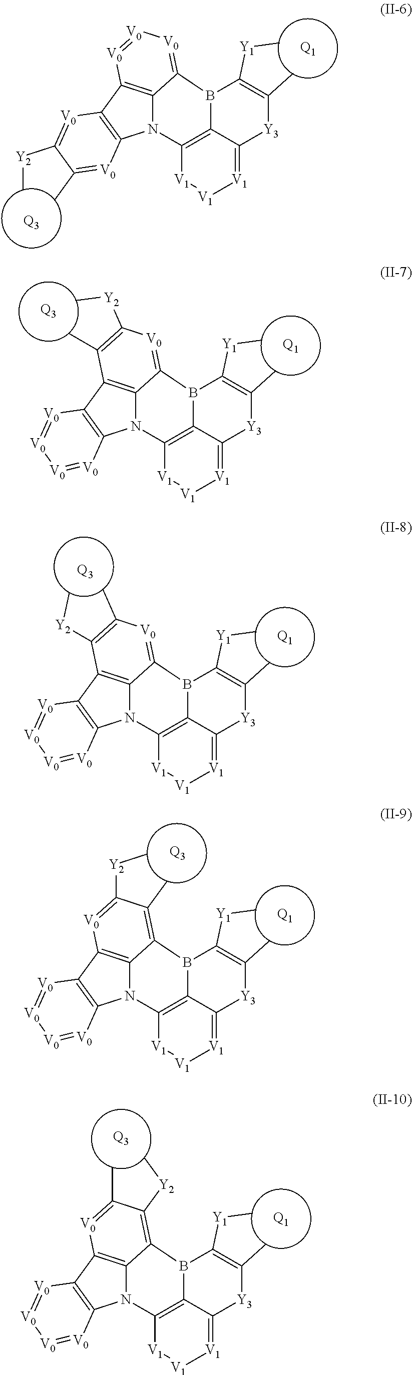
wherein, V₁ at each occurrence is independently C—R₂ or N—R₃.

5. The boron-nitrogen-containing organic compound according to claim 1, wherein Q₁ ring, Q₂ ring, and Q₃ ring are each independently selected from one or combinations of more than one of the following structures: 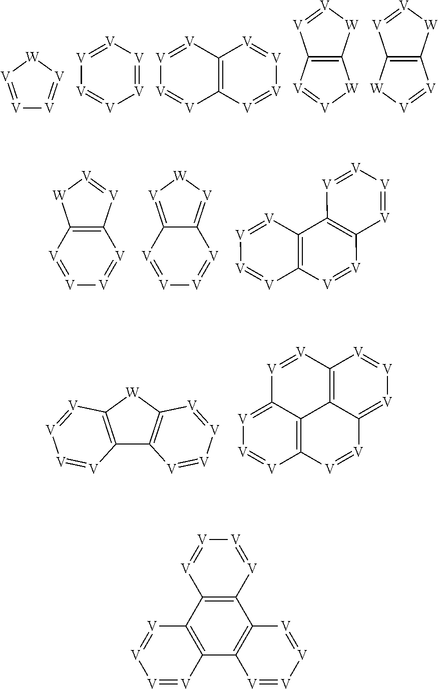
wherein, V at each occurrence is independently C—R₄ or N—R₅;
W at each occurrence is independently selected from B—R₆, C(═O), N—R₇, O, S, P, P═O, or P═S;
each of R₄ to R₇ at each occurrence is independently selected from —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 40 ring atoms, an aryloxy or heteroaryloxy group containing 5 to 40 ring atoms, or any combination thereof, wherein one or more R₄-R₇ form a ring system with each other and/or with the groups bonded thereto.

6. The boron-nitrogen-containing organic compound according to claim 2, wherein Q₁ ring, Q₂ ring, and Q₃ ring are each independently selected from one or combinations of more than one of the following structures: 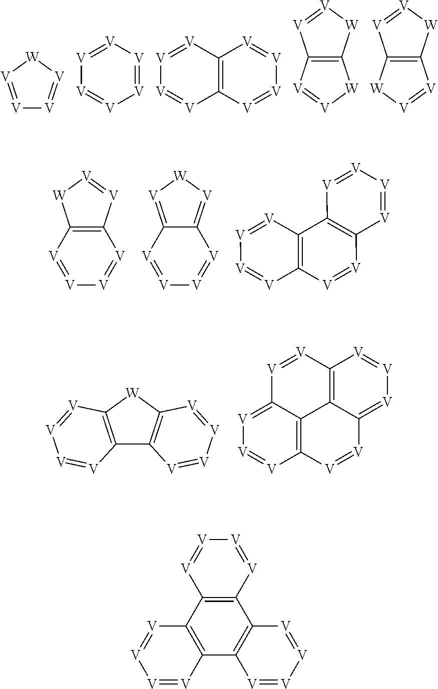
wherein, V at each occurrence is independently C—R₄ or N—R₅;
W at each occurrence is independently selected from B—R₆, C(═O), N—R₇, O, S, P, P═O, or P═S;
each of R₄ to R₇ at each occurrence is independently selected from —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 40 ring atoms, an aryloxy or heteroaryloxy group containing 5 to 40 ring atoms, or any combination thereof, wherein one or more R₄-R₇ form a ring system with each other and/or with the groups bonded thereto.

7. The boron-nitrogen-containing organic compound according to claim 3, wherein Q₁ ring, Q₂ ring, and Q₃ ring are each independently selected from one or combinations of more than one of the following structures: 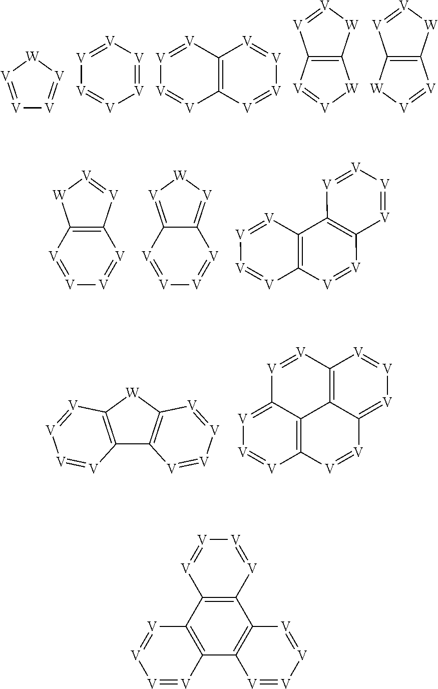
wherein, V at each occurrence is independently C—R₄ or N—R₅;
W at each occurrence is independently selected from B—R₆, C(═O), N—R₇, O, S, P, P═O, or P═S;
each of R₄ to R₇ at each occurrence is independently selected from —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 40 ring atoms, an aryloxy or heteroaryloxy group containing 5 to 40 ring atoms, or any combination thereof, wherein one or more R₄-R₇ form a ring system with each other and/or with the groups bonded thereto.

8. The boron-nitrogen-containing organic compound according to claim 4, wherein Q₁ ring, Q₂ ring, and Q₃ ring are each independently selected from one or combinations of more than one of the following structures: 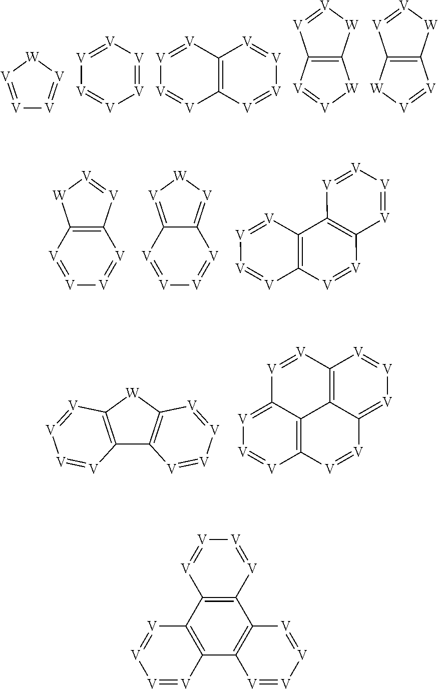
wherein, V at each occurrence is independently C—R₄ or N—R₅;
W at each occurrence is independently selected from B—R₆, C(═O), N—R₇, O, S, P, P═O, or P═S;
each of R₄ to R₇ at each occurrence is independently selected from —H, -D, a C₁-C₂₀ linear alkyl group, a C₁-C₂₀ linear alkoxy group, a C₁-C₂₀ linear thioalkoxy group, a C₃-C₂₀ branched/cyclic alkyl group, a C₃-C₂₀ branched/cyclic alkoxy group, a C₃-C₂₀ branched/cyclic thioalkoxy group, a C₃-C₂₀ branched/cyclic silyl group, a C₁-C₂₀ substituted ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate group, an isothiocyanate group, a hydroxyl group, a nitro group, —CF₃, —Cl, —Br, —F, a cross-linkable group, a substituted/unsubstituted aromatic or heteroaromatic group containing 5 to 40 ring atoms, an aryloxy or heteroaryloxy group containing 5 to 40 ring atoms, or any combination thereof, wherein one or more R₄-R₇ form a ring system with each other and/or with the groups bonded thereto.

9. A formulation, comprising an organic solvent, and at least one of the boron-nitrogen-containing organic compound according to claim 1.

10. An organic electronic device, comprising the boron-nitrogen-containing organic compound according to claim 1.

11. The organic electronic device according to claim 10, wherein the organic electronic device is selected from a color converter, an organic light-emitting diode, an organic photovoltaic cell, an organic light emitting electrochemical cell, an organic field effect transistor, an organic light emitting field effect transistor, an organic laser, an organic spintronic electronic device, an organic sensor, or an organic plasmon emitting diode.

12. The organic electronic device according to claim 10, wherein the organic electronic device is an organic light-emitting device, the organic light-emitting device comprises a light-emitting layer, and the dopant material of the light-emitting layer comprises at least one of the boron-nitrogen-containing organic compound.
